(19) United States
(12) Patent Application Publication
(10) Pub. No.: US 2026/0353543 A1
(43) Pub. Date: Nov. 5, 2026

(54) CIRCUIT BOARD AND WORKING ASSEMBLY

(71) Applicant: Canaan Creative Co., LTD., Beijing (CN)

(72) Inventors: Shaohua ZHANG, Beijing (CN); Huan YANG, Beijing (CN); Nangeng ZHANG, Beijing (CN)

(21) Appl. No.: 19/120,752

(22) PCT Filed: Oct. 20, 2023
(86) PCT No.: PCT/CN2023/125699

§ 371 Date: Apr. 11, 2025

(30) Foreign Application Priority Data
Oct. 20, 2022 (CN) 202211291965.1
Nov. 11, 2022 (CN) 202211415822.7

(51) Int. Cl. H05K 1/02; H05K 1/18

(52) U.S. Cl. CPC H05K 1/0203; H05K 1/18; H05K 2201/10522

(57) ABSTRACT

A circuit board, provided with a chip array. The chip array comprises a plurality of power taking units, each power taking unit comprises at least one chip, and the distances between at least some of the adjacent power taking units are not equal, thereby facilitating heat dissipation and temperature equalization of the circuit board.

### CROSS REFERENCE TO RELATED APPLICATIONS

This present application is a U.S. National Stage Application of International Application No. PCT/CN2023/125699, filed on Oct. 20, 2023, which claims priority to and benefits of Chinese Patent Application No. 202211291965.1, entitled “WORKING ASSEMBLY AND ELECTRONIC DEVICE”, filed with the China Patent Office on Oct. 20, 2022, and Chinese Patent Application No. 202211415822.7, entitled “CIRCUIT BOARD AND WORKING ASSEMBLY”, filed with the China Patent Office on Nov. 11, 2022. The entire contents of all of the above-identified applications are incorporated herein by reference.

### TECHNICAL FIELD

The present application relates to the technical field of heat dissipation, and, especially, to a circuit board and a working assembly.

### BACKGROUND

For a circuit board, there is a need to have higher heat dissipation and temperature equalization performances.

### SUMMARY

Embodiments of the present application provide a circuit board and an electronic device.

As a first aspect of the embodiments of the present application, an embodiment of the present application provides a circuit board, provided with a chip array thereon, the chip array including a plurality of power taking units, the power taking unit including at least one chip, wherein distances between at least some of the adjacent power taking units are not equal.

As a second aspect of the embodiments of the present application, an embodiment of the present application provides a circuit board, provided with a chip array including a plurality of chips and at least one vacant position.

As a third aspect of the embodiments of the present application, an embodiment of the present application provides a circuit board, provided with a plurality of chip groups, each including at least one row of chips and/or at least one column of chips, wherein a spacing of at least some of the adjacent chip groups is not equal to a spacing of the adjacent chips within any one of the chip groups.

As a fourth aspect of the embodiments of the present application, an embodiment of the present application provides a working assembly, including a circuit board, and a heat sink including a heat dissipation body and heat dissipation fins, the heat dissipation body including a first surface and a second surface opposite to each other, and the first surface connected with the heat dissipation fins.

The above summary is only for the purpose of the specification, and is not intended to make limitations in any way. In addition to the aspects, implementations, and features described above, further aspects, implementations, and features of the present application will be easily understood by referring to the drawings and the following detailed description.

### BRIEF DESCRIPTION OF THE DRAWINGS

In the drawings, unless otherwise specified, the same reference numerals throughout the plurality of drawings represent the same or similar components or elements. These drawings are not necessarily drawn to scale. It should be understood that these drawings only depict some implementations disclosed in the present application and should not be regarded as limitations on the scope of the present application.

FIG. 1A shows a schematic structural view of a circuit board according to an embodiment of the present application.

FIG. 1B shows a schematic structural view of a circuit board according to Embodiment One of the present application.

FIG. 2A shows a schematic structural view of a circuit board according to Embodiment Two of the present application.

FIG. 2B shows a current diagram of the circuit board shown in FIG. 2A.

FIG. 2C shows a signal diagram of the circuit board shown in FIG. 2A.

FIG. 3 shows a schematic structural view of a circuit board according to Embodiment Three of the present application.

FIG. 4 shows a schematic structural view of a circuit board according to Embodiment Four of the present application.

FIG. 5 shows a schematic structural view of a circuit board according to Embodiment Five of the present application.

FIG. 6A shows a schematic structural view of a circuit board according to Embodiment Six of the present application.

FIG. 6B shows another schematic structural view of the circuit board according to Embodiment Six of the present application.

FIG. 7 shows a schematic structural view of a circuit board according to Embodiment Seven of the present application.

FIG. 8 shows a schematic structural view of a circuit board according to Embodiment Eight of the present application.

FIG. 9 shows a schematic structural view of a circuit board according to Embodiment Nine of the present application.

FIG. 10 shows a schematic structural view of a circuit board according to Embodiment Ten of the present application.

FIG. 11 shows a schematic structural view of a circuit board according to Embodiment Eleven of the present application.

FIG. 12 shows a schematic structural view of a circuit board according to Embodiment Twelve of the present application.

FIG. 13 shows a schematic structural view of a circuit board according to Embodiment Thirteen of the present application.

FIG. 14 shows a schematic structural view of a circuit board according to Embodiment Fourteen of the present application.

FIG. 15 shows a schematic structural view of a circuit board according to Embodiment Fifteen of the present application.

FIG. 16 shows a schematic structural view of a circuit board according to Embodiment Sixteen of the present application.

FIG. 17 shows a schematic structural view of a circuit board according to Embodiment Seventeen of the present application.

FIG. 18 shows a schematic structural view of a circuit board according to Embodiment Eighteen of the present application.

FIG. 19A shows a schematic structural view of a circuit board according to Embodiment Nineteen of the present application.

FIG. 19B shows a current diagram of the circuit board shown in FIG. 19A.

FIG. 20 shows a schematic structural view of a circuit board according to Embodiment Twenty of the present application.

FIG. 21A shows a schematic structural view of a circuit board according to Embodiment Twenty-One of the present application.

FIG. 21B shows a current diagram of the circuit board shown in FIG. 21A;

FIG. 22 shows a schematic structural view of an electronic device according to an embodiment of the present application.

FIG. 23 shows a schematic structural view of a working assembly according to an embodiment of the present application.

### REFERENCE NUMERALS

110: circuit board; 111: chip; 113: vacant position; 114: power taking unit; 115: power line; 116: signal line; 117: welding pad; 118: chip group; 119: first electrical connector; 119′: second electrical connector;
2100: working assembly; 2110: heat sink;
3100: electronic device.

### DETAILED DESCRIPTION

Only some exemplary embodiments are briefly described below. Just as those skilled in the art may appreciate, the described embodiments may be modified in various ways without departing from the spirit or scope of the present application. Therefore, the drawings and description are considered to be exemplary in nature, not limitative.

In the existing technologies, solutions of disposing chips on a circuit board are to dispose a single chip or to unevenly or irregularly dispose a plurality of chips, which are poor in heat dissipation and temperature equalization.

Usually, only a single chip or a small number of chips is provided on a circuit board in the existing technologies, at which time the requirements are not high for the heat dissipation and temperature equalization performances of the chip(s) of the entire circuit board. Usually in a case of a plurality of chips, the chip arrangement manner is not of regularity either. For a circuit board with more chips, there is a need to have higher heat dissipation and temperature equalization performances.

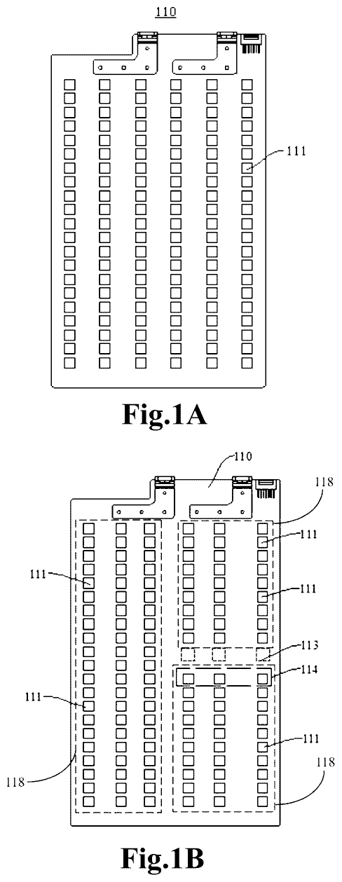

FIG. 1A is a schematic structural view of a circuit board 110 involved in the present application. As shown in FIG. 1A, a plurality of chips on the circuit board 110 are arranged in an array, row spacings of the plurality of chips 111 are the same, and column spacings of the plurality of chips 111 are the same. A total number of the chips in the chip array is large, which can improve the computing power of the circuit board 110, thereby improving the overall performance of the circuit board 110, and the manner of array arrangement can improve the heat dissipation and temperature equalization of the plurality of chips 111.

In order to further improve the heat dissipation and temperature equalization of the plurality of chips 111, the present application discloses the following embodiments.

An embodiment of the present application provides a circuit board 110, provided with a chip array including a plurality of power taking units 114, each including at least one chip 111, wherein distances between at least some of the adjacent power taking units 114 are not equal. In the description of the present application, the meaning of “plurality” is two or more. The power taking units 114 can be connected in series, and chips 111 in the power taking unit 114 can be connected in parallel.

For example, as shown in FIG. 1B, the chip array includes 40 power taking units 114 connected in series, and the 40 power taking units 114 are connected in series. Each power taking unit 114 includes 3 chips 111 connected in parallel, so that there are 21 power taking units 114 on the left and 19 power taking units 114 on the right. A distance between the 9th and 10th power taking units 114 on the right counted from top to bottom is not equal to distances between other adjacent power taking units 114.

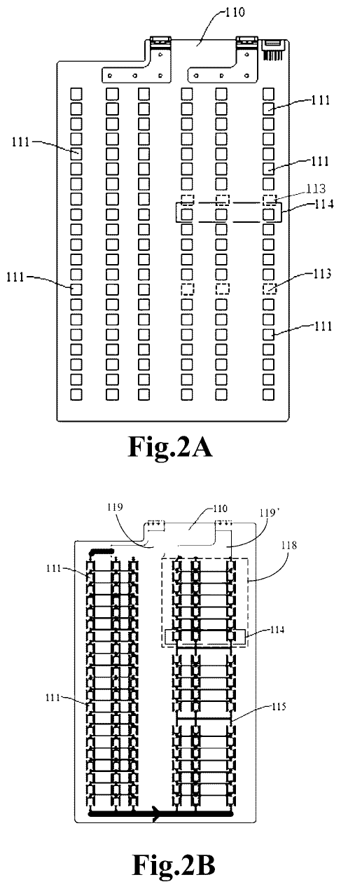

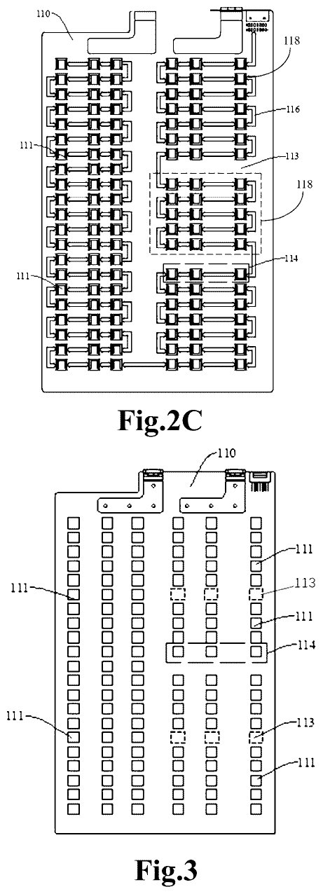

That is to say, in FIG. 1B, distances between at least some of the adjacent power taking units 114 are not equal, and a similar situation also exists in the circuit boards 110 of FIGS. 2A to 17 and FIGS. 19A to 21B.

Thus, a heat dissipation channel is formed between the adjacent power taking units 114 with unequal distances, which is beneficial to the heat dissipation of the circuit board 110.

In an implementation, the chips in the chip array are of the same size, and a total number of the chips in the chip array is greater than or equal to 20 or 50. For example, in the example of FIG. 1B, each chip is rectangular, and a total number of the chips in the chip array is 120. Therefore, in FIG. 1B, the chips in the chip array are of the same size, and a total number of the chips in the chip array is greater than or equal to 20 or 50. A similar situation also exists in the circuit boards 110 of FIGS. 2A to 21B.

In this embodiment, by making the chips 111 in the chip array the same in size, the versatility of the chips 111 can be improved, and the processing can be convenient; by making the total number of the chips 111 in the chip array greater than or equal to 20 or 50, the total number of the chips in the chip array is large, which can improve the computing power of the circuit board 110, and thereby improve the overall performance of the circuit board 110.

In an implementation, along a direction perpendicular to a parallel connection direction or along a series connection direction (e.g., the up-down direction in FIG. 1B), distances between at least some of the adjacent power taking units 114 are greater than distances between other adjacent power taking units 114. For example, in the example of FIG. 1B, the 21 power taking units 114 in the left 3 columns, i.e., a first distribution zone, are provided with even spacings, and distances between the 9th and 10th power taking units 114 in the right 3 columns, i.e., a second distribution zone, counted from top to bottom, are greater than distances between other adjacent power taking units 114. In this way, in the up-down direction, the 19 power taking units 114 in the second distribution zone can be partitioned according to the spacing between the adjacent power taking units 114, so as to divide the 19 power taking units 114 into two sub-areas. Power taking units 114 in each sub-area can be arranged with equal spacings, and a spacing between the two sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

In an implementation, referring to FIGS. 2A-2C, along a direction perpendicular to a parallel connection direction or along a series connection direction, lengths of electrical connection lines between at least some of the adjacent power taking units 114 are longer than lengths of electrical connection lines between other adjacent power taking units 114, wherein a length direction is perpendicular to the parallel connection direction of the power taking units 114. The electrical connection lines may include power lines 115 and/or signal lines 116. Exemplarily, in conjunction with FIG. 2A-2C, in the up-down direction, a spacing between the 7th power taking unit 114 and the 8th power taking unit 114 on the right and a spacing between the 12th power taking unit 114 and the 13th power taking unit 114 can be greater than spacings of other adjacent power taking units 114, and therefore, in the up-down direction, a length of an electrical connection line between the 7th power taking unit 114 and the 8th power taking unit 114 on the right and a length of an electrical connection line between the 12th power taking unit 114 and the 13th power taking unit 114 are longer than lengths of electrical connection lines between other adjacent power taking units 114; namely, there are large vacancies between the adjacent power taking units 114 to form a heat dissipation channel, and the heat dissipation channel is formed, which is beneficial to the heat dissipation of the circuit board 110. A similar situation also exists in the circuit boards 110 of FIG. 1B, FIGS. 3 to 17, and FIGS. 19A to 21B.

Further, the above other adjacent power taking units 114 are adjacent power taking units 114 in the same row or the same column. For example, in the examples of FIGS. 2A-2C, the above other adjacent power taking units 114 can be non-edge power taking units 114 in the chip array in the direction perpendicular to the parallel connection direction of the power taking units 114. For example, they can be adjacent power taking units 114 in the 1st to 7th power taking units 114 provided in the same column on the right, adjacent power taking units 114 in the 8th to 12th power taking units 114 provided in the same column on the right, and adjacent power taking units 114 in the 13th to 19th power taking units 114 provided in the same column on the right. A similar situation also exists in the circuit boards 110 of FIG. 1B, FIGS. 3 to 17, and FIGS. 19A to 21B.

In an implementation, along a heat dissipation direction, the distance between the adjacent power taking units 114 increases, and/or the distance between the adjacent chips 111 increases. Exemplarily, in conjunction with FIG. 22, the circuit board 110 can be applied to an electronic device 3100, such as a computing device. A heat dissipation duct is defined within the electronic device 3100, and the circuit board 110 can work within the heat dissipation duct. A heat dissipation direction of the circuit board 110 is a direction from an air inlet to an air outlet of the heat dissipation duct. A heat dissipation source of the circuit board 110 can be an air-cooled heat dissipation source (e.g., a fan) or a liquid-cooled heat dissipation source. For example, the heat dissipation direction is a direction from left to right. Along the left-right direction, distances between the left and right power taking units 114 can be greater than distances between two adjacent columns of the chips within each power taking unit 114. Of course, along the left-right direction, distances between the left and right power taking units 114 can be equal to distances between two adjacent columns of the chips within each power taking unit 114; still alternatively, along the left-right direction, distances between the left and right power taking units 114 can be less than distances between two adjacent columns of the chips within each power taking unit 114; yet alternatively, along the left-right direction, distances between multiple columns of the chips can gradually increase or decrease.

In an implementation, in a heat dissipation direction, a rectangular area of the circuit board 110 occupied by the chip array is divided into a plurality of distribution zones, and the numbers of the power taking units 114 within at least two of the distribution zones are not equal.

Exemplarily, in conjunction with FIG. 1B, in the left-right direction, the rectangular area of the circuit board 110 occupied by the chip array is divided into two distribution zones, namely, a maximum value Y of the number of row chips equally divides the chip array into two distribution zones, which are respectively a first distribution zone (e.g., the chips in the left three columns in FIG. 1B) and a second distribution zone (e.g., the chips in the right three columns in FIG. 1B), and the numbers of the power taking units 114 within the first distribution zone and the second distribution zone are not equal. Specifically, the first distribution zone includes 63 chips 111 arranged in 21 rows and 3 columns, and 3 chips 111 in each row in the first distribution zone are connected in parallel to constitute 1 power taking unit 114, so the first distribution zone includes 21 power taking units 114. The second distribution zone includes 57 chips 111 arranged in 19 rows and 3 columns, and 3 chips 111 in each row in the second distribution zone are connected in parallel to constitute 1 power taking unit 114, so the second distribution zone includes 19 power taking units 114. Of course, the maximum value Y of the number of row chips can also divide the chip array into more than two distribution zones. The number of distribution zones is not limited in the present application.

Further, in a case that the chip row direction is the heat dissipation direction, the number of chip columns in each distribution zone is the same; and in a case that the chip column direction is the heat dissipation direction, the number of chip rows in each distribution zone is the same. For example, in the example of FIG. 1B, the chip row direction is the heat dissipation direction, and the numbers of columns in both the first distribution zone and the second distribution zone are 3. A similar situation also exists in FIG. 1B and FIGS. 3 to 17.

In an implementation, along a heat dissipation direction, the number of the power taking units 114 within a plurality of distribution zones decreases. Exemplarily, as shown in FIG. 1B, the number of the power taking units 114 in the first distribution zone is 21, and the number of the power taking units 114 in the second distribution zone is 19. Of course, the present application is not limited to this. In a case where the number of the power taking units 114 in a distribution zone is greater than 2, the numbers of the power taking units 114 within the adjacent distribution zones do not decrease one by one, and the numbers of the power taking units 114 within several adjacent distribution zones are allowed to increase along the heat dissipation direction, as long as the spacings of the adjacent distribution zones are generally in an increasing trend along the left-right direction. The number of the distribution zones is 6 for illustration. Along the left-right direction, the numbers of the power taking units 114 in the plurality of distribution zones may respectively be 15, 14, 13, 12, 11, and 10; alternatively, the number of the power taking units 114 in the plurality of distribution zones may respectively be 12, 12, 11, 11, 10, and 10; still alternatively, the number of the power taking units 114 in the plurality of distribution zones may respectively be 11, 10, 10, 10, 10, and 10; yet alternatively, the number of the power taking units 114 in the plurality of distribution zones may respectively be 16, 15, 13, 14, 12, and 10. In this way, a total number of the chips in a first half part close to an air inlet is greater than a total number of the chips in a second half part close to an air outlet, which can reduce the maximum temperature difference between the chips 111 close to the air outlet and the chips 111 close to the air inlet, thereby improving the temperature equalization of the chips 111.

In an implementation, a rectangular area of the circuit board 110 occupied by the chip array is divided into a plurality of sub-areas.

It can be understood that the chip array is divided into the plurality of sub-areas because of the existence of chip vacant positions 113, so that spacings of at least some of the adjacent sub-areas are greater than or equal to a spacing for accommodating one chip.

As shown in FIG. 1B, there are chip vacant positions 113 between the 9th and 10th rows of the chips in the right three columns in the chip array, thereby dividing the chips in the left three columns in a sub-area, dividing the chips in the right three columns from the 1st to 9th rows in a sub-area, and dividing the chips in the right three columns from the 10th to 19th rows in a sub-area, namely, the chip vacant positions 113 divide the chip array into 3 sub-areas.

As shown in FIG. 2A, there are chip vacant positions 113 between the 7th and 8th rows and between 12th and 13th rows of the chips in the right three columns in the chip array, thereby dividing the chips in the left three columns in a sub-area, dividing the chips in the right three columns from the 1st to 7th rows in a sub-area, dividing the chips in the right three columns from the 8th to 12th rows in a sub-area, and dividing the chips in the right three columns from the 13th to 19th rows in a sub-area, namely, the chip vacant positions 113 divide the chip array into 4 sub-areas.

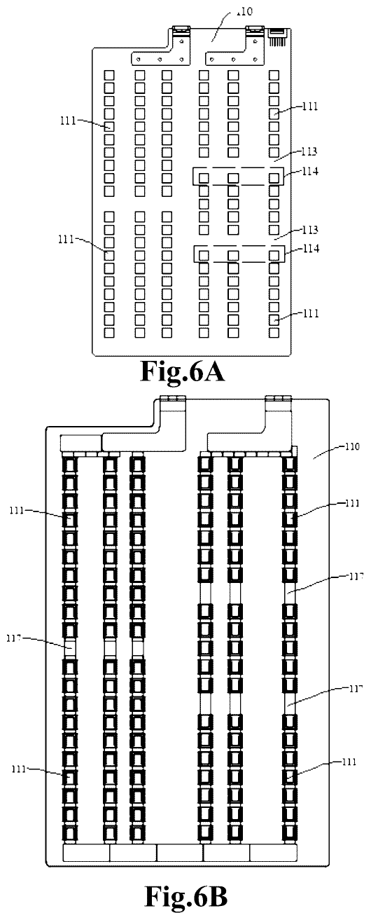

As shown in FIG. 6A, there are chip vacant positions 113 between the 10th and 11th rows of the chips in the left three columns in the chip array, and there are chip vacant positions 113 between the 7th and 8th rows and between the 12th and 13th rows of the chips in the right three columns in the chip array, thereby the left three columns of the chips from the 1st to 10th rows into a sub-area, diving the left three columns of the chips from the 11th to 20th rows into a sub-area, dividing the chips in the right three columns from the 1st to 7th rows in a sub-area, dividing the chips in the right three columns from the 8th to 12th rows in a sub-area, and dividing the chips in the right three columns from the 13th to 19th rows in a sub-area, namely, the chip vacant positions 113 divide the chip array into 5 sub-areas.

A sub-area is composed of at least one power taking unit 114, distances between some two adjacent sub-areas are greater than distances between the adjacent power taking units 114 within the sub-area, and the power taking unit 114 includes at least one chip 111. In a case that the power taking unit 114 includes a plurality of chips 111, the chips 111 in the power taking unit 114 are in the same row or the same column and are connected in parallel. A chip parallel connection direction of each sub-area is the same, and along a direction perpendicular to the chip parallel connection direction, spacings of at least some of the adjacent sub-areas are not equal to spacings of the adjacent power taking units 114 within any sub-area. A sub-area includes a plurality of power taking units 114 that are connected in series. A chip series connection direction of each sub-area is the same, and along the chip series connection direction, spacings of at least some of the adjacent sub-areas is not equal to spacings of the adjacent power taking units 114 within any sub-area. The chips 111 between the sub-areas can be disposed along the row and column directions with equal spacings or unequal spacings or with increasing spacings or decreasing spacings, but spacings of at least some of the adjacent sub-areas will be different from spacings of the adjacent chips contained within a sub-area due to the existence of chip vacant positions 113. It needs to be explained that the electrical connection manner of the chips 111 in the above embodiments is not merely limited to series connection and parallel connection, and other electrical connection manners such as a combination of series connection and parallel connection may also be made between the chips.

Optionally, the numbers of the power taking units 114 in at least two sub-areas may be equal or unequal. A maximum value of the number of column chips in the chip array is X, and based on X, an area of the circuit board occupied by the chip array can be divided into a plurality of sub-areas. In the example of FIG. 1B, X is 21, and based on X, the 1st to 9th power taking units 114 in the second distribution zone can be divided in a sub-area, which includes 27 chips arranged in 9 rows and 3 columns; and the 10th to 19th power taking units 114 can be divided in another sub-area, which includes 30 chips arranged in 10 rows and 3 columns. Thus, in the up-down direction, the 19 power taking units 114 in the second distribution zone are partitioned, so as to divide the 19 power taking units 114 into two sub-areas. Power taking units 114 in each sub-area can be arranged with equal spacings, and a spacing between the two sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips in the center location within each sub-area, and, in turn, reducing the temperature difference between the plurality of chips 111 within the sub-area.

Of course, the present application is not limited to this. A height of the area of the circuit board occupied by the chip array in a perpendicular heat dissipation direction is H, and the area of the circuit board occupied by the chip array can also be divided into a plurality of sub-areas based on H.

Further, the plurality of sub-areas include two end areas and one middle area, and heights of both the two end areas and one middle area are H/3. For example, at this time, the numbers of rows in each end area and the middle area can be equal. The heights of the above areas are not limited to H/3. Based on the height being H, heights of the end areas can also be set to be H/4, and a height of the middle area can be set to be H/2. The present application does not make specific limitations here, as long as the power taking units 114 can be divided into different sub-areas according to design requirements, and the distances between at least some of the adjacent power taking units 114 are not equal, so as to achieve formation of a heat dissipation channel, which is beneficial to the heat dissipation of the circuit board 110.

In an implementation, as shown in FIGS. 2A-2C, the plurality of sub-areas include two end areas and one middle area, and the number of the power taking units 114 in the end areas is greater than the number of the power taking units 114 in the middle area. For example, in FIG. 2A, based on a spacing between the 7th power taking unit 114 and the 8th power taking unit 114 and a spacing between the 12th power taking unit 114 and the 13th power taking unit 114, the 1st to 7th power taking units 114 in the second distribution zone can be divided in a first sub-area, which includes 21 chips 111 arranged in 7 rows and 3 columns; the 8th to 12th power taking units 114 are divided in a second sub-area, which includes 15 chips 111 arranged in 5 rows and 3 columns; and the 13th to 19th power taking units 114 are divided in a third sub-area, which also includes 21 chips 111 arranged in 7 rows and 3 columns. The number of the power taking units 114 in the end areas is 7, and the number of the power taking units 114 in the middle area is 5.

In an implementation, as shown in FIGS. 2A-2C, the number of the power taking units 114 increases from the middle area to the end areas. For example, in FIG. 2A, the number of the power taking units 114 in the end areas is 7, and the number of the power taking units 114 in the middle area is 5. The number of the chips in the end areas is 21, and the number of the chips in the middle area is 15. Thus, in a case where the circuit board 110 is applied to the electronic device 3100, since the chips in the two end areas are closer to the external environment and the heat dissipation is better, by disposing a large number of the chips 111 in the end areas and a small number of the chips 111 in the middle area, the chip temperature in the middle area can be effectively reduced, thereby decreasing the temperature difference between the chips 111 in the middle area and the chips 111 in the end areas, improving the heat dissipation effect of the circuit board 110, and ensuring the overall performance of the circuit board 110.

In an implementation, the plurality of sub-areas include two end areas and one middle area, and the number of the chips corresponding to the end areas is greater than or equal to a total number of the chips in the middle area. For example, in FIG. 2A, chips in the end areas are chips 111 in the first sub-area and chips 111 in the third sub-area, and chips 111 in the middle area are chips 111 in the second sub-area. The first sub-area and the third sub-area include 21 chips 111 respectively, and the second sub-area includes 15 chips 111, and the number of the chips corresponding to the end areas is greater than the total number of the chips in the middle area. Thus, the chip temperature in the middle area can be further reduced, thereby reducing the temperature difference between the chips 111 in the middle area and the chips 111 in the end areas, improving the heat dissipation effect of the circuit board 110, and ensuring the overall performance of the circuit board 110.

In an implementation, an average chip spacing in the end areas is smaller than an average chip spacing in the middle area. With such an arrangement, in the case where the circuit board 110 is applied to the electronic device 3100, since the chips 111 in the two end areas are closer to the external environment and the heat dissipation is better, by making the chips 111 in the end areas denser and the chips 111 in the middle area sparser, the chip temperature in the middle area can also be effectively reduced, thereby decreasing the temperature difference between the chips 111 in the middle area and the chips 111 in the end areas, improving the heat dissipation effect of the circuit board 110, and ensuring the overall performance of the circuit board 110.

In an implementation, as shown in FIG. 5 or FIG. 9 or FIG. 14 or FIG. 15, the two end areas include a first end area and a second end area, and the number of the power taking units 114 in the first end area is less than the number of the power taking units 114 in the second end area, wherein in a perpendicularly placed state of the circuit board 110, the first end area is close to a top of the circuit board 110, and the second end area is close to a bottom of the circuit board 110. In this way, since the end area provided close to the top can better exchange heat with the external environment, the above arrangement can reduce the total heat generation of the chips 111 in the second end area, thereby effectively reducing the chip temperature in the second end area, in turn decreasing the temperature difference between the chips 111 in the first end area and the chips 111 in the second end area, and improving the heat dissipation effect of the circuit board 110.

In addition, due to the chimney effect, some hot wind with a low density flows to an upper portion of the circuit board 110, and the chips 111 in the upper portion are hence decreased so as to decrease the heat generation while leaving more heat dissipation areas, so that an upper area can better exchange heat with the external environment, which, in turn, decreases the temperature difference between the chips 111 in the upper area and the chips 111 in a lower area, and improving the heat dissipation effect of the circuit board 110.

In an implementation, metal pieces are provided between the adjacent power taking units 114, and along a series connection direction, lengths of metal pieces between at least some of the adjacent power taking units 114 are longer than those between other adjacent power taking units 114, wherein a length direction is perpendicular to a parallel connection direction of the power taking units 114. Exemplarily, in conjunction with FIGS. 2A-2C, the length direction is an up-down direction. A spacing between the 7th power taking unit 114 and the 8th power taking unit 114 on the right and a spacing between the 12th power taking unit 114 and the 13th power taking unit 114 can be greater than spacings of other adjacent power taking units 114, and therefore, in the up-down direction, a length of a metal piece between the 7th power taking unit 114 and the 8th power taking unit 114 on the right and a length of a metal piece between the 12th power taking unit 114 and the 13th power taking unit 114 are longer than lengths of metal pieces between other adjacent power taking units 114. A similar situation also exists in the circuit boards 110 of FIGS. 1B, FIGS. 3 to 17, and FIGS. 19A to 21B. Similarly, the above other adjacent power taking units 114 are adjacent power taking units 114 in the same row or the same column; and in a direction perpendicular to the parallel connection direction, the other adjacent power taking units 114 are non-edge power taking units 114 in the chip array.

In the above arrangement, the lengths of the metal pieces are increased, so that the power taking units 114 make space to form a heat dissipation duct, and a spacing between two power taking groups can be greater than spacings of the adjacent power taking units 114 in each power taking group, thereby making distances between the chips in two ends within each power taking group in the series connection direction and the chips in a center location small, effectively reducing the temperature of the chips in the center location within each power taking group, and, in turn, reducing the temperature difference between a plurality of chips within the power taking group.

Optionally, the metal piece may be a copper sheet or an aluminum sheet, which is welded on the circuit board 110 for dissipating heat for two adjacent working chips connected therewith and reducing the voltage drop between the two adjacent working chips connected therewith. Thus, the working stability and reliability of the working chips are improved. Exemplarily, a thickness of the metal piece is less than or equal to a thickness of the chip. A thickness direction of the metal piece and a thickness direction of the chip are perpendicular to a direction of the circuit board 110.

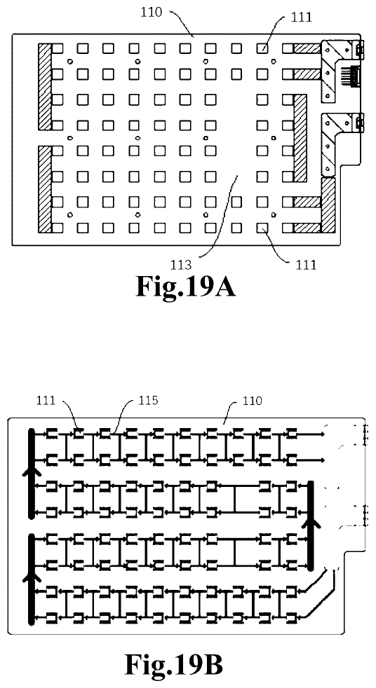

In an implementation, as shown in FIG. 1B, a chip row direction can be the parallel connection direction of the plurality of chips 111 (e.g., the left-right direction in FIG. 1B). A similar situation also exists in the circuit boards 110 of FIGS. 2A to 17. Of course, the chip row direction may also be perpendicular to the parallel connection direction of the chips 111 (e.g., the left-right direction in FIG. 19A).

In an implementation, a chip row direction is the heat dissipation direction (e.g., the left-right direction in FIG. 1B), at which time a chip column direction is perpendicular to the heat dissipation direction. A similar situation also exists in the circuit boards 110 of FIGS. 2A to 17.

In an implementation, the parallel connection direction of the chip array is the heat dissipation direction (e.g., the left-right direction in FIG. 1B). A similar situation also exists in the circuit boards 110 of FIGS. 2A to 17.

In an implementation, a working temperature difference between the chips 111 of the chip array ranges from 0 to 10 °C. (with the endpoint values included). For example, in a case where the heat dissipation source is a fan, when a speed of the fan is 4000 rpm, a temperature difference between the chips 111 can be 8 to 10 °C (with the endpoint values included). Of course, the above working temperature difference range is not merely limited to 0 to 10 °C.

In an implementation, a temperature difference between a highest temperature and a lowest temperature of the chips on the circuit board ranges from 5 to 12 °C (with the endpoint values included), as long as the present application can achieve the reduction of the temperature difference between the plurality of chips relative to the arrangement form of the power taking units 114 in FIG. 1A. For example, a temperature difference of the chips in the arrangement form in FIG. 1A is 20 to 40 °C (with the endpoint values included), while a temperature difference of the chips in the arrangement forms of the power taking units 114 in FIGS. 1B to 21B of the present application is 10 to 20 °C. (with the endpoint values included).

In an implementation, centers of the chips in each row or the chips in each column are on the same straight line. For example, in the example of FIG. 1B, 120 chips in the chip array are arranged in 21 rows and 6 columns, centers of the chips in each row are on a straight line, and centers of the chips in each column are on a straight line. Row spacings of the chips in first 3 columns are the same, and the 10th and 11th rows of the chips in second 3 columns are missing. The number of the chips in the first 3 columns is 63, and the number of the chips in the second 3 columns is 57. A row direction of the chip array can be a heat dissipation direction. In this way, a total number of the chips in a first half part close to an air inlet is greater than a total number of the chips in a second half part close to an air outlet. The number of the chips 111 at the air inlet is large, which can increase the heat generation of the chips 111 at the air inlet, and the number of the chips 111 at the air outlet is small, which can decrease the heat generation of the chips 111 at the air outlet, so that the maximum temperature difference between the chips 111 close to the air outlet and the chips 111 close to the air inlet can be further reduced, thereby improving the temperature equalization of the chips 111. A similar situation also exists in the circuit boards 110 of FIGS. 2A to 21B.

In an implementation, a total number of the number of the chips and the number of the vacant positions 113 in the chip array is X*Y. For example, in the example of FIG. 1B, X is 21 and Y is 6. A total number of the number of the chips and the number of the vacant positions 113 in the chip array is 126. Among them, the number of the chips in the chip array is 120, and the number of the vacant positions 113 is 6.

In an implementation, a maximum value Y of the number of row chips divides the chip array into at least two distribution zones.

Exemplarily, if Y is an even number, a total chip number A in a first Y/2 column(s) of the chip array is greater than a total chip number B in a second Y/2 column(s) of the chip array. For example, in FIG. 1B, Y is an even number 6, the total chip number in first 3 columns of the chip array is 63, and the total chip number in second 3 columns of the chip array is 57.

If Y is an odd number, a total chip number C in a first (Y−1)/2 column(s) of the chip array is greater than a total chip number D in a second (Y−1)/2 column(s) of the chip array. For example, Y being 7 is taken as an example for illustration. At this time, the total chip number C in the first 3 columns of the chip array is greater than the total chip number D in the second 3 columns of the chip array. In this way, a total number of the chips in a first half part close to an air inlet is greater than a total number of the chips in a second half part close to an air outlet, which can reduce the maximum temperature difference between the chips 111 close to the air outlet and the chips 111 close to the air inlet, thereby improving the temperature equalization of the chips 111.

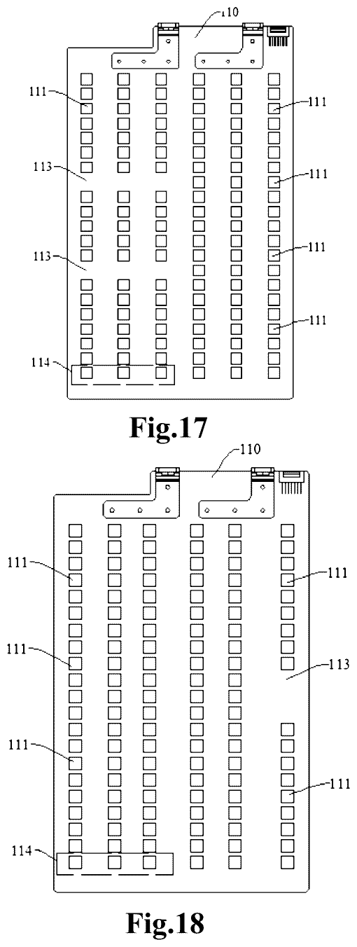

Alternatively, if Y is an even number, a total chip number A in a first Y/2 column(s) and corresponding column(s) of the chip array can also be less than a total chip number B in a second Y/2 column(s) and corresponding column(s) of the chip array. For example, in FIG. 17, Y is an even number 6, the total chip number in the first 3 columns of the chip array is 57, and the total chip number in the second 3 columns of the chip array is 63.

If Y is an odd number, a total chip number C in a first (Y−1)/2 column(s) and corresponding column(s) of the chip array can also be less than a total chip number D in a second (Y−1)/2 column(s) and corresponding column(s) of the chip array. For example, Y being 7 is taken as an example for illustration. At this time, the total chip number C in the first 3 columns of the chip array can be less than the total chip number D in the second 3 columns of the chip array.

Of course, the present application is not limited to this. If Y is an even number, a total chip number A in a first Y/2 column(s) and corresponding column(s) of the chip array can also be equal to a total chip number B in a second Y/2 column(s) and corresponding column(s) of the chip array. For example, in the example of FIG. 12, Y is an even number 6, the total chip number in the first 3 columns of the chip array is 57, and the total chip number in the second 3 columns of the chip array is 57.

If Y is an odd number, a total chip number C in a first (Y−1)/2 column(s) and corresponding column(s) of the chip array can also be equal to a total chip number D in a second (Y−1)/2 column(s) and corresponding column(s) of the chip array. For example, Y being 7 is taken as an example for illustration. At this time, the total chip number C in the first 3 columns of the chip array can be equal to the total chip number D in the second 3 columns of the chip array.

The present application further provides a working assembly 2100, including a circuit board 110 and a heat sink 2110. The circuit board 110 is the circuit board 110 in any one of the above implementations, and the heat sink 2110 includes a heat dissipation body and heat dissipation fins, the heat dissipation body including a first surface and a second surface opposite to each other, and the first surface connected with the heat dissipation fins.

Exemplarily, the heat sink 2110 can be an air-cooled heat sink 2110 or a liquid-cooled heat sink 2110. The heat sink 2110 can be located on a side of the circuit board 110 where working chips are provided, for dissipating heat for the circuit board 110. The heat sink 2110 can also be located on a side of the circuit board 110 where no chips are provided. Alternatively, chips are provided on both sides of the circuit board 110, and the heat sink 2110 is respectively provided on both sides of the circuit board 110.

In an implementation, the second surface is provided with a plurality of bosses, each provided corresponding to each row of the power taking units 114 or each column of the power taking units 114. In this way, the heat generated in a working process of the chips in the power taking units 114 can be effectively conducted to the heat sink 2110 through the bosses, thereby improving the heat dissipation effect.

Alternatively, in another implementation, the second surface is provided with a plurality of bosses, and at least some of the bosses can also be provided at corresponding locations between at least some of the adjacent power taking units 114. For example, in FIG. 3, 117 chips on the circuit board 110 are arranged in multiple rows, and a row direction is parallel to a direction from an air inlet to an air outlet of a heat dissipation duct. The number of the chips in the 6th row, the 11th row, and the 16th row is 3 respectively, and the number of the chips in other rows is 6, so the number of the chips in the 6th row, the 11th row, and the 16th row is less than the number of the chips in the other rows. At least some of the bosses can be provided at corresponding locations between the 5th power taking unit 114 and the 6th power taking unit 114, corresponding locations between the 9th power taking unit 114 and the 10th power taking unit 114, and corresponding locations between the 13th power taking unit 114 and the 14th power taking unit 114 in the second distribution zone

An embodiment of the present application provides a circuit board 110, provided with a chip array including a plurality of chips 111 and at least one vacant position 113. In the description of the present application, the meaning of “plurality” is two or more.

The chip array can include two chip 111 connection manners: series connection and parallel connection. For example, as shown in FIG. 1B, the chip array includes 120 chips 111 and 6 vacant positions 113. The three columns on the left in the chip array include 63 chips 111, and no vacant positions 113 are provided in the three columns on the left. The right three columns on the in the chip array include 57 chips 111, and a total of 6 vacant positions 113 are provided in 2 rows between the 9th row of the chips 111 and the 10th row of the chips 111 on the right counted from top to bottom in the right three columns.

That is to say, in FIG. 1B, the chip array includes a plurality of chips 111 and at least one vacant position 113, and a similar situation also exists in the circuit boards 110 of FIGS. 2A to 21B. Thus, a heat dissipation channel is formed at the vacant positions 113 of the chip array, which is beneficial to the heat dissipation of the circuit board 110.

In an implementation, the chips 111 in the chip array are of the same size, and a total number of the chips 111 in the chip array is greater than or equal to 20 or 50. For example, in the example of FIG. 1B, each chip 111 is rectangular, and a total number of the chips 111 in the chip array is 120. Therefore, in FIG. 1B, the chips 111 in the chip array are of the same size, and the total number of the chips 111 in the chip array is greater than or equal to 20 or 50. A similar situation also exists in the circuit boards 110 of FIG. 2A to FIG. 21B.

In this embodiment, by making the chips 111 in the chip array the same in size, the versatility of the chips 111 can be improved, and the processing can be convenient; by making the total number of the chips 111 in the chip array greater than or equal to 20 or 50, the total number of the chips 111 in the chip array is large, which can improve the computing power of the circuit board 110, and thereby improve the overall performance of the circuit board 110.

In an implementation, a size of the vacant position 113 is greater than or equal to a size of a single chip 111 in the chip array, at which time a space corresponding to the vacant position 113 can accommodate at least one chip 111. The “size of the vacant position 113” includes a length and/or width of the vacant position 113. With such an arrangement, the heat dissipation channel at the vacant position 113 of the chip array is large in size, which can reduce wind resistance and improve the heat dissipation effect.

In an implementation, spacings of at least some of the adjacent chips 111 in the chip array are not equal.

In an example, the at least one vacant position 113 is provided in a row direction of the chip array, so that there is an unequal spacing between adjacent chips 111 in at least one row of the chips 111 in the chip array. For example, in conjunction with FIG. 19A, the row direction is a left-right direction. The chip array includes 76 chips 111 and 4 vacant positions 113. The 4 vacant positions 113 are respectively located in the 3rd row and the 3rd column, the 4th row and the 3rd column, the 5th row and the 3rd column, and the 6th row and the 3rd column. Thus, a distance between the second chip 111 and the third chip 111 counted from right to left in the third row is greater than distances between the remaining adjacent chips 111; a distance between the second chip 111 and the third chip 111 counted from right to left in the fourth row is greater than distances between the remaining adjacent chips 111; a distance between the second chip 111 and the third chip 111 counted from right to left in the fifth row is greater than distances between the remaining adjacent chips 111; and a distance between the second chip 111 and the third chip 111 counted from right to left in the sixth row is greater than distances between the remaining adjacent chips 111.

In another example, the at least one vacant position 113 is located in a column direction of the chip array, so that there is an unequal spacing between adjacent chips 111 in at least one column of the chips 111 in the chip array. For example, as shown in FIG. 18, the row direction is a left-right direction. The chip array includes 123 chips 111 and 3 vacant positions 113. The three vacant positions 113 are respectively located in the 10th to 12th rows in the 6th column counted from left to right. Thus, a distance between the 9th chip 111 and the 10th chip 111 counted from top to bottom in the 6th row is greater than distances between the remaining adjacent chips 111.

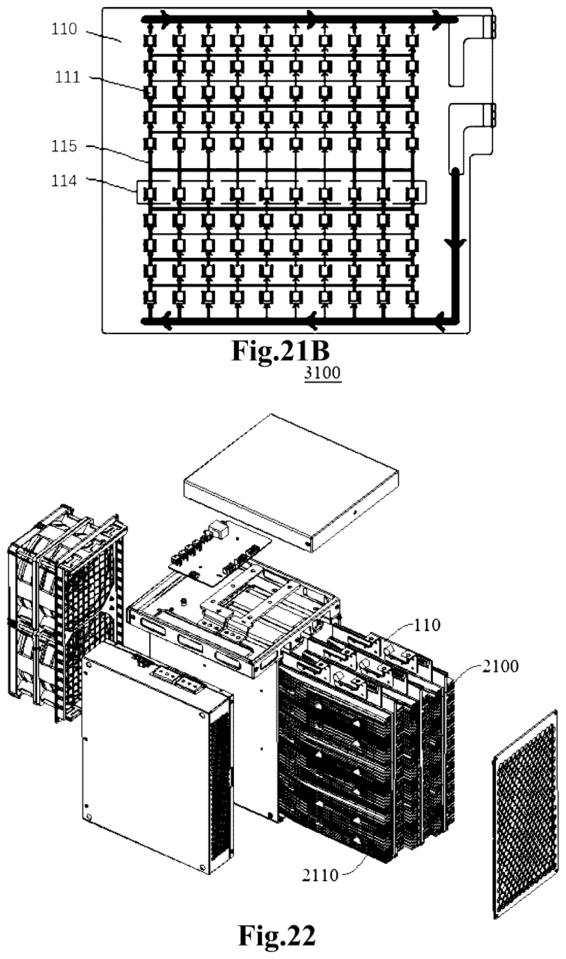

In an implementation, the chip array includes a plurality of power taking units 114, and a connection manner of the chips 111 in a power taking unit 114 is parallel connection. For example, as shown in FIG. 1B, the chip array includes 40 power taking units 114 that are connected in series. Each power taking unit 114 includes 3 chips 111 connected in parallel, so that there are 21 power taking units 114 on the left and 19 power taking units 114 on the right. Among them, a distance between the 9th and 10th power taking units 114 counted from top to bottom on the right is not equal to distances between other adjacent power taking units 114. As shown in FIG. 21B, the chip array includes 10 power taking units 114 that are connected in series. Each power taking unit 114 includes 10 chips 111 connected in parallel, so that there are 5 power taking units 114 on the upper side and 5 power taking units 114 on the lower side. Among them, a distance between the 5th and 6th power taking units 114 counted from top to bottom is not equal to distances between other adjacent power taking units 114.

In an implementation, a total number of the vacant positions 113 is an integer multiple of the number of the chips 111 contained in one of the power taking units 114. Exemplarily, the total number of the chips 111 in the chip array can be an integer multiple of the number of the power taking units 114. For example, as shown in FIG. 1B, the chip array includes 120 chips 111 and 6 vacant positions 113, the number of the chips 111 contained in one of the power taking units 114 is 3, and the total number of the vacant positions 113 is 2 times the number of the chips 111 contained in the power taking unit 114. As shown in FIG. 21B, the chip array includes 100 chips 111 and 10 vacant positions 113. The number of the chips 111 contained in one of the power taking units 114 is 10, and the total number of the vacant positions 113 is 1 times the number of the chips 111 contained in the power taking unit 114.

In an implementation, in a direction perpendicular to a chip 111 parallel connection direction of the chip array, a length of an electrical connection line between two power taking units 114 adjacent to the vacant position 113 forwardly and rearwardly is longer than lengths of electrical connection lines between other adjacent power taking units 114, wherein a length direction is perpendicular to the chip 111 parallel connection direction of the chip array. For example, in conjunction with FIGS. 2A-2C, the chip 111 parallel connection direction is a left-right direction, and the direction perpendicular to the chip 111 parallel connection direction of the chip array is an up-down direction. The electrical connection line may include a power line 115 and/or a signal line 116. Exemplarily, in conjunction with FIGS. 2A-2C, in the up-down direction, a spacing between the 7th power taking unit 114 and the 8th power taking unit 114 on the right and a spacing between the 12th power taking unit 114 and the 13th power taking unit 114 can be greater than spacings of other adjacent power taking units 114, and therefore, in the up-down direction, a length of an electrical connection line between the 7th power taking unit 114 and the 8th power taking unit 114 on the right and a length of an electrical connection line between the 12th power taking unit 114 and the 13th power taking unit 114 are longer than lengths of electrical connection lines between other adjacent power taking units 114. A similar situation also exists in the circuit boards 110 of FIGS. 1B, FIGS. 3 to 17, and FIGS. 19A to 21B.

Further, the above other adjacent power taking units 114 are in the same row or the same column. For example, in the examples of FIGS. 2A-2C, the above other adjacent power taking units 114 can be non-edge power taking units 114 in the chip array in the direction perpendicular to the parallel connection direction of the power taking units 114. For example, they can be adjacent power taking units 114 in the 1st to 7th power taking units 114 provided in the same column on the right, adjacent power taking units 114 in the 8th to 12th power taking units 114 provided in the same column on the right, and adjacent power taking units 114 in the 13th to 19th power taking units 114 provided in the same column on the right. A similar situation also exists in the circuit boards 110 of FIG. 1B, FIGS. 3 to 17, and FIGS. 19A to 21B.

In an implementation, the chip array is set to be X*Y, a maximum value of the number of column chips in a column direction of the chip array is X, and a maximum value of the number of row chips in a row direction of the chip array is Y. A total number of the number of the chips 111 and the number of the vacant positions 113 in the chip array is X*Y. For example, in the example of FIG. 1B, X is 21 and Y is 6. A total number of the number of the chips 111 and the number of the vacant positions 113 in the chip array is 126. Among them, the number of the chips 111 in the chip array is 120, and the number of the vacant positions 113 is 6.

In an implementation, the maximum value Y of the number of row chips divides the chip array into at least two parts, and a total number of the chips 111 in each part is not completely equal.

Exemplarily, in conjunction with FIG. 1B, the maximum value 6 of the number of row chips divides the chip array into two parts, which are a first part (e.g., the left three columns of the chips 111 in FIG. 1B) and a second part (e.g., the right three columns of the chips 111 in FIG. 1B), with the numbers of the power taking units 114 within the first part and the second part not equal. Specifically, the first part includes 63 chips 111 arranged in 21 rows and 3 columns, and 3 chips 111 in each row in the first part are connected in parallel to constitute 1 power taking unit 114, so the first part includes 21 power taking units 114. The second part includes 57 chips 111 arranged in 19 rows and 3 columns, and 3 chips 111 in each row in the second part are connected in parallel to constitute 1 power taking unit 114, so the second part includes 19 power taking units 114. Of course, the maximum value Y of row chips 111 can also divide the chip array into more than two parts. The number of parts is not limited in the present application.

In an implementation, the maximum value Y of the number of row chips divides the chip array into at least two parts, and along a heat dissipation direction, the total number of the chips 111 in each part decreases. Exemplarily, the circuit board 110 can be applied to an electronic device 3100, such as a computing device. A heat dissipation duct is defined within the electronic device 3100, and the circuit board 110 can work within the heat dissipation duct. A heat dissipation direction of the circuit board 110 is a direction from an air inlet to an air outlet of the heat dissipation duct. A heat dissipation source of the circuit board 110 can be an air-cooled heat dissipation source (e.g., a fan) or a liquid-cooled heat dissipation source. For example, in FIG. 1B, the heat dissipation direction is a direction from left to right. Along the direction from left to right, a total number of the chips 111 in the first part is 63, and a total number of the chips 111 in the second part is 57, namely, the total number of the chips 111 in each part decreases.

Of course, the present application is not limited to this. In a case where the number of the parts is greater than 2, the total numbers of the chips 111 within the adjacent parts are not merely limited to decreasing one by one, and the total numbers of the chips 111 within several adjacent parts are allowed to increase along the heat dissipation direction, as long as the total numbers of the chips 111 within the parts are generally in a decreasing trend along the left-right direction. The number of the parts is 6 for illustration. Along the left-right direction, the total numbers of the chips 111 in a plurality of parts can respectively be 25, 24, 23, 22, 21, and 20; alternatively, the total numbers of chips 111 of the plurality of parts can respectively be 22, 22, 21, 21, 20, and 20; still alternatively, the numbers of the power taking units 114 in the plurality of parts can respectively be 21, 20, 20, 20, 20, and 20; yet alternatively, the numbers of the power taking units 114 within the plurality of parts can respectively be 26, 25, 23, 24, 22, and 20. In this way, a total number of the chips 111 in a first half part close to the air inlet is greater than a total number of the chips 111 in a second half part close to the air outlet, which can reduce the maximum temperature difference between the chips 111 close to the air outlet and the chips 111 close to the air inlet, thereby improving the temperature equalization of the chips 111.

In an implementation, the maximum value Y of the number of row chips divides the chip array into at least two parts, and the number of rows or columns in each part is not completely equal and/or a chip 111 layout of each part is asymmetric. For example, in FIG. 1B, the maximum value Y of the number of row chips is 6, and the maximum value Y of the number of row chips divides the chip array into a first part and a second part. Among them, the first part includes 63 chips 111 arranged in 21 rows and 3 columns, and the second part includes 57 chips 111 arranged in 19 rows and 3 columns. The numbers of rows in the first part and the second part are not equal, and chip 111 layouts of the parts are asymmetric.

In an implementation, the maximum value Y of the number of row chips equally divides the chip array into two parts, and along a heat dissipation direction, an average column spacing of a first half part is less than an average column spacing of a second half part. It needs to be explained that the above “equally divides” refers to that quantitatively, the column number of the chips 111 is equally divided; and dimensionally, the circuit board 110 is not necessarily equally divided. In a case that Y is an even number, as shown in FIG. 1B, Y is an even number 6, at which time the numbers of columns of the first half part and the second half part are Y/2=3 respectively. In a case that Y is an odd number, the numbers of columns of the chips 111 in the first half part and the second half part can be (Y−1)/2 respectively. For example, in a case of Y being 7, the numbers of columns of the chips 111 in the first half part and the second half part are 3 respectively.

Thus, since the first half part of the heat dissipation direction is provided close to an air inlet, where an ambient temperature is relatively low, and the second half part of the heat dissipation direction is provided close to an air outlet, where an ambient temperature is relatively high, by making the average column spacing of the first half part less than the average column spacing of the second half part, a chip 111 density provided close to an air outlet can be relatively small, thereby decreasing the total heat generation of the chips 111 provided close to the air outlet, and, in turn, decreasing the temperature difference between the chips 111 in the first half part and the chips 111 in the second half part.

In an implementation, the maximum value Y of the number of row chips equally divides the chip array into two parts, and along a heat dissipation direction, the number of chip 111 rows and/or the number of the chips 111 and/or the number of the vacant positions 113 in a first half part are not equal to those in a second half part. For example, in the example of FIG. 1B, the first half part is a first part, and the second half part is a second part. The first part includes 63 chips 111 arranged in 21 rows and 3 columns, and the number of the vacant positions 113 in the first part is zero. The second part includes 57 chips 111 arranged in 19 rows and 3 columns, and the number of the vacant positions 113 in the second part is 6. Therefore, the numbers of chip 111 rows in the first half part and the second half part are different, the numbers of chips 111 are different, and the numbers of vacant positions 113 are not equal.

In an implementation, the maximum value Y of the number of row chips equally divides the chip array into two parts, and along a heat dissipation direction, the number of chip 111 rows and/or the number of the chips 111 in a first half part is greater than those in a second half part. For example, in the example of FIG. 1B, a first part includes 63 chips 111 arranged in 21 rows and 3 columns, and a second part includes 57 chips 111 arranged in 19 rows and 3 columns. Therefore, the number of chip 111 rows in the first half part is greater than that in the second half part, and the number of the chips 111 in the first half part is greater than that in the second half part. In this way, the total heat generation of the chips 111 provided close to an air outlet can be further decreased, and the temperature difference between the chips 111 in the first half part and the chips 111 in the second half part can be decreased in turn.

In an implementation, the maximum value Y of the number of row chips equally divides the chip array into two parts, and along a heat dissipation direction, the number of chip 111 rows and/or the number of the chips 111 in a first half part is equal to those in a second half part. For example, as shown in FIG. 12, a first part includes 57 chips 111 arranged in 19 rows and 3 columns, and a second part includes 57 chips 111 arranged in 19 rows and 3 columns. Therefore, the number of chip 111 rows in the first half part is equal to that in the second half part, and the number of the chips 111 in the first half part is equal to that in the second half part.

In an implementation, the maximum value Y of the number of row chips equally divides the chip array into two parts, and along a heat dissipation direction, the number of the vacant positions 113 in a first half part is less than or equal to that in a second half part. For example, in the example of FIG. 8, a first part includes 60 chips 111 and 3 vacant positions 113, and a second part includes 54 chips 111 and 9 vacant positions 113. Therefore, the number of the vacant positions 113 in the first half part is less than that in the second half part.

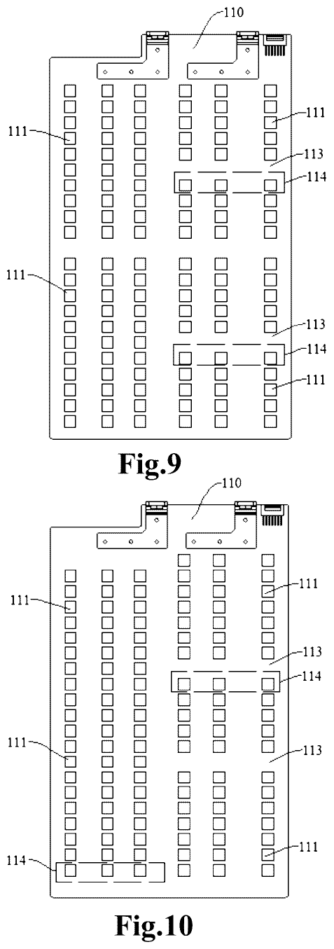

In an implementation, as shown in FIG. 9 and FIG. 12, the maximum value Y of the number of row chips equally divides the chip array into two parts, and along a heat dissipation direction, vacant positions 113 in at least some rows in a first half part and a second half part are on the same straight line. For example, in FIG. 9, the 11th row in a first part includes 3 vacant positions 113. The 6th row, the 11th row, and the 17th row in a second part respectively include 3 vacant positions 113. Among them, the vacant positions 113 in the first part and the vacant positions 113 in the 11th row in the second part are on the same straight line. In FIG. 12, the 8th row and the 14th row in a first part respectively include 3 vacant positions 113. The 8th row and the 14th row in a second part respectively include 3 vacant positions 113. Among them, the vacant positions 113 in the 8th row in the first part and the vacant positions 113 in the 8th row in the second part are on the same straight line, and the vacant positions 113 in the 14th row in the first part and the vacant positions 113 in the 14th row in the second part are on the same straight line.

In an implementation, the maximum value Y of the number of row chips equally divides the chip array into two parts, and along a heat dissipation direction, vacant positions 113 in at least some rows in a first half part and a second half part are not on the same straight line. For example, in FIG. 9, the 11th row in a first part includes 3 vacant positions 113. The 6th row, the 11th row, and the 17th row in a second part respectively include 3 vacant positions 113. Among them, the vacant positions 113 in the first part and the vacant positions 113 in the 11th row in the second part are on the same straight line, and the vacant positions 113 in the first part and the vacant positions 113 in the 6th row and the 17th row in the second part are not on the same straight line. In FIG. 6A, the 11th row in a first part includes 3 vacant positions 113. The 8th row and the 14th row in a second part respectively include 3 vacant positions 113. Among them, the vacant positions 113 in the first part and the vacant positions 113 in the second part are not on the same straight line.

Along a heat dissipation direction, the vacant position 113 is located on an upper edge and/or a lower edge of the chip array.

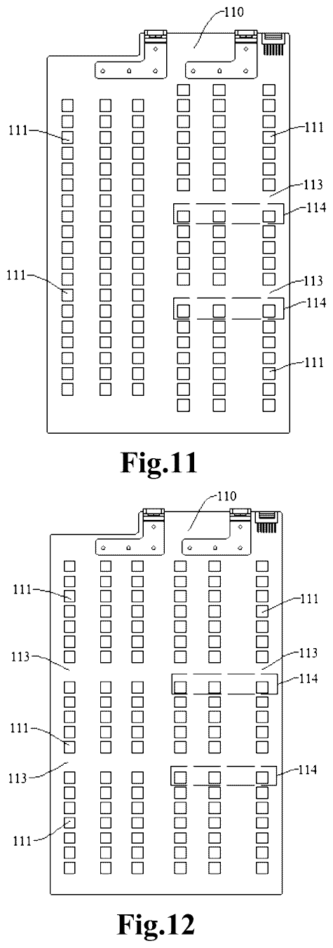

In an implementation, as shown in FIGS. 10 and 11, the maximum value Y of the number of row chips equally divides the chip array into two parts, and along a heat dissipation direction, vacant positions 113 are located on an upper edge and/or a lower edge of a first half part. The “upper edge of the first half part” refers to an upper edge of the first half part in a direction perpendicular to the heat dissipation direction; and the “lower edge of the first half part” refers to a lower edge of the first half part in the direction perpendicular to the heat dissipation direction.

For example, in the example of FIG. 10, a first half part includes a row of vacant positions 113 that is located on an upper edge of the first half part. In the example of FIG. 11, a first half part includes two rows of vacant positions 113 that are located on an upper edge and a lower edge of the first half part, respectively. With such an arrangement, the vacant positions 113 can form an air duct, which is beneficial to the heat dissipation of the chips 111 to further improve the heat dissipation effect.

In an implementation, an area of the circuit board 110 occupied by a chip array is divided into three areas in two ends and in the middle. For example, in FIG. 2A, based on a spacing between the 7th power taking unit 114 and the 8th power taking unit 114 and a spacing between the 12th power taking unit 114 and the 13th power taking unit 114, the 1st to 7th power taking units 114 in a second part can be divided in a first sub-area, which includes 21 chips 111 arranged in 7 rows and 3 columns; the 8th to 12th power taking units 114 are divided in a second sub-area, which includes 15 chips 111 arranged in 5 rows and 3 columns; and the 13th to 19th power taking units 114 are divided in a third sub-area, which also includes 21 chips 111 arranged in 7 rows and 3 columns. The number of the power taking units 114 in the end areas is 7, and the number of the power taking units 114 in the middle area is 5.

In an implementation, a total number of the chips 111 corresponding to the two end areas is greater than or equal to a total number of the chips 111 in the middle area. For example, in FIG. 2A, the 1st to 7th power taking units 114 in the second part are divided in a first sub-area, which includes 21 chips 111 arranged in 7 rows and 3 columns; the 8th to 12th power taking units 114 are divided in a second sub-area, which includes 15 chips 111 arranged in 5 rows and 3 columns; and the 13th to 19th power taking units 114 are divided in a third sub-area, which also includes 21 chips 111 arranged in 7 rows and 3 columns. Among them, the first sub-area and the second sub-area are the two end areas, and the second sub-area is the middle area. Therefore, a total number of the chips 111 corresponding to the two end areas is greater than a total number of the chips 111 in the middle area.

In this embodiment, in the case where the circuit board 110 is applied to the electronic device 3100, since the chips 111 in the two end areas are closer to the external environment and the heat dissipation is better, by disposing a large number of the chips 111 in the end areas and a small number of the chips 111 in the middle area, the chip 111 temperature in the middle area can be effectively reduced, thereby decreasing the temperature difference between the chips 111 in the middle area and the chips 111 in the end areas, improving the heat dissipation effect of the circuit board 110, and ensuring the overall performance of the circuit board 110.

In an implementation, an average row spacing of the chips 111 in the two end areas is less than an average row spacing of the chips 111 in the middle area. With such an arrangement, in the case where the circuit board 110 is applied to the electronic device 3100, since the chips 111 in the two end areas are close to the external environment and the heat dissipation is better, by making the average row spacing of the chips 111 in the two end areas less than the average row spacing of the chips 111 in the middle area, the chip 111 temperature in the middle area can also be effectively reduced, thereby decreasing the temperature difference between the chips 111 in the middle area and the chips 111 in the end areas, improving the heat dissipation effect of the circuit board 110, and ensuring the overall performance of the circuit board 110.

In an implementation, that the area of the circuit board 110 occupied by the chip array is divided into three areas in two ends and in the middle, includes: a maximum value of the number of column chips of the chip array is X, and based on X, the area of the circuit board occupied by the chip array is divided into three areas in two ends and in the middle. For example, in conjunction with FIG. 1B, by taking X (i.e., 21) as a partition basis, in an embodiment, the partition manner is an average partition to partition the circuit board 110 from top to bottom into three parts. 7 chips 111 in a column are correspondingly partitioned into a part, and then a total number of the chips 111 in a first part is 42, a total number of the chips 111 in a second part is 36, and a total number of the chips 111 in a third part is 42. A total number of the chips 111 in the first part (42) or the third part (42) close to the two ends of the circuit board 110 is greater than the number of the chips 111 in the intermediate second part (36); alternatively, in combination with FIG. 1B, the partition manner is to make the number of the chips 111 in the two end areas greater than the number of the chips 111 in the middle area. For example, the circuit board 110 can be partitioned from top to bottom into three parts, with 8 chips 111 from top to bottom in a column as a part, 5 chips 111 as a part, and 8 chips 111 as a part. Then a total number of the chips 111 in the first part is 48, a total number of the chips 111 in the second part is 24, and a total number of the chips 111 in the third part is 18.

Of course, the present application is not limited to this. In another implementation, that the area of the circuit board 110 occupied by the chip array is divided into three areas in two ends and in the middle, includes: a height of the area of the circuit board 110 occupied by the chip array is H in a perpendicular heat dissipation direction; and based on H, the area of the circuit board 110 occupied by the chip array is divided into three areas in two ends and in the middle. For example, in a case where the partition manner is average partition, heights of both two end areas and one middle area are H/3.

It needs to be explained that the area of the circuit board 110 occupied by the chip array may be divided into a plurality of areas, which may be divided according to actual conditions and are not limited to the three areas mentioned above.

It can be understood by those skilled in the art that the partition manner is not limited to the above records. In a case that the total number of the chips 111 in a first heat-generating column is an odd number or an even number, the manner of partition can be flexibly selected. Of course, the circuit board 110 can also be partitioned and divided by taking an overall area formed by edges of the chips 111 arranged thereon as a reference, which may be partitioned averagely, and, of course, may also be partitioned according to other proportions so as to make the total number of the chips 111 in each part meet preset distribution requirements.

In short, the arrangement manner of the chips 111 can be set in conjunction with heat dissipation conditions of various locations in the air duct. For example, if the ambient temperature of the air inlet is low and the overall heat dissipation efficiency is high, then more chips 111 can be disposed; and if the ambient temperature of the air outlet is high and the overall heat dissipation efficiency is low, then fewer chips 111 can be disposed, and a total number of the chips 111 close to the air outlet is less than a total number of the chips 111 at the air inlet. At the same time, in both upper and lower ends of the circuit board 110, in a direction perpendicular to a direction of wind, the temperatures at the two ends are lower than the temperature in the center of the circuit board 110, and then more chips 111 can be disposed in the two ends, while fewer chips 111 can be disposed in the center, and a total number of the chips 111 in the two ends is greater than a total number of the chips 111 in the center. Also, it can be divided into two parts, and the total number of the chips 111 in a lower half part is greater than the total number of the chips 111 in an upper half part. This is different from the design idea that usually changes the thermal resistance of the heat sink 2110 to achieve temperature equalization.

In an implementation, the two end areas include a first end area and a second end area, and the number of the chips 111 in the first end area is less than the number of the chips 111 in the second end area, wherein in a perpendicularly placed state of the circuit board 110, the first end area is close to a top of the circuit board 110, and the second end area is close to a bottom of the circuit board 110. In this way, since the end area provided close to the top can better exchange heat with the external environment, the above arrangement can decrease the total heat generation by the chips 111 in the second end area, thereby effectively reducing the chip 111 temperature in the second end area, in turn decreasing the temperature difference between the chips 111 in the first end area and the chips 111 in the second end area, and improving the heat dissipation effect of the circuit board 110.

In an implementation, in a direction perpendicular to a chip 111 parallel connection direction of the chip array, an area of the circuit board 110 occupied by a chip array is divided into three areas in two ends and in the middle. For example, in FIG. 2A, based on a spacing between the 7th power taking unit 114 and the 8th power taking unit 114 and a spacing between the 12th power taking unit 114 and the 13th power taking unit 114, the 1st to 7th power taking units 114 in a second part can be divided in a first sub-area, which includes 21 chips 111 arranged in 7 rows and 3 columns; the 8th to 12th power taking units 114 are divided in a second sub-area, which includes 15 chips 111 arranged in 5 rows and 3 columns; and the 13th to 19th power taking units 114 are divided in a third sub-area, which also includes 21 chips 111 arranged in 7 rows and 3 columns. The number of the power taking units 114 in the end areas is 7, and the number of the power taking units 114 in the middle area is 5.

In an implementation, the numbers of rows or columns of the corresponding chips 111 within the areas are the same. For example, in a case that a row direction of the chips 111 is the heat dissipation direction, the numbers of columns of the chips 111 in the parts are the same; and in a case that a column direction of the chips 111 is the heat dissipation direction, the numbers of rows of the chips 111 in the parts are the same. For example, in the example of FIG. 1B, the row direction of the chips 111 is the heat dissipation direction, and the numbers of columns of both the first part and the second part are 3. A similar situation also exists in FIG. 1B and FIGS. 3 to 17.

In an implementation, the numbers of the power taking units 114 corresponding to at least two areas are not equal. For example, in the example of FIG. 2A, the 1st to 7th power taking units 114 in a second part are divided in a first sub-area, which includes 21 chips 111 arranged in 7 rows and 3 columns; the 8th to 12th power taking units 114 are divided in a second sub-area, which includes 15 chips 111 arranged in 5 rows and 3 columns; and the 13th to 19th power taking units 114 are divided in a third sub-area, which also includes 21 chips 111 arranged in 7 rows and 3 columns. The number of the power taking units 114 in the end areas is 7, and the number of the power taking units 114 in the middle area is 5.

In an implementation, the number of the power taking units 114 in the areas increases from the middle area to the end areas. For example, in FIG. 2A, the number of the power taking units 114 in the end areas is 7, and the number of the power taking units 114 in the middle area is 5. Thus, in the case where the circuit board 110 is applied to the electronic device 3100, since the chips 111 in the two end areas are closer to the external environment and the heat dissipation is better, by disposing a large number of the chips 111 in the end areas and a small number of the chips 111 in the middle area, the chip 111 temperature in the middle area can be effectively reduced, thereby decreasing the temperature difference between the chips 111 in the middle area and the chips 111 in the end areas, improving the heat dissipation effect of the circuit board 110, and ensuring the overall performance of the circuit board 110.

In an implementation, each vacant position 113 corresponds to a welding pad 117. For example, a conductive metal piece can be provided corresponding to the vacant position 113, and the welding pad 117 is used for welding the conductive metal piece.

Optionally, the conductive metal piece may be a copper sheet or an aluminum sheet, which is welded on the welding pad 117 for dissipating heat for two adjacent working chips 111 connected therewith, and reducing the voltage drop between the two adjacent working chips 111 connected therewith. Thus, the working stability and reliability of the working chips 111 are improved. Exemplarily, a thickness of the conductive metal piece is less than or equal to a thickness of the chip 111. A thickness direction of the conductive metal piece and a thickness direction of the chip 111 are perpendicular to a direction of the circuit board 110.

In an implementation, an identical conductive metal piece cannot be shared on a plurality of consecutive vacant positions 113. For example, each vacant position 113 can correspond to a metal piece.

In an implementation, in an area of the circuit board 110 occupied by a chip array, in a direction perpendicular to a chip 111 parallel connection direction of the chip array, a length of a metal piece between two chips 111 adjacent to the vacant position 113 forwardly and rearwardly is longer than a length of a metal piece provided between adjacent chips 111 not spaced by the vacant position 113, wherein a long direction is perpendicular to the parallel connection direction. Exemplarily, the above adjacent chips 111 not spaced by the vacant position 113 may be in the same row or the same column, and the adjacent chips 111 not spaced by the vacant position 113 are non-edge chips 111 in the chip array in the direction perpendicular to the chip 111 parallel connection direction of the chip array. In conjunction with FIGS. 2A-2C, the length direction is an up-down direction, and the above adjacent chips 111 not spaced by the vacant position 113 are in the same column. A spacing between the 7th power taking unit 114 and the 8th power taking unit 114 on the right and a spacing between the 12th power taking unit 114 and the 13th power taking unit 114 can be greater than spacings of other adjacent power taking units 114, and therefore, in the up-down direction, a length of a metal piece between the 7th power taking unit 114 and the 8th power taking unit 114 on the right and a length of a metal piece between the 12th power taking unit 114 and the 13th power taking unit 114 are longer than lengths of metal pieces between other adjacent power taking units 114. A similar situation also exists in the circuit boards 110 of FIGS. 1B, FIGS. 3 to 17, and FIGS. 19A to 21B.

In an implementation, in an area of the circuit board 110 occupied by a chip array, in a direction perpendicular to a chip 111 parallel connection direction of the chip array, a length of a signal line 116 between two chips 111 adjacent to the vacant position 113 forwardly and rearwardly is longer than a length of a signal line between adjacent chips not spaced by the vacant position, wherein a long direction is perpendicular to the parallel connection direction; and/or, a length of a power line 115 between two chips 111 adjacent to the vacant position 113 is longer than a length of a power line 115 between adjacent chips 111 not spaced by the vacant position 113, wherein a long direction is perpendicular to the parallel connection direction.

Exemplarily, the adjacent chips 111 not spaced by the vacant position 113 may be in the same row or the same column. The adjacent chips 111 not spaced by the vacant position 113 are non-edge chips 111 in the chip array in the direction perpendicular to the chip 111 parallel connection direction of the chip array.

For example, in conjunction with FIGS. 2A-2C, FIG. 2A is a schematic structural view of the circuit board 110; FIG. 2B shows a current diagram of the circuit board 110 shown in FIG. 2A; and FIG. 2C shows a signal diagram of the circuit board 110 shown in FIG. 2A. The chip 111 parallel connection direction is a left-right direction, and the direction perpendicular to the chip 111 parallel connection direction of the chip array is an up-down direction. In conjunction with FIGS. 2A-2C, in the up-down direction, a spacing between the 7th power taking unit 114 and the 8th power taking unit 114 on the right and a spacing between the 12th power taking unit 114 and the 13th power taking unit 114 can be greater than spacings of other adjacent power taking units 114, and therefore, in the up-down direction, a length of a power line 115 between the 7th power taking unit 114 and the 8th power taking unit 114 on the right and a length of a power line 115 between the 12th power taking unit 114 and the 13th power taking unit 114 are longer than lengths of power lines 115 between other adjacent power taking units 114, and a length of a signal line 116 between the 7th power taking unit 114 and the 8th power taking unit 114 on the right and a length of a signal line 116 between the 12th power taking unit 114 and the 13th power taking unit 114 are longer than lengths of signal lines 116 between other adjacent power taking units 114. A similar situation also exists in the circuit boards 110 of FIGS. 1B, FIGS. 3 to 17, and FIGS. 19A to 21B.

In an implementation, a working temperature difference between the chips 111 of the chip array ranges from 0 to 10 °C (with the endpoint values included). For example, in a case where the heat dissipation source is a fan, when a speed of the fan is 4000 rpm, a temperature difference between the chips 111 can be 8 to 10 °C (with the endpoint values included). In this way, the working temperature difference between the chips 111 is small, thereby improving the working performance of the circuit board 110.

Optionally, the vacant position 113 is provided with more than 3, and along the heat dissipation direction, spacings of the adjacent vacant positions 113 are not equal. For example, at this time, column spacings of adjacent columns in the chip array may be not equal.

Further, there are more than 3 vacant positions 113, and along the heat dissipation direction, the spacings of the adjacent vacant positions 113 can increase. For example, along the heat dissipation direction, column spacings of the adjacent columns in the chip array can gradually increase, and in this way, chips 111 provided close to the air outlet are sparse, thereby reducing the working temperature of the chips 111 provided close to the air outlet, and decreasing the temperature difference between the chips 111 at the air inlet and the air outlet.

In an implementation, referring to FIGS. 1B-9, FIGS. 12-15, FIGS. 17-19B, and FIGS. 21A-21B, in a direction perpendicular to a chip 111 parallel connection direction of the chip array, the vacant position 113 is a non-edge chip 111 in the chip array.

In an implementation, in a direction perpendicular to a chip 111 parallel connection direction of the chip array, spacings of other chips 111 not adjacent to the vacant position 113 than chips 111 adjacent to the vacant position 113 forwardly and rearwardly are equal. As shown in FIG. 1B, in an up-down direction, the 10th and 11th rows on the right are vacant positions 113. Spacings of the adjacent chips 111 in the 1st to 9th rows on the right are equal, and spacings of the adjacent chips 111 in 12th to 21st rows are equal.

In an implementation, in a direction perpendicular to a chip 111 parallel connection direction of the chip array, a spacing of the chips 111 adjacent to the vacant position 113 forwardly and rearwardly after filing a chip 111 is greater than or equal to spacings of other chips 111 not adjacent to the vacant position 113. That is to say, in a case where a chip 111 is filled in the vacant position 113, a distance between the chip 111 in this vacant position 113 and an adjacent chip 111 is greater than or equal to distances between the remaining adjacent chips 111.

In an implementation, the chips 111 in the chip array are arranged in a row and column, and centers of the chips 111 in each row or column are on the same straight line. For example, in the example of FIG. 1B, 120 chips 111 in the chip array are arranged in 21 rows and 6 columns, and centers of the chips 111 in each row are on a straight line, and centers of the chips 111 in each column are on a straight line. Row spacings of the chips 111 in first 3 columns are the same, and the 10th and 11th rows of the chips 111 in second 3 columns are missing. The number of the chips 111 in the first 3 columns is 63, and the number of the chips 111 in the second 3 columns is 57. A row direction of the chip array can be a heat dissipation direction, and a column direction of the chip array is perpendicular to the heat dissipation direction of the chips 111. In this way, a total number of the chips 111 in a first half part close to an air inlet is greater than a total number of the chips 111 in a second half part close to an air outlet. The number of the chips 111 at the air inlet is large, which can increase the heat generation of the chips 111 at the air inlet, and the number of the chips 111 at the air outlet is small, which can decrease the heat generation of the chips 111 at the air outlet, so that the maximum temperature difference between the chips 111 close to the air outlet and the chips 111 close to the air inlet can be further reduced, thereby improving the temperature equalization of the chips 111. A similar situation also exists in the circuit boards 110 of FIGS. 2A to 21B.

In an implementation, the chips 111 in the chip array are arranged in a row and column, and a center of each vacant position 113 is on the same straight line as the row or column. Exemplarily, each vacant position 113 can be provided at an intersection of a row and column of the chip array, namely, the center of the vacant position 113 is on a straight line with centers of other chips 111 of the chips 111 in a corresponding row, and the center of the vacant position 113 is on a straight line with centers of other chips 111 of the chips 111 in a corresponding column.

In an implementation, along a heat dissipation direction, the number of the vacant positions 113 in the chip array increases in an area on the circuit board 110 away from a heat dissipation source. For example, in a case where the heat dissipation source is a fan, the fan is provided at an air inlet of a heat dissipation duct, and the area on the circuit board 110 away from the heat dissipation source is an area on the circuit board 110 close to an air outlet. By increasing the number of the vacant positions 113 in the area on the circuit board 110 away from the heat dissipation source in the heat dissipation direction, the total number of the chips 111 in a first half part close to the air inlet can be made greater than the total number of the chips 111 in a second half part close to the air outlet, which can reduce the maximum temperature difference between the chips 111 close to the air outlet and the chips 111 close to the air inlet, thereby improving the temperature equalization of the chips 111.

In an implementation, the number of the vacant positions 113 increases in an area where high temperature is prone to occur. For example, in a case where a heat dissipation source is a fan, the fan is provided at an air inlet of a heat dissipation duct, and an area on the circuit board 110 away from the heat dissipation source is an area on the circuit board 110 close to the air outlet. By increasing the number of the vacant positions 113 in the area on the circuit board 110 away from the heat dissipation source in the heat dissipation direction, the total number of the chips 111 in a first half part close to the air inlet can be made greater than the total number of the chips 111 in a second half part close to the air outlet, which can reduce the maximum temperature difference between the chips 111 close to the air outlet and the chips 111 close to the air inlet, thereby improving the temperature equalization of the chips 111.

In an implementation, an ambient temperature is directly proportional to the number of the vacant positions 113 in the chip array, and the higher the ambient temperature in an area on the circuit board 110, the greater the number of the vacant positions 113 provided. The ambient temperature includes air temperature, chip 111 temperature, other electronic component temperature, and circuit board 110 temperature. For example, no chips 111 are provided in an area on the circuit board 110 occupied by corresponding vacant positions 113. The number of the vacant positions 113 is negatively correlated with a chip 111 density in an area where the vacant positions 113 are located, namely, the greater the number of the vacant positions 113, the lower the chip 111 density; and the smaller the number of the vacant positions 113, the higher the chip 111 density. With such an arrangement, it can be ensured that a density of the chips 111 is low in a case where the ambient temperature is high, thereby being beneficial to the heat dissipation of the chips 111, and reducing the maximum temperature difference of the chips 111 in the chip array.

In an implementation, the maximum value Y of the number of row chips divides the chip array into at least two parts.

Exemplarily, if Y is an even number, a total chip number A in a first Y/2 column(s) of the chip array is greater a total chip number B in a second Y/2 column(s) of the chip array. For example, in FIG. 1B, Y is an even number 6, the total chip number in the first 3 columns of the chip array is 63, and the total chip number in the second 3 columns of the chip array is 57.

If Y is an odd number, a total chip number C in a first (Y−1)/2 column(s) of the chip array is greater than a total chip number D in a second (Y−1)/2 column(s) of the chip array. For example, Y being 7 is taken as an example for illustration. At this time, the total chip number C in the first 3 columns of the chip array is greater than the total chip number D in the second 3 columns of the chip array. In this way, a total number of the chips 111 in a first half part close to an air inlet is greater than a total number of the chips 111 in a second half part close to an air outlet, which can reduce the maximum temperature difference between the chips 111 close to the air outlet and the chips 111 close to the air inlet, thereby improving the temperature equalization of the chips 111.

Alternatively, if Y is an even number, a total chip number A in a first Y/2 column(s) and corresponding column(s) of the chip array can also be less than a total chip number B in a second Y/2 column(s) and corresponding column(s) of the chip array. For example, in FIG. 17, Y is an even number 6, the total chip number in the first 3 columns of the chip array is 57, and the total chip number in the second 3 columns of the chip array is 63.

If Y is an odd number, a total chip number C in a first (Y−1)/2 column(s) and corresponding column(s) of the chip array can also be less than a total chip number D in a second (Y−1)/2 column(s) and corresponding column(s) of the chip array. For example, Y being 7 is taken as an example for illustration. At this time, the total chip number C in the first 3 columns of the chip array can be less than the total chip number D in the second 3 columns of the chip array.

Of course, the present application is not limited to this. If Y is an even number, a total chip number A in a first Y/2 column(s) and corresponding column(s) of the chip array can also be equal to a total chip number B in a second Y/2 column(s) and corresponding column(s) of the chip array. For example, in the example of FIG. 12, Y is an even number 6, the total chip number in the first 3 columns of the chip array is 57, and the total chip number in the second 3 columns of the chip array is 57.

If Y is an odd number, a total chip number C in a first (Y−1)/2 column(s) and corresponding column(s) of the chip array can also be equal to a total chip number D in a second (Y−1)/2 column(s) and corresponding column(s) of the chip array. For example, Y being 7 is taken as an example for illustration. At this time, the total chip number C in the first 3 columns of the chip array can be equal to the total chip number D in the second 3 columns of the chip array.

The present application further provides a working assembly 2100, including a circuit board 110 and a heat sink 2110. The circuit board 110 is the circuit board 110 in any one of the above implementations, and the heat sink 2110 includes a heat dissipation body and heat dissipation fins, the heat dissipation body including a first surface and a second surface opposite to each other, and the first surface connected with the heat dissipation fins.

Exemplarily, the heat sink 2110 can be an air-cooled heat sink 2110 or a liquid-cooled heat sink 2110. The heat sink 2110 can be located on a side of the circuit board 110 where working chips are provided, for dissipating heat for the circuit board 110. The heat sink 2110 can also be located on a side of the circuit board 110 where no chips are provided. Alternatively, chips are provided on both sides of the circuit board 110, and the heat sink 2110 is respectively provided on both sides of the circuit board 110.

In an implementation, the second surface is provided with a plurality of bosses, each provided corresponding to each row of the power taking units 114 or each column of the power taking units 114. In this way, the heat generated in a working process of the chips in the power taking units 114 can be effectively conducted to the heat sink 2110 through the bosses, thereby improving the heat dissipation effect.

Alternatively, in another implementation, the second surface is provided with a plurality of bosses, and at least some of the bosses can also be provided at corresponding locations between at least some of the adjacent power taking units 114. For example, in FIG. 3, 117 chips on the circuit board 110 are arranged in multiple rows, and a row direction is parallel to a direction from an air inlet to an air outlet of a heat dissipation duct. The number of the chips in the 6th row, the 11th row, and the 16th row is 3 respectively, and the number of the chips in other rows is 6, so the number of the chips in the 6th row, the 11th row, and the 16th row is less than the number of the chips in the other rows. At least some of the bosses can be provided at corresponding locations between the 5th power taking unit 114 and the 6th power taking unit 114, corresponding locations between the 9th power taking unit 114 and the 10th power taking unit 114, and corresponding locations between the 13th power taking unit 114 and the 14th power taking unit 114 in the second part.

In an implementation, as shown in FIG. 2A, a plurality of chips 111 close to an air outlet are divided into a plurality of sets of heat-generating component sets along a second direction, and a gap between two adjacent sets of heat-generating component sets is greater than a gap between two adjacent chips 111 in each heat-generating component set.

For example, six columns of the chips 111 are shown in the example of FIG. 2A. For the convenience of description, the six columns of the chips 111 arranged in sequence along a first direction are respectively referred to as a first heat-generating column, a second heat-generating column . . . a sixth heat-generating column. The number of the chips 111 in the first to third heat-generating columns is 21, and the number of the chips 111 in the fourth to sixth heat-generating columns is 19. Among them, the 21 chips 111 in the first to third heat-generating columns are provided with even spacings. The 19 chips 111 in the fourth to sixth heat-generating columns are divided into three sets of heat-generating component sets, and the numbers of the chips 111 in the heat-generating component sets in the three sets of heat-generating component sets located in two ends of the second direction are the same, and the number of the chips 111 in the heat-generating component sets located in a middle portion of the second direction is less than the number of the chips 111 in the heat-generating component sets in two ends.

In this embodiment, there can be a large heat dissipation gap between two adjacent sets of heat-generating component sets at the air outlet, which can reduce the temperature close to the air outlet, and, in turn, reduce the maximum temperature difference between the air inlet and the air outlet, thereby improving the temperature equalization of the working assembly 100.

In an implementation, the arrangement manner of the chips 111 can be in various forms. From a first column close to an air inlet (e.g., the above first heat-generating column) to a last column close to an air outlet (e.g., the above sixth heat-generating column), the number of the chips in each column is not completely equal. The number of each column of the chips may gradually decrease, for example, 21, 20, 19, 18, 17, and 16; may partially decrease, for example, 21, 21, 21, 19, 19, and 19; or may also be a jump in number, for example, 21, 21, 20, 19, 20, and 21; or 21, 21, 20, 19, 18, and 21; other numbers of chip arrays may also be provided according to heat dissipation requirements, so that the total number of the chips in a first half part close to the air inlet is greater than the total number of the chips in a second half part close to the air outlet. The first half part and the second half part here can be partitioned in half in terms of the number of chip columns, or in half in terms of the size of the circuit board 110. As shown in FIG. 2A, the total number of the chips in the first three columns close to the air inlet is set to be greater than the total number of the chips in the second three columns close to the air outlet.

Due to the variation in the number of the chips in each column, the arrangement of the chips in each row may also be combined in different forms, and the number of the chips in each row may be different. For example, chips in some rows are arranged on a straight line by center points of the chips, and center points of the chips in some rows do not form a straight line, such as a step arrangement (e.g., a step arrangement presented in a row direction in view of the above “the number of each column of the chips may gradually decrease, for example, 21, 20, 19, 18, 17, and 16”). There are also different embodiments for the number of the chips in each row. For example, in the second direction, the number of row chips close to two ends of the circuit board 110 is greater than the number of row chips close to a center location of the circuit board 110. In short, to partition the total chip distribution and/or quantity, the total number of the chips in each partitioned part meets preset distribution requirements.

Specifically, by taking the number of the chips in the first heat-generating column as a partition basis in the second direction, the circuit board 110 is partitioned from left to right into three parts: a first part, a second part, and a third part, and a total number of the chips in the first part or the third part close to the two ends of the circuit board 110 is greater than the number of the chips in the middle second part. In another embodiment, if, by taking the number of the chips in the first heat-generating column as a partition basis in the second direction, the circuit board 110 is partitioned from left to right into two parts, then the number of the chips in a first part is less than or equal to the number of the chips in a second part.

As for the above specific partition, referring to FIG. 2A, by taking the number of the chips in the first heat-generating column as a partition basis in the second direction, in an embodiment, the partition manner is an average partition to partition the circuit board 110 from left to right into three parts. There are 21 chips in the first heat-generating column. To partition the circuit board 110 from left to right into three parts, every 7 chips in the first heat-generating column is correspondingly partitioned into a part, and then a total number of the chips in a first part is 42, a total number of the chips in a second part is 36, and a total number of the chips in a third part is 42. The total number of the chips in the first part (42) or the third part (42) close to the two ends of the circuit board 110 is greater than the number of the chips in the middle second part (36); if, by taking the number of the chips in the first heat-generating column as a partition basis in the second direction to partition the circuit board 110 from left to right into two parts, the circuit board 110 can be partitioned from left to right into two parts by taking a central axis of the 11th chip in the middle of the first heat-generating column as a partition point, then the number of the chips in a first part (57) is equal to the number of the chips in a second part (57). It can be understood by those skilled in the art that the partition manner is not limited to the above records. In a case that the total number of the chips in the first heat-generating column is an odd number or an even number, the manner of partition can be flexibly selected. Of course, the circuit board can also be partitioned and divided by taking an overall area formed by edges of the chips arranged thereon as a reference, which may be partitioned averagely, and, of course, may also be partitioned according to other proportions so as to make the total number of the chips in each part meet preset distribution requirements.

In short, the arrangement manner of the chips 111 can be set in conjunction with heat dissipation conditions of various locations in the air duct. For example, if the ambient temperature of the air inlet is low and the overall heat dissipation efficiency is high, then more chips can be disposed; and if the ambient temperature of the air outlet is high and the overall heat dissipation efficiency is low, then fewer chips can be disposed, and the total number of the chips close to the air outlet is less than the total number of the chips at the air inlet. At the same time, in both upper and lower ends of the circuit board 110, in a direction perpendicular to a direction of wind, the temperatures at the two ends are lower than the temperature in the center of the circuit board 110, and then more chips 111 can be disposed in the two ends, while fewer chips 111 can be disposed in the center, and the total number of the chips in the two ends is greater than the total number of the chips in the center. Also, it can be divided into two parts, and the total number of the chips in a lower half part is greater than the total number of the chips in an upper half part. This is different from the design idea that usually changes the thermal resistance of the heat sink to achieve temperature equalization.

In some embodiments, the present application further provides a circuit board 110, provided with a plurality of chip groups 118, each including at least one row of chips and/or at least one column of chips, wherein inter-group spacing of at least some of the two adjacent chip groups is not equal to a spacing of the adjacent chips within any chip group.

The plurality of chip groups 118 are arranged to constitute a chip array. In a case that the chip array is constituted, along a row direction or column direction, spacings of at least some of the adjacent chip groups 118 are greater than or equal to a spacing for accommodating one chip, namely, there are chip vacant positions between some adjacent chip groups 118.

As shown in FIG. 1B, the chips in the left three columns are a chip group 118, the chips in the right three columns in the 1st to 9th rows are a chip group 118, and the chips in the right three columns in the 10th to 19th rows are a chip group 118. The 3 chip groups 118 constitute a chip array, and there is a row of chip vacant positions between the 2 chip groups 118 in the right three columns of the chips.

As shown in FIG. 2A, the chips in the left three columns are a chip group 118, the chips in the right three columns in the 1st to 7th rows are a chip group 118, the chips in the right three columns in the 8th to 12th rows are a chip group 118, and the chips in the right three columns in the 13th to 19th rows are a chip group 118. The 4 chip groups 118 constitute a chip array, and there are two rows of chip vacant positions between the 3 chip groups 118 in the right three columns of the chips.

As shown in FIG. 6A, the chips in the left three columns in the 1st to 10th rows are a chip group 118, the chips in the left three columns in the 12th to 20th rows are a chip group 118, the chips in the right three columns in the 1st to 7th rows are a chip group 118, the chips in the right three columns in the 8th to 12th rows are a chip group 118, and the chips in the right three columns in the 13th to 19th rows are a chip group 118. The 5 chip groups 118 constitute a chip array, and there is a row of chip vacant positions between the 3 chip groups 118 in the left three columns, and two rows of chip vacant positions between the 3 chip groups 118 in the right three columns.

The chip group 118 is composed of at least one power taking unit 114 including at least one chip. In a case that the power taking unit 114 includes a plurality of chips, the chips in the power taking unit 114 are in the same row or column and are connected in parallel. A chip parallel connection direction of each chip group 118 is the same, and along a direction perpendicular to the chip parallel connection direction, spacings of at least some of the adjacent chip groups 118 are not equal to spacings of the adjacent power taking units 114 within any chip group 118. The chip group 118 includes a plurality of power taking units 114 that are connected in series. A chip series connection direction of each chip group 118 is the same, and along the chip series connection direction, spacings of at least some of the adjacent chip groups 118 are not equal to spacings of the adjacent power taking units 114 within any chip group 118. The chips between the chip groups 118 can be disposed along the row and column directions with equal spacings or unequal spacings or with increasing spacings or decreasing spacings, but spacings of at least some of the adjacent chip groups 118 will be different from spacings of the adjacent chips within a chip group 118 due to the existence of chip vacant positions. It needs to be explained that the electrical connection manner of the chips in the above embodiments is not merely limited to series connection and parallel connection, and other electrical connection manners such as a combination of series connection and parallel connection may also be made between the chips.

In this embodiment, the chips on the circuit board 110 are divided by set. Furthermore, inter-group spacing between the chip groups 110 is set to be greater than a chip spacing within each chip group 118, and a heat dissipation channel is formed between each chip group, thereby making it more convenient to dissipate heat for the chips arranged on the circuit board. For example, the chips on the circuit board 110 shown in FIG. 1B are densely arranged with equal spacings, which is not beneficial to the heat dissipation of chips close to the center area. Through the embodiment of the present application, all chips are divided by set into a plurality of sets 118, and the inter-group spacing is set to be greater than the chip spacing within the groups, so that the chips close to the center area of the circuit board can achieve heat dissipation through wider inter-group spacing, thereby improving the temperature equalization of all the chips on the entire circuit board. Exemplarily, spacing(s) between the chip groups corresponds to one or more consecutive vacant positions 113 in FIG. 1B.

In some embodiments, in the direction perpendicular to the parallel connection direction of the chips, a spacing of two adjacent chip groups 118 is greater than or equal to a spacing for accommodating one chip 111.

In this embodiment, by setting the spacing of the chip groups 118 to be greater than or equal to a distance for accommodating one chip 111, it is guaranteed that the spacing between the chip groups 118 is large enough, thereby ensuring the heat dissipation of the chips close to the center area.

In some embodiments, each chip group 118 includes multiple rows of the chips, and there are at least two chip groups 118 different in the number of chip rows. For example, each chip group 118 includes at least one row of the chips, and the number of chip rows contained in each chip group 118 is not unique. As shown in FIG. 16, the circuit board 110 is divided into a chip group containing only one row of the chips, a chip group containing two rows of the chips, a chip group containing three rows of the chips, etc., and each chip group forms a chip array.

In this embodiment, the number of rows of the chips within a chip group is not limited, which is convenient for arranging and dividing each chip group according to the actual situations of the circuit board space and the total number of the chips.

In some embodiments, each chip group 118 includes multiple columns of the chips, and the number of chip columns of each chip group 118 is the same. As shown in FIG. 1B, the circuit board 110 includes three chip groups 118, wherein chips in the three columns located in the left half part of the circuit board 110 are a chip group 118, and chips in the three columns located in the right half part of the circuit board are divided into two chip groups 118, and a large gap is provided between the two chip groups 118, which can accommodate at least two rows of the chips.

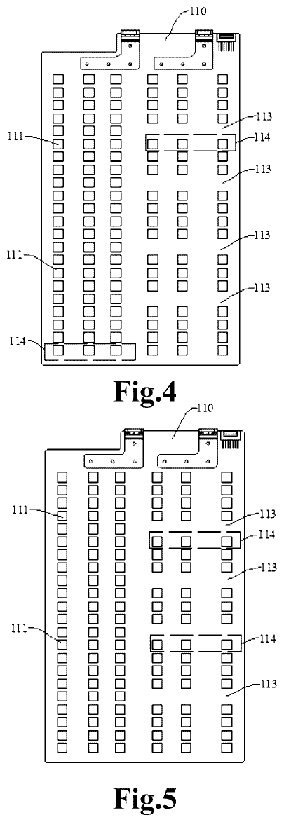

Exemplarily, in this embodiment, when heat dissipation is performed for the circuit board 110, the left side of the circuit board 110 is located upstream in the heat dissipation direction, and the right side is located downstream in the heat dissipation direction. By dividing the three columns of the chips close to the downstream in the heat dissipation direction into two or more sets (e.g., three sets, with reference to FIG. 2A, FIG. 4, FIG. 5, FIG. 10, FIG. 11, and FIG. 18), the inter-set gaps are guaranteed, thereby improving the heat dissipation performance of the downstream chips in the heat dissipation direction, and improving the temperature equalization between the chips on the entire circuit board.

In some embodiments, the plurality of chip groups 118 are connected therebetween in series power supply, and chips in each row of each chip group 118 are connected therebetween in series power supply.

Exemplarily, as shown in FIG. 2B, the circuit board 110 includes four chip groups 118, including a first chip group (with three columns of the chips) located in the left half part of the circuit board 110, and a second chip group, a third chip group, and a fourth chip group located from top to bottom in the right half part of the circuit board. The circuit board further includes a first electrical connector and a second electrical connector, one of which is used to connect the positive pole of a power source and the other is used to connect the negative pole of the power source. The first chip group, the second chip group, the third chip group and the fourth chip group are sequentially connected in series between the first electrical connector 119 and the second electrical connector 119′ to achieve series power supply.

In this embodiment, the number of chip columns contained in each chip group 118 is the same, thereby guaranteeing that in a case that the chip groups 118 are connected therebetween in series, it is convenient to dispose a space area on the circuit board occupied by the plurality of chip groups in series, which is beneficial to the versatility of the circuit board design and the reasonable planning of the wiring on the circuit board (e.g., the power lines 115 and the signal lines between the chips and between the chip groups).

In some embodiments, the chips within each row of the chips of each chip group 118 are connected therebetween in parallel power supply. Exemplarily, chip rows contained within each chip group 118 are also connected therebetween in series power supply, and chips in each row within each chip group 118 are connected in parallel.

In this embodiment, by performing parallel connection between chips in each row, the voltage of each chip within each row of the chips can be made consistent, thereby guaranteeing that each chip obtains the same working voltage and improving the working stability.

Further, in a case that all chips on the circuit board 110 are consistent (e.g., being chips of the same model), since the number of the chips in each row is the same, the voltage drop of each row of the chips connected in parallel in the series connection direction is substantially consistent and stable, which is beneficial to stabilizing the working voltage between each row of the chips within a predetermined range, and improving the working stability of the chips.

In some embodiments, a column direction is perpendicular to a parallel connection direction of the chips, and a row direction is parallel to the parallel connection direction of the chips. The chips on the circuit board 110 are at least partially arranged in a row and column, wherein the row direction is perpendicular to the parallel connection direction of the chips connected in parallel on the circuit board 110.

In some embodiments, each chip group 118 consists of at least one power taking unit 114, wherein chips in the power taking unit 114 are connected in parallel, and the chips in the power taking unit 114 are arranged in rows. Exemplarily, the chip group 118 includes multiple rows of the chips, the chips in each row are connected in parallel to constitute a power taking unit, and a plurality of power taking units 114 constituted by the multiple rows of the chips are connected in series.

In this embodiment, the plurality of chips contained within the power taking unit 114 are connected in parallel to guarantee that the voltage acquired by each chip within the power taking unit 114 is consistent, which is beneficial to improving the consistency of the working performance of each chip within the power taking unit 114 (e.g., computing power consistency or working frequency consistency, etc.).

In some embodiments, along a heat dissipation direction, the plurality of chip groups 118 are divided into at least one set of chip groups.

The heat dissipation direction mentioned in the embodiments of the present application can be, for example, a direction of wind. For example, during air-cooled heat dissipation, a heat dissipation fan is adopted to dissipate heat from the circuit board 110, and the wind takes away the heat generated by the working of the chips on the circuit board 110, thereby achieving heat dissipation.

As shown in FIG. 21A, the circuit board 110 includes two upper and lower chip groups 118, and a spacing between the two chip groups 118 is greater than spacings between the chips within each set of chips. In this embodiment, the two upper and lower chip groups 118 on the circuit board 110 are divided into a set of chip groups. In addition, a heat dissipation duct is formed between the two chip groups 118, a direction of which is parallel to the heat dissipation direction, and runs through the intermediate area of the chip array on the entire circuit board 110, facilitating the heat dissipation of the chips 111 in the intermediate and rearward areas of the circuit board 110.

In some embodiments, the plurality of chip groups 118 are divided into a first set of chip groups and a second set of chip groups.

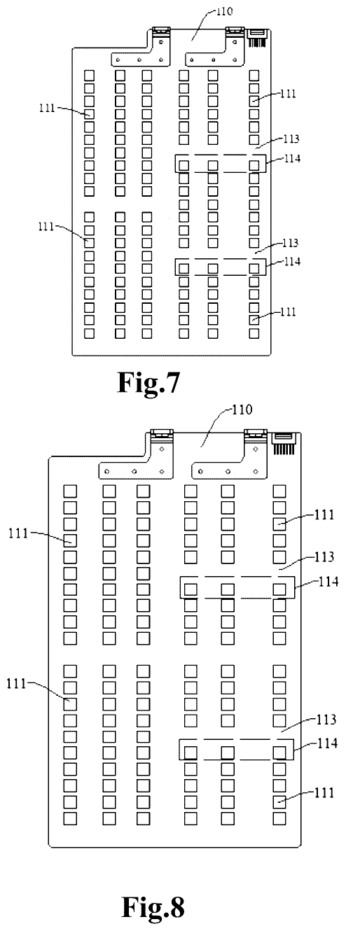

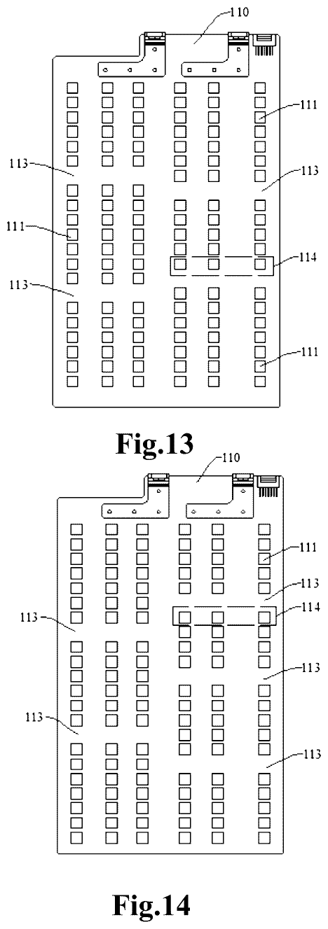

In the embodiments shown in FIGS. 6 and 7, the circuit board 110 includes five chip groups 118, which are divided into two sets of chip groups, with a first set of chip groups including two chip groups 118 distributed in the upper and lower portions, and a second set of chip groups including three chip groups 118 in upper, middle and lower portions. Further, in this embodiment, gaps (i.e., heat dissipation ducts) formed between the chip groups 118 in the sets of chip groups are misaligned with each other, in which way in a case that wind flows from a heat dissipation duct in the first set of chip groups to the second set of chip groups, it flows directly to an area where chips are densely arranged, which is beneficial to forming a disturbed flow and increasing the heat dissipation efficiency. In addition, the situation where heat dissipation ducts are misaligned also exists in FIGS. 13-16, which will not be repeated here.

In some embodiments, chips within the set of chip groups are in the same series connection current direction.

Further, FIG. 21B shows a series power supply connection relationship of the chips in FIG. 21A. In this embodiment, the chips within an entire row of the chips are connected in parallel, rows of the chips are connected therebetween in series, and the connection to an external power source is achieved through two electrical connectors. The direction of the arrows on the connecting lines in the figure is the series connection current direction. An overall current direction is to flow from one electrical connector into the first row of the chips, then into the last row of the chips through each row of the chips in sequence, and then flow out through another electrical connector.

In some embodiments, the numbers of the chips in the first set of chip groups and the second set of chip groups are equal.

In the embodiments shown in FIGS. 12 and 13, the first set of chip groups and the second set of chip groups respectively include three chip groups, and the first set of chip groups includes two first gaps, the second set of chip groups includes two second gaps, and the numbers of chips contained in the two set of chip groups are equal, both 57.

In this embodiment, while chips on the circuit board 110 are grouped to form inter-set gaps to achieve heat dissipation, the numbers of the chips in the first set of chip groups and the second set of chip groups are kept consistent, which facilitates the layout of the chips on the circuit board 110.

Further, the numbers of chip columns in the first set of chip groups and the second set of chip groups are the same, and the number of the chips in the first set of chip groups is greater than the number of the chips in the second set of chip groups.

The numbers of chip columns contained in the sets of chip groups are the same, thereby guaranteeing that in a case that chip groups within each set are connected in series, it is convenient to dispose a space area on the circuit board occupied by the plurality of chip groups in a string, which is beneficial to the versatility of the circuit board design and the reasonable planning of the wiring on the circuit board (e.g., the power lines 115 and the signal lines 116 between the chips and between the chip groups).

In some embodiments, the number of the chips in the first set of chip groups is less than the number of the chips in the second set of chip groups.

In the embodiments shown in FIGS. 16 and 17, all chips on the circuit board 110 are divided into two left and right parts, corresponding to the first set of chip groups and the second set of chip groups, respectively. The number of the chips in the first set of chip groups is less than the number of the chips in the second set of chip groups. In this embodiment, the second set of chip groups can be in an area with high heat dissipation efficiency, and the first set of chip groups can be in an area with low heat dissipation efficiency, thereby facilitating achievement of the temperature equalization of the chips on the entire circuit board 110.

Further, the numbers of chip columns in the first set of chip groups and the second set of chip groups are the same, and the number of the chips in the first set of chip groups is less than the number of the chips in the second set of chip groups.

The numbers of chip columns contained in the sets of chip groups are the same, thereby guaranteeing that in a case that chip groups 118 within each set are connected in series, it is convenient to dispose a space area on the circuit board occupied by the plurality of chip groups in a string, which is beneficial to the versatility of the circuit board design and the reasonable planning of the wiring on the circuit board (e.g., the power lines 115 and the signal lines 116 between the chips and between the chip groups).

In some embodiments, the number of the chips in the first set of chip groups is greater than the number of the chips in the second set of chip groups.

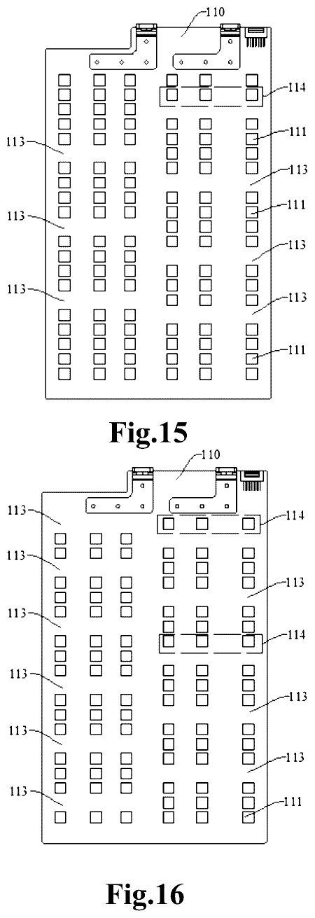

As shown in FIG. 14, FIG. 15, and FIGS. 6-9, all chips on the circuit board 110 are divided into two left and right parts, corresponding to the first set of chip groups and the second set of chip groups, respectively. The number of the chips in the first set of chip groups is greater than the number of the chips in the second set of chip groups.

In this embodiment, the number of the chips 111 in the first set of chip groups is greater than the number of the chips 111 in the second set of chip groups, so that an overall chip density of the first set of chip groups is greater than an overall chip density of the second set of chip groups. The first set of chip groups can be in an area with high heat dissipation efficiency, and the second set of chip groups can be in an area with low heat dissipation efficiency, thereby facilitating achievement of the temperature equalization of the chips 111 on the entire circuit board 110.

Exemplarily, the circuit board 110 in this embodiment can be provided in such a manner that the first set of chip groups is close to a heat dissipation source. For example, the heat dissipation source is a fan configured in such a manner that a wind direction is parallel to the parallel connection direction of the chips 111 on the circuit board 110, and the first set of chip groups is close to the fan.

Further, the numbers of chip columns in the first set of chip groups and the second set of chip groups are the same, and the number of the chips in the first set of chip groups is greater than the number of the chips in the second set of chip groups.

The numbers of chip columns contained in the sets of chip groups are the same, thereby guaranteeing that in a case that chip groups within each set are connected in series, it is convenient to dispose a space area on the circuit board occupied by the plurality of chip groups in a string, which is beneficial to the versatility of the circuit board design and the reasonable planning of the wiring on the circuit board (e.g., the power lines 115 and the signal lines 116 between the chips and between the chip groups).

In some embodiments, an average chip spacing of the first set of chip groups is less than an average chip spacing of the second set of chip groups.

As shown in FIG. 2A, the circuit board 110 includes a first set of chip groups composed of the first three columns of the chips, and a second set of chip groups composed of the second three columns of the chips, wherein the first set of chip groups includes only one chip group, and the second set of chip groups includes three chip groups along a column direction. An average value of column spacings between the three columns of the chips in the first set of chip groups is less than an average column spacing between the three columns of the chips in the second set of chip groups.

In a case that the circuit board 110 in this embodiment is in a working environment, the first set of chip groups and the second set of chip groups are distributed along a heat dissipation direction. Taking air-cooled heat dissipation as an example, the heat dissipation direction is a blowing direction of a fan, the first set of chip groups is located upstream in the heat dissipation direction, and the second set of chip groups is located downstream in the heat dissipation direction (wherein the upstream and downstream are only mentioned relative to locations of the circuit board 110 and the fan, and an end of the circuit board 110 closer to the fan is upstream, while the opposite other end is downstream). Relatively, from upstream to downstream, the temperature of the wind gradually increases, and by setting a column spacing in the second set of chip groups to be greater than a column spacing in the first set of chip groups, it is thereby beneficial to improve the temperature equalization of the chips 111 on the circuit board 110.

In some embodiments, the first set of chip groups includes 1 chip group in a direction perpendicular to a parallel connection direction of chips 111; and along the perpendicular direction, chip spacings between adjacent chips within the chip group in the first set of chip groups are equal.

As shown in FIG. 2A, a first set of chip groups located on the left side of the circuit board 110 includes one chip group, and spacings of chips 111 within a set in a direction perpendicular to a parallel connection direction of the chips 111 are equal. Since rows of the chips 111 are connected in series in the direction perpendicular to the parallel connection direction of the chips 111 within each chip group 118, the hardware design of the circuit board 110 is facilitated by providing the chips 111 with equal spacings. For example, connectors or wirings between the chips 111 can adopt a uniform size or length, which simplifies the design on the one hand, and also can reduce the cost on the other. The connectors may be copper sheets or welding pads attached between the chips 111. It needs to be explained that the above is merely an example, and the present application is not limited to this.

In some embodiments, the first set of chip groups includes a plurality of chip groups 118 in a direction perpendicular to a parallel connection direction of chips 111; and a group spacing between adjacent chip groups 118 in the first set of chip groups is greater than the chip spacing between adjacent chips within each chip group 118.

In this embodiment, chips 111 on the circuit board 110 include a first set of chip groups, and this set is provided in such a manner that inter-group spacing between the chip groups 118 is greater than the chip spacing within each chip group 118, and a heat dissipation channel is formed between each set of chips, thereby making it more convenient to dissipate heat for the chips 111 arranged on the circuit board 110.

In some embodiments, the second set of chip groups includes 1 chip group in a direction perpendicular to a parallel connection direction of chips; and along the perpendicular direction, chip spacings between adjacent chips within the chip group in the second set of chip groups are equal.

As shown in FIG. 17, a second set of chip groups located on the right side of the circuit board 110 includes one chip group 118, and spacings of chips within a set in a direction perpendicular to a parallel connection direction of the chips are equal. Since rows of the chips 111 are connected in series in the direction perpendicular to the parallel connection direction of the chips within each chip group 118, the hardware design of the circuit board 110 is facilitated by providing the chips with equal spacings. For example, connectors or wirings between the chips can adopt a uniform size or length, which simplifies the design on the one hand, and also can reduce the cost on the other. The connectors may be copper sheets or welding pads attached between the chips. It needs to be explained that the above is merely an example, and the present application is not limited to this.

In some embodiments, the second set of chip groups includes a plurality of chip groups 118 in a direction perpendicular to a parallel connection direction of chips 111; and group spacing between adjacent chip groups 118 in the second set of chip groups is greater than the chip spacing between adjacent chips within each chip group 118.

In this embodiment, chips on the circuit board 110 include a second set of chip groups, and this set is provided in such a manner that inter-group spacing between the chip groups 118 is greater than the chip spacing within each chip group 118, and a heat dissipation channel is formed between each set of chips, thereby making it more convenient to dissipate heat for the chips arranged on the circuit board 110.

In some embodiments, in a direction perpendicular to a parallel connection of the chips, a plurality of first gaps are formed between a plurality of pairs of adjacent chip groups in the first set of chip groups; and a plurality of second gaps are formed between a plurality of pairs of adjacent chip groups in the second set of chip groups.

Exemplarily, gaps between the chip groups 118 are greater than or equal to a spacing for accommodating one chip 111. In this embodiment, chips on the circuit board 110 include a first set of chip groups and a second set of chip groups, and gaps are formed between the chip groups 118 within a set, and a heat dissipation channel is formed between each set of the chips, thereby making it more convenient to dissipate heat for the chips 111 arranged on the circuit board 110.

In some embodiments, the plurality of first gaps correspond to the plurality of second gaps one by one, and at least some of the first gaps and second gaps corresponding to each other are collinear. In the embodiments shown in FIGS. 8, 9, and 12, at least some of first gaps and second gaps corresponding to each other are collinear. In the embodiments shown in FIGS. 8 and 9, there is one first gap and three second gaps, and only a pair of the first gap and second gap are collinear; and in the embodiment shown in FIG. 12, there are two first gaps and two second gaps, and two pairs of the first gaps and the second gaps are collinear, respectively.

In this embodiment, by setting the first gaps in the first set of chip groups and the second gaps in the second set of chip groups to be collinear, the wind resistance is greatly reduced, thereby increasing the wind speed and volume, and enhancing the heat dissipation efficiency.

In some embodiments, for at least one first gap, there is no collinear second gap in the second set of chip groups. In the embodiments shown in FIGS. 6 and 7, the circuit board 110 includes 5 chip groups 118, which are divided into two sets of chip groups, with a first set of chip groups including two chip groups distributed in the upper and lower portions, and a second set of chip groups including three chip groups in upper, middle and lower portions.

Further, in this embodiment, gaps (i.e., heat dissipation ducts) formed between the chip groups 118 in the sets of chip groups are misaligned with each other, in which way in a case that wind flows from a heat dissipation duct in the first set of chip groups to the second set of chip groups, it flows directly to an area where chips are densely arranged, which is beneficial to forming a disturbed flow and increasing the heat dissipation efficiency. In addition, the situation where heat dissipation ducts are misaligned also exists in FIGS. 13-16, which will not be repeated here.

In some embodiments, the number of the plurality of first gaps is less than the number of the plurality of second gaps.

As shown in FIGS. 6-9, FIG. 14 and FIG. 15, the circuit board 110 includes a first set of chip groups and a second set of chip groups distributed left and right, each including three columns of the chips, wherein the number of first gaps in the first set of chip groups is less than the number of gaps in the second set of chip groups. Taking FIG. 6 as an example, a first set of chip groups includes one first gap, and a second set of chip groups includes two second gaps.

In this embodiment, fewer first gaps are provided in the first set of chip groups, and more second gaps are provided in the second set of chip groups. The more gaps there are, the less space there is available for providing chips 111, so that the number of the chips in the first set of chip groups is greater than the number of the chips in the second set of chip groups, thereby generally distributing the chips 111 in the first set of chip groups densely, and distributing the chips 111 in the second set of chip groups sparsely. As can be seen, in this embodiment, along a heat dissipation direction (or along a chip parallel connection direction), the chips are generally arranged in a first dense and then sparse trend, which facilitates the temperature equalization of the chips 111 in each area on the circuit board 110.

In some embodiments, in a direction perpendicular to a parallel connection direction of chips, the number of at least one column of the chips in the first set of chip groups is greater than the number of at least one column of the chips in the second set of chip groups.

As shown in FIGS. 1B-10, FIG. 14, FIG. 15, FIG. 18, and FIG. 20, the circuit board 110 includes a first set of chip groups and a second set of chip groups distributed left and right, each including three columns of the chips 111, wherein the number of at least one column of the chips in the first set of chip groups is greater than the number of at least one column of the chips in the second set of chip groups. Taking FIG. 4 as an example, a first set of chip groups includes one chip group, a second set of chip groups includes 5 chip groups, and the number of the chips in any column of the chips in the first set of chip groups is greater than the number of the chips in any column of the chips in the second set of chip groups.

Further, the number of the chips in all chip columns in the first set of chip groups is greater than the number of the chips in all chip columns in the second set of chip groups. In this embodiment, the number of the chips 111 contained in chip columns in the first set of chip groups is set to be less than the number of the chips 111 contained in chip columns in the second set of chip groups, thereby making the number of the chips in the first set of chip groups generally greater than the number of the chips in the second set of chip groups.

The first set of chip groups and the second set of chip groups are distributed along the heat dissipation direction, so that the setting of the number of the chips in the above embodiment can improve the temperature equalization of the chips 111 on the circuit board 110.

In some embodiments, a distance from a first chip to a last chip in at least one column of the chips in the first set of chip groups is less than a distance from a first chip to a last chip in at least one column of the chips in the second set of chip groups.

In the embodiments shown in FIG. 10, FIG. 11, and FIG. 16, the circuit board 110 includes a first set of chip groups and a second set of chip groups distributed left and right, each including three columns of the chips, wherein the first set of chip groups includes only one chip group, and three chips in a first row are missing in this chip group (as shown in FIGS. 10 and 16), or chips in a first row and last row are missing in this chip group 118 (as shown in FIG. 11), while chips in upper and lower ends are not missing in the second set of chip groups, thereby making a distance from a first chip to a last chip in a chip column in the first set of chip groups less than a distance from a first chip to a last chip in at least one column of the chips in the second set of chip groups.

Exemplarily, the first set of chip groups and the second set of chip groups are distributed along the heat dissipation direction. In this embodiment, an area where a chip row is missing in the first set of chip groups forms a heat dissipation channel extending to the second set of chip groups. Taking air-cooled heat dissipation as an example, wind can enter the second set of chip groups through the heat dissipation channel for heat dissipation, increasing the volume of wind entering the second set of chip groups. In addition, since there are chips only on an upper side or lower side of the heat dissipation channel, the wind entering the second set of chip groups through the heat dissipation channel is enabled to absorb less heat and the temperature is relatively low, which facilitates the heat dissipation and cooling of the second set of chip groups, and improves the temperature equalization of the chips on the entire circuit board 110.

In some embodiments, the number of chip groups in the first set of chip groups is less than the number of chip groups in the second set of chip groups.

In the embodiments shown in FIGS. 1B-10, FIG. 14, FIG. 15, FIG. 18, and FIG. 20, the circuit board 110 includes a first set of chip groups and a second set of chip groups distributed left and right, and the number of the chip groups in the first set of chip groups is less than the number of the chip groups in the second set of chip groups. Overall, the number of first gaps between the chip groups formed in the first set of chip groups is less than the number of second gaps between the chip groups formed in the second set of chip groups. More second gaps make chips 111 in the second set of chip groups have higher heat dissipation efficiency. For air-cooled heat dissipation, although the temperature of wind entering the second set of chip groups after the first set of chip groups is high, due to more second gaps in the second set of chip groups, the problem of high wind temperature is balanced, thereby improving the temperature equalization of the chips 111 on the circuit board 110.

In some embodiments, in a direction perpendicular to a parallel connection direction of chips, the second set of chip groups includes two end chip groups and one middle chip group, wherein the number of the chips in each end chip group is greater than the number of the chips in the middle chip group.

In the embodiment shown in FIG. 6, the circuit board 110 includes a first set of chip groups and a second set of chip groups distributed left and right, wherein each chip group 118 in the second set of chip groups includes the same column of chips, and two end chip groups include 7 rows of the chips 111 respectively, a middle chip group includes 5 rows of the chips 111, and the number of the chips contained in the two end chip groups is greater than the number of the chips 111 contained in the middle chip group.

Exemplarily, the first set of chip groups and the second set of chip groups are distributed along a heat dissipation direction. Taking air-cooled heat dissipation as an example, wind first enters the first set of chip groups to absorb heat and then enters the second set of chip groups. Exemplarily, the circuit board 110 of this embodiment is vertically configured in a housing of an electronic device, and two upper and lower ends of the housing of the electronic device are beneficial to heat dissipation of the chips 111 in the upper and lower ends of the circuit board 110. Therefore, the number of the chips in these two ends can be more than the middle, so as to achieve temperature equalization between the chips 111.

In some embodiments, the two end chip groups include a first end chip group and a second end chip group, and the number of the chips in the first end chip group is less than the number of the chips in the second end chip group, wherein in a perpendicularly placed state of the circuit board 110, the first end chip group is close to a top of the circuit board 110, and the second end chip group is close to a bottom of the circuit board 110.

Exemplarily, the first set of chip groups and the second set of chip groups are distributed along a heat dissipation direction. Taking air-cooled heat dissipation as an example, wind first enters the first set of chip groups to absorb heat and then enters the second set of chip groups. In the heat dissipation direction, the wind temperature gradually increases. Since wind with higher temperature more tends to rise, high temperature wind rises to the first end chip group, and low temperature wind enters the second end chip group. By setting the number of the chips contained in the first end chip group to be less than the number of the chips contained in the second end chip group, the temperature equalization of the chips can be better achieved.

In some embodiments, in the parallel connection direction of the vertical chips, the average spacing between the chips 111 in each end chip group is less than the average spacing between the chips 111 in the middle chip group.

Exemplarily, the first set of chip groups and the second set of chip groups are distributed along a heat dissipation direction. Taking air-cooled heat dissipation as an example, the wind first enters the first set of chip groups to absorb heat and then enters the second set of chip groups. Exemplarily, the circuit board 110 of this embodiment is vertically configured in the housing of the electronic device, and the upper and lower ends of the electronic device housing are beneficial to the heat dissipation of the chips at the upper and lower ends of the circuit board 110, so the chip spacing at the two ends can be smaller than the middle, so as to achieve temperature equalization between the chips 111.

In some embodiments, along a heat dissipation direction, an average chip spacing in the first set of chip groups is less than an average chip spacing in the second set of chip groups.

Exemplarily, the first set of chip groups and the second set of chip groups are distributed along the heat dissipation direction. Taking air-cooled heat dissipation as an example, wind first enters the first set of chip groups to absorb heat and then enters the second set of chip groups, and the temperature of wind entering the second set of chip groups is higher. By setting the average chip spacing in the first set of chip groups to be smaller than the average chip spacing in the second set of chip groups, chip rows in the second set of chip groups are sparser, which facilitates achievement of the temperature equalization between the chips 111 on the entire circuit board 110.

In some embodiments, in a direction perpendicular to a parallel connection direction of chips, a length of an electrical connection line between adjacent chip groups are greater than a length of an electrical connection line between adjacent chips within a chip group. Exemplarily, the electrical connection line includes a power line 115 and/or a signal line 116.

In the embodiment shown in FIG. 2B, the circuit board 110 includes a first set of chip groups and a second set of chip groups distributed left and right, wherein the second set of chip groups includes three chip groups in upper, middle and lower portions. As can be seen, lengths of power lines 115 between the chip groups 118 are longer than lengths of power lines 115 between chips within each chip group 118. The same situation exists in FIG. 19B and FIG. 21B, which will not be repeated here.

In the embodiment shown in FIG. 2C, the circuit board 110 includes a first set of chip groups and a second set of chip groups distributed left and right, wherein the second set of chip groups includes three chip groups in upper, middle and lower portions. As can be seen, lengths of signal lines 116 between the chip groups 118 are longer than lengths of signal lines 116 between chips within each chip group 118.

In some embodiments, in a direction perpendicular to a parallel connection direction of chips, metal pieces are provided between adjacent chip groups. By providing metal pieces between adjacent chip groups, the voltage drop between the adjacent chip groups can be decreased.

In some embodiments, in the direction perpendicular to the parallel connection direction of the chips, metal pieces are provided between adjacent chips within each chip group 118, and lengths of metal pieces between adjacent chip groups are greater than lengths of metal pieces between adjacent chips 111. By providing metal pieces between adjacent chip groups and between chips 111 within a chip group, the voltage drop between adjacent chips 111 can be decreased.

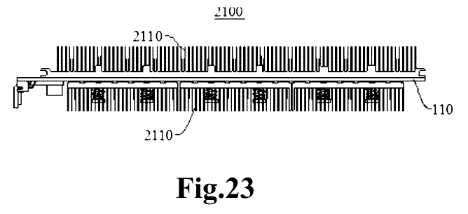

On the other hand, as shown in FIG. 23, the present application further provides a working assembly 2100, which includes:

a circuit board 110, as described in any of the above embodiments; and

a heat sink 211, this heat sink including a heat dissipation body and heat dissipation fins, the heat dissipation body including a first surface and a second surface opposite to each other, and the first surface connected with the heat dissipation fins. In addition, the second surface is provided with a plurality of bosses, each provided corresponding to each row of the chips or each column of the chips.

Further, the second surface is provided with a plurality of bosses, at least some provided at corresponding locations between at least some of the adjacent chip groups 118, or between at least some of the adjacent power taking units, or of at least some vacant positions.

It needs to be explained that if there are vacant positions 113 on the circuit board 110, one possible situation is that at least some of the bosses correspond to the vacant positions 113.

In this embodiment, at least some of the bosses are provided at corresponding locations between at least some of the adjacent chip groups 118, namely, the bosses are provided corresponding to gaps between the chip groups 118, and a heat dissipation channel is formed between the bosses and the gaps. In air-cooled heat dissipation, the wind volume through this heat dissipation channel can be improved, which is beneficial to the temperature equalization of the chips on the entire circuit board.

The circuit boards 110 according to a plurality of embodiments of the present application will be described below in conjunction with FIGS. 1B-21B.

### Embodiment One

FIG. 1B shows a schematic structural view of a circuit board 110 according to Embodiment One of the present application. In Embodiment One, a heat dissipation direction is the direction from left to right in FIG. 1B, a parallel connection direction and a row direction are the left-right direction in FIG. 1B, and a direction perpendicular to the parallel connection direction, a direction perpendicular to the heat dissipation direction and a column direction are the up-down direction in FIG. 1B.

As shown in FIG. 1B, the circuit board 110 is provided with a chip array, and the number of the chips 111 in the chip array is greater than 20 or 50. For example, the number of the chips 111 in the chip array in FIG. 1B is 120. The chip array is set to be X*Y, a maximum value of the number of column chips in the column direction of the chip array is X, and a maximum value of the number of row chips in the row direction of the chip array is Y. In Embodiment One, X is 21, and Y is 6.

In the example of FIG. 1B, in the left-right direction, a rectangular area of the circuit board 110 occupied by the chip array is divided into two distribution zones, namely, a maximum value Y of the number of row chips equally divides the chip array into two distribution zones, which are respectively a first distribution zone (e.g., the left three columns of the chips in FIG. 1B) and a second distribution zone (e.g., the right three columns of the chips in FIG. 1B), with the numbers of the power taking units 114 within the first distribution zone and the second distribution zone not equal. Specifically, the first distribution zone includes 63 chips 111 arranged in 21 rows and 3 columns, and 3 chips 111 in each row in the first distribution zone are connected in parallel to constitute 1 power taking unit 114, so the first distribution zone includes 21 power taking units 114. The second distribution zone includes 57 chips 111 arranged in 19 rows and 3 columns, and 3 chips 111 in each row in the second distribution zone are connected in parallel to constitute 1 power taking unit 114, so the second distribution zone includes 19 power taking units 114.

Of course, the maximum value Y of the number of row chips can also divide the chip array into more than two distribution zones. The number of distribution zones is not limited in the present application.

In Embodiment One, the row direction of the chips 111 is the heat dissipation direction, and the number of columns in the first distribution zone and the number of columns in the second distribution zone are the same (three columns in both). Of course, the present application is not limited to this. In a case that the column direction of the chips 111 is the heat dissipation direction, the number of rows of the chips 111 in each distribution zone can be the same.

Along the left-right direction, the number of the power taking units 114 within the two distribution zones decreases. As shown in FIG. 1B, the number of the power taking units 114 in the first distribution zone is 21, and the number of the power taking units 114 in the second distribution zone is 19. Of course, the present application is not limited to this. In a case where the number of the power taking units 114 in a distribution zone is greater than 2, the numbers of the power taking units 114 within the adjacent distribution zones do not decrease one by one, and the numbers of the power taking units 114 within several adjacent distribution zones are allowed to increase along the heat dissipation direction, as long as the spacings of the adjacent distribution zones are generally in an increasing trend along the left-right direction. The number of the distribution zones is 6 for illustration. Along the left-right direction, the numbers of the power taking units 114 in the plurality of distribution zones may respectively be 15, 14, 13, 12, 11, and 10; alternatively, the number of the power taking units 114 in the plurality of distribution zones may respectively be 12, 12, 11, 11, 10, and 10; still alternatively, the number of the power taking units 114 in the plurality of distribution zones may respectively be 11, 10, 10, 10, 10, and 10; yet alternatively, the number of the power taking units 114 in the plurality of distribution zones may respectively be 16, 15, 13, 14, 12, and 10. In this way, the total number of the chips in a first half part close to an air inlet is greater than the total number of the chips in a second half part close to an air outlet, which can reduce the maximum temperature difference between the chips 111 close to the air outlet and the chips 111 close to the air inlet, thereby improving the temperature equalization of the chips 111.

Along the up-down direction, the distances between the 21 power taking units 114 in the first distribution zone can be equal. A spacing between the 9th power taking unit 114 and the 10th power taking unit 114 in the second distribution zone can be greater than spacings of other adjacent power taking units 114. In the up-down directions, the above “other adjacent power taking units 114” are non-edge power taking units 114 in the chip array. For example, the spacings of the other adjacent power taking units 114 can be spacings of the adjacent power taking units 114 in the 1st to 9th power taking units 114 provided in the same column and spacings of the adjacent power taking units 114 in the 10th to 19th power taking units 114. The above “spacings of the other adjacent power taking units 114” can be equal to spacings of the adjacent power taking units 114 in the first distribution zone, at which time an average column spacing of the first distribution zone is less than an average column spacing of the second distribution zone.

Along the left-right direction, the distance between the adjacent power taking units 114 increases, and/or the distance between the adjacent chips 111 increases. For example, along the left-right direction, a distance between the first distribution zone and the second distribution zone can be greater than a distance between two adjacent columns of the chips 111 in each distribution zone; alternatively, along the heat dissipation direction, a distance between the first distribution zone and the second distribution zone can be equal to a distance between two adjacent columns of the chips 111 in each distribution zone; still alternatively, along the heat dissipation direction, distances between multiple columns of the chips 111 can gradually increase or decrease.

In the up-down direction, the rectangular area of the circuit board 110 occupied by the chip array is divided into a plurality of sub-areas, and the numbers of the power taking units 114 in at least two sub-areas are not equal. In Embodiment One, based on the spacing between the 9th power taking unit 114 and the 10th power taking unit 114 in the second distribution zone, the 1st to 9th power taking units 114 in the second distribution zone can be divided in a sub-area, which includes 27 chips 111 arranged in 9 rows and 3 columns; and the 10th to 19th power taking units 114 can be divided in another sub-area, which includes 30 chips 111 arranged in 10 rows and 3 columns.

Thus, in the up-down direction, the 19 power taking units 114 in the second distribution zone can be partitioned according to the spacing between the adjacent power taking units 114, so as to divide the 19 power taking units 114 into two sub-areas. Power taking units 114 in each sub-area can be arranged with equal spacings, and a spacing between the two sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

In the left-right direction, at least some of the power taking units 114 in the first distribution zone and the second distribution zone are respectively on the same straight line. Specifically, in FIG. 1B, 120 chips 111 in the chip array are arranged in 21 rows and 6 columns, and centers of the chips 111 in each row are on a straight line, and centers of the chips 111 in each column are on a straight line. Row spacings of the chips 111 in first 3 columns are the same, and the 10th and 11th rows of the chips 111 in second 3 columns are missing. The number of the chips 111 in the first 3 columns is 63, and the number of the chips 111 in the second 3 columns is 57. The row direction of the chip array can be a heat dissipation direction, and a column direction of the chip array is perpendicular to the heat dissipation direction of the chips 111. In this way, a total number of the chips 111 in a first half part close to an air inlet is greater than a total number of the chips 111 in a second half part close to an air outlet. The number of the chips 111 at the air inlet is large, which can increase the heat generation of the chips 111 at the air inlet, and the number of the chips 111 at the air outlet is small, which can decrease the heat generation of the chips 111 at the air outlet, so that the maximum temperature difference between the chips 111 close to the air outlet and the chips 111 close to the air inlet can be further reduced, thereby improving the temperature equalization of the chips 111.

Optionally, row spacings of the chips 111 in each distribution zone can be the same, and centers of a plurality of the chips 111 in each row can be on a straight line. Along the series connection direction, centers of the three chips 111 in the end of the first distribution zone and those of the three chips 111 in the end of a corresponding sub-area are on a straight line. A gap between the two sub-areas corresponds to the chips 111 in the 10th and 11th rows of the first distribution zone in the first direction.

Metal pieces can be provided between the adjacent power taking units 114, and along the up-down direction, lengths of metal pieces between at least some of the adjacent power taking units 114 are longer than those between other adjacent power taking units 114. Thus, the metal pieces provided as such can decrease the resistance of the current channel, decrease the voltage drop of the current channel, and thereby decrease the energy loss on the current channel.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 1B, the 120 chips 111 on the circuit board 110 are arranged in multiple rows, and the row direction is parallel to a direction from the air inlet to the air outlet of a heat dissipation duct. The number of the chips 111 in the 10th and 11th rows is 3 respectively, and the number of the chips 111 in other rows is 6, so the number of the chips 111 in the 10th and 11th rows is less than the number of the chips 111 in other rows. At least some of the bosses can be provided at corresponding locations between the 9th power taking unit 114 and the 10th power taking unit 114.

In a case that no chip vacant position is provided in FIG. 1A, the temperature at which the chip array works for a period of time under a preset total power is shown as below, and it can be seen that the chip temperature fluctuates in a range of 65 °C to 75 °C, with a temperature difference of about 10 °C.

| | | | | | |
|---|---|---|---|---|---|
| 65.7661 | 67.1192 | 67.4797 | 70.53 | 71.3647 | 72.0779 |
| 66.4376 | 67.7707 | 68.0896 | 71.1034 | 71.9325 | 72.5633 |
| 66.9813 | 68.3128 | 68.6146 | 71.5651 | 72.3926 | 72.9653 |
| 67.4885 | 68.7912 | 69.0691 | 71.9758 | 72.7952 | 73.3313 |
| 67.9664 | 69.2214 | 69.4687 | 72.3512 | 73.1521 | 73.6624 |
| 68.3031 | 69.5567 | 69.7961 | 72.6405 | 73.4292 | 73.9125 |
| 68.5464 | 69.8498 | 70.1057 | 72.8693 | 73.6426 | 74.0891 |
| 69.0725 | 70.1821 | 70.3641 | 73.1448 | 73.9622 | 74.5259 |
| 69.206 | 70.289 | 70.4579 | 73.2387 | 74.0482 | 74.6277 |
| 69.2799 | 70.35 | 70.5106 | 73.2745 | 74.0858 | 74.6698 |
| 69.2823 | 70.3747 | 70.5344 | 73.2781 | 74.0948 | 74.6721 |
| 69.3064 | 70.4018 | 70.5627 | 73.3025 | 74.1175 | 74.6875 |
| 69.3547 | 70.4318 | 70.5961 | 73.3473 | 74.1508 | 74.7116 |
| 69.3128 | 70.4311 | 70.6138 | 73.3686 | 74.1608 | 74.7025 |
| 69.1971 | 70.3912 | 70.6127 | 73.3354 | 74.1148 | 74.6214 |
| 68.0349 | 69.2126 | 69.3972 | 72.0961 | 72.8755 | 73.3016 |
| 67.7678 | 68.9435 | 69.1434 | 71.8942 | 72.6758 | 73.1253 |
| 67.3974 | 68.6086 | 68.8325 | 71.6144 | 72.401 | 72.8669 |
| 66.8763 | 68.1393 | 68.3955 | 71.214 | 72.0113 | 72.4998 |
| 66.2791 | 67.5662 | 67.8582 | 70.7262 | 71.5284 | 72.0627 |
| 65.5809 | 66.8383 | 67.1808 | 70.113 | 70.907 | 71.5372 |

In FIG. 1B, there are provided chip vacant positions 113. In a case where the preset total power remains unchanged, the temperature at which the chip array works for a period of time is shown as below, and it can be seen that the chip temperature fluctuates in a range of 70 °C to 75 °C, with a temperature difference of about 5 °C. It needs to be explained that the preset power remains unchanged, but the number of the chips decreases, so the average power of each chip increases, resulting in an increase in the heat generation of each chip 111. However, in FIG. 1B, due to the existence of the chip vacant positions 113, the maximum value of the temperature is still about 75 °C, the chip heat dissipation is improved, and the chip temperature equalization is further improved. As indicated by this, the present application is beneficial to the heat dissipation and temperature equalization of the circuit board 110. The above embodiment does not represent the final actual use effect, but only makes explanation for the invention points of heat dissipation and temperature equalization of the present application.

| | | | | | |
|---|---|---|---|---|---|
| 70.0432 | 70.1548 | 70.364 | 72.834 | 73.5258 | 73.867 |
| 70.0548 | 70.8121 | 70.9449 | 73.0988 | 73.7573 | 74.0731 |
| 70.0932 | 71.3405 | 71.4177 | 72.8335 | 73.4578 | 73.8548 |
| 70.6 | 71.7987 | 71.8266 | 73.4578 | 73.8548 | 74.1 |
| 71.075 | 72.2102 | 72.2044 | 73.4183 | 73.9927 | 74.291 |
| 71.4001 | 72.5274 | 72.5187 | 74.207 | 74.7697 | 74.8837 |
| 71.6197 | 72.7939 | 72.797 | 74.4622 | 75.0018 | 74.9 |
| 71.9372 | 72.8258 | 72.6355 | 73.2006 | 73.6691 | 73.8608 |
| 72.059 | 72.9092 | 72.7051 | 73.7475 | 74.2169 | 74.3151 |
| 72.1276 | 72.9662 | 72.7572 | | | |
| 72.1277 | 72.9985 | 72.7906 | | | |
| 72.1587 | 73.0369 | 72.8337 | 73.4244 | 73.896 | 74.0708 |
| 72.2223 | 73.083 | 72.8942 | 73.3123 | 73.7776 | 73.9649 |
| 72.1951 | 73.1077 | 72.9552 | 73.676 | 74.1513 | 74.2813 |
| 72.0929 | 73.1015 | 73.0012 | 74.2516 | 74.7225 | 74.6985 |
| 71.0491 | 72.0761 | 71.9786 | 73.3846 | 73.9099 | 73.9535 |
| 70.8002 | 71.8328 | 71.7584 | 72.7423 | 73.2792 | 73.4918 |
| 70.4381 | 71.5234 | 71.4839 | 71.1004 | 72.3414 | 72.9239 |
| 70.1345 | 71.0812 | 71.1004 | 72.3414 | 72.9239 | 73.2048 |
| 70.0587 | 70.5245 | 70.6201 | 72.5989 | 73.2173 | 73.4091 |
| 70.0387 | 70.0587 | 70.4381 | 72.3075 | 72.9496 | 73.1862 |

### Embodiment Two

FIG. 2A shows a schematic structural view of a circuit board 110 according to Embodiment Two of the present application. As shown in FIG. 2A, the number of the chips 111 in the chip array on the circuit board 110 is 120. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 63 chips 111 arranged in 21 rows and 3 columns, and the 3 chips 111 in each row of the first distribution zone are connected in parallel to constitute 1 power taking unit 114, so the first distribution zone includes 21 power taking units 114. Distances between the 21 power taking units 114 in the first distribution zone can be equal. The second distribution zone includes 57 chips 111 arranged in 19 rows and 3 columns, and the 3 chips 111 in each row of the second distribution zone are connected in parallel to constitute 1 power taking unit 114, so the second distribution zone includes 19 power taking units 114. In a series connection direction, a spacing between the 7th power taking unit 114 and the 8th power taking unit 114 and a spacing between the 12th power taking unit 114 and the 13th power taking unit 114 can be greater than spacings of other adjacent power taking units 114.

In a direction perpendicular to a parallel connection direction, the above “other adjacent power taking units 114” are non-edge power taking units 114 in the chip array. For example, the spacings of the other adjacent power taking units 114 can be spacings of the 1st to 7th power taking units 114, spacings of the 8th to 12th power taking units 114, and spacings of the 13th to 19th power taking units 114 provided in the same column. In FIG. 2A, the parallel connection direction is a row direction.

Based on the spacing between the 7th power taking unit 114 and the 8th power taking unit 114 and the spacing between the 12th power taking unit 114 and the 13th power taking unit 114, the 1st to 7th power taking units 114 in the second distribution zone can be divided in a first sub-area, which includes 21 chips 111 arranged in 7 rows and 3 columns; the 8th to 12th power taking units 114 can be divided in a second sub-area, which includes 15 chips 111 arranged in 5 rows and 3 columns; and the 13th to 19th power taking units 114 can be divided in a third sub-area, which also includes 21 chips 111 arranged in 7 rows and 3 columns.

Thus, in the series connection direction, the 19 power taking units 114 in the second distribution zone can be partitioned according to the spacings between the adjacent power taking units 114, so as to divide the 19 power taking units 114 into three sub-areas. Power taking units 114 in each sub-area can be arranged with equal spacings, and a spacing between two sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

Along the parallel connection direction, the number of the power taking units 114 in each distribution zone can decrease. As shown in FIG. 2A, the number of the power taking units 114 in the first distribution zone can be 21, and the number of the power taking units 114 in the second distribution zone can be 19. Of course, the present application is not limited to this. In a case where the number of the power taking units 114 in a distribution zone is greater than 2, the numbers of the power taking units 114 within adjacent distribution zones may gradually decrease in sequence, may gradually decrease in part, or may decrease in part. The number of the distribution zones is 6 for illustration. Along the parallel connection direction, the numbers of the power taking units 114 in the plurality of distribution zones may respectively be 15, 14, 13, 12, 11, and 10; alternatively, the numbers of the power taking units 114 in the plurality of distribution zones may respectively be 12, 12, 11, 11, 10, and 10; still alternatively, the numbers of the power taking units 114 in the plurality of distribution zones may respectively be 11, 10, 10, 10, 10, and 10.

Metal pieces can be provided between the adjacent power taking units 114, and along the series connection direction, lengths of metal pieces between at least some of the adjacent power taking units 114 are longer than those between other adjacent power taking units 114, wherein a long direction is perpendicular to the parallel connection direction. For example, the metal pieces may be a copper sheet. Thus, the metal pieces provided as such can decrease the resistance of the current channel, decrease the voltage drop of the current channel, and thereby decrease the energy loss on the current channel.

Row spacings of the chips 111 in each distribution zone are the same, and centers of a plurality of the chips 111 in each row are on a straight line. Along the series connection direction, centers of the three chips 111 in the end of the first distribution zone and those of the three chips 111 in the end of a corresponding sub-area are on a straight line. Gaps between two adjacent sub-areas correspond to the chips 111 in the 8th and 14th rows of the first distribution zone in the first direction, respectively.

That is to say, 120 chips 111 in the chip array are arranged in 21 rows and 6 columns, with centers of the chips 111 in each row on a straight line, and centers of the chips 111 in each column on a straight line. Row spacings of the chips 111 in first 3 columns are the same, and the 8th and 14th rows of the chips 111 in second 3 columns are missing. The number of the chips 111 in the first 3 columns is 63, and the number of the chips 111 in the second 3 columns is 57. The row direction of the chip array can be a heat dissipation direction. In this way, a total number of the chips 111 in a first half part close to an air inlet is greater than a total number of the chips 111 in a second half part close to an air outlet, which can also decrease the maximum temperature difference between the chips 111 close to the air outlet and the chips 111 close to the air inlet, thereby improving the temperature equalization of the chips 111.

Optionally, along a direction perpendicular to the heat dissipation direction, the second distribution zone is distributed in two end areas and one middle area. The number of the chips 111 in each end area is greater than or equal to the number of the chips 111 in the middle area. In FIG. 2A, the chips 111 in the end areas are the chips 111 in the first sub-area and the chips 111 in the third sub-area, and the chips 111 in the middle area are the chips 111 in the second sub-area. The number of the chips 111 in each end area is 21, and the number of the chips 111 in the middle area is 15. Thus, in a case where the circuit board 110 is applied to an electronic device 3100, since the chips in the two end areas are closer to the external environment and the heat dissipation is better, by disposing a large number of the chips 111 in the end areas and a small number of the chips 111 in the middle area, the chip temperature in the middle area can be effectively reduced, thereby decreasing the temperature difference between the chips 111 in the middle area and the chips 111 in the end areas, improving the heat dissipation effect of the circuit board 110, and ensuring the overall performance of the circuit board 110.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 2A, the 120 chips 111 on the circuit board 110 are arranged in multiple rows, and the row direction is parallel to a direction from the air inlet to the air outlet of a heat dissipation duct. The number of the chips 111 in the 8th and 14th rows is 3 respectively, and the number of the chips 111 in other rows is 6, so the number of the chips 111 in the 8th and 14th rows is less than the number of the chips 111 in other rows. At least some of the bosses can be provided at corresponding locations between the 7th power taking unit 114 and the 8th power taking unit 114, and corresponding locations between the 12th power taking unit 114 and the 13th power taking unit 114.

FIG. 2B shows a current diagram of the circuit board 110 shown in FIG. 2A; and FIG. 2C shows a signal diagram of the circuit board 110 shown in FIG. 2A. As shown in FIGS. 2B and 2C, along the series connection direction of each chip 111 set, lengths of electrical connection lines between the adjacent distribution zones are greater than lengths of electrical connection lines between the adjacent power taking units 114 in each distribution zone. The electrical connection lines may be the lengths of power lines 115 and/or signal lines 116.

In addition, an upper edge of the circuit board 110 is provided with a first electrical connector 119 and a second electrical connector 119′, and the first electrical connector 119 and the second electrical connector 119′ may be L-shaped. The above is only an example, and the location and shape of the first electrical connector 119 and the second electrical connector 119′ are not limited. Specifically, the first electrical connector 119 and the second electrical connector 119′ are not merely limited to being provided on the upper edge as shown in FIG. 2A, but may also be provided at locations on other edges. That is, as for the L-shaped power supply terminals shown in each figure, the location thereof is not limited to that in the figure, and may also be provided in the top, bottom, left, right or any location of the circuit board.

It needs to be explained that, as shown in FIG. 2B, the plurality of chips 111 on the circuit board 110 adopt a series-parallel power supply connection manner. Specifically, every three chips are connected in parallel to constitute a power taking unit 114, and a plurality of power taking units 114 are connected in series between the first electrical connector 119 and the second electrical connector 119′. Only as an example, the above power taking units 114 are each composed of three chips, which may also be composed of 2, 4, 5 or even more chips connected in parallel, and the present application makes no limitation in this regard.

In FIG. 2A, there are provided chip vacant positions 113. In a case where a preset total power remains unchanged, the temperature at which the chip array works for a period of time is shown as below, and it can be seen that the chip temperature fluctuates in a range of 70 °C to 75 °C, with a temperature difference of about 5 °C. It needs to be explained that the preset power remains unchanged, but the number of the chips 111 decreases, so the average power of each chip 111 increases, resulting in an increase in the heat generation of each chip 111. However, in FIG. 1B, due to the existence of the chip vacant positions 113, the maximum value of the temperature is still about 75 °C, the chip heat dissipation is improved, and the chip temperature equalization is further improved. As indicated by this, the present application is beneficial to the heat dissipation and temperature equalization of the circuit board 110. The above embodiment does not represent the final actual use effect, but only makes explanation for the invention points of heat dissipation and temperature equalization of the present application.

### Embodiment Three

FIG. 3 shows a schematic structural view of a circuit board 110 according to Embodiment Three of the present application. As shown in FIG. 3, the number of the chips 111 in a chip array on the circuit board 110 is 117. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 63 chips 111 arranged in 21 rows and 3 columns, and the 3 chips 111 in each row of the first distribution zone are connected in parallel to constitute 1 power taking unit 114, so the first distribution zone includes 21 power taking units 114. Spacings of the power taking units 114 in the first distribution zone can be equal. The second distribution zone includes 54 chips 111 arranged in 18 rows and 3 columns, and the 3 chips 111 in each row of the second distribution zone are connected in parallel to constitute 1 power taking unit 114, so the second distribution zone includes 18 power taking units 114. In a series connection direction, a spacing between the 5th power taking unit 114 and the 6th power taking unit 114, a spacing between the 9th power taking unit 114 and the 10th power taking unit 114, and a spacing between the 13th power taking unit 114 and the 14th power taking unit 114 can be greater than spacings of other adjacent power taking units 114.

In a direction perpendicular to a parallel connection direction, the above “other adjacent power taking units 114” are non-edge power taking units 114 in the chip array. The spacings of the other adjacent power taking units 114 can be spacings of the 1st to 5th power taking units 114, spacings of the 6th to 9th power taking units 114, spacings of the 10th to 13th power taking units 114, and spacings of the 13th to 19th power taking units 114 provided in the same column. In FIG. 3, the parallel connection direction is a row direction.

Based on the spacing between the 5th power taking unit 114 and the 6th power taking unit 114, the spacing between the 9th power taking unit 114 and the 10th power taking unit 114, and the spacing between the 13th power taking unit 114 and the 14th power taking unit 114, the 1st to 5th power taking units 114 in the second distribution zone can be divided in a first sub-area, which includes 15 chips 111 arranged in 5 rows and 3 columns; the 6th to 9th power taking units 114 can be divided in a second sub-area, which includes 12 chips 111 arranged in 4 rows and 3 columns; the 10th to 13th power taking units 114 can be divided in a third sub-area, which also includes 12 chips 111 arranged in 4 rows and 3 columns; and the 14th to 18th power taking units 114 can be divided in a fourth sub-area, which includes 15 chips 111 arranged in 5 rows and 3 columns.

Thus, in the series connection direction, the 18 power taking units 114 in the second distribution zone can be partitioned according to the spacings between the adjacent power taking units 114, so as to divide the 18 power taking units 114 into 4 sub-areas. Power taking units 114 in each sub-area can be arranged with equal spacings, and a spacing between two adjacent sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

Along the parallel connection direction, the number of the power taking units 114 in each distribution zone can decrease. As shown in FIG. 3, the number of the power taking units 114 in the first distribution zone can be 21, and the number of the power taking units 114 in the second distribution zone can be 18. Of course, the present application is not limited to this. In a case where the number of the power taking units 114 in a distribution zone is greater than 2, the numbers of the power taking units 114 within adjacent distribution zones may gradually decrease in sequence, may gradually decrease in part, or may decrease in part. The number of the distribution zones is 6 for illustration. Along the parallel connection direction, the numbers of the power taking units 114 in the plurality of distribution zones may respectively be 15, 14, 13, 12, 11, and 10; alternatively, the numbers of the power taking units 114 in the plurality of distribution zones may respectively be 12, 12, 11, 11, 10, and 10; still alternatively, the numbers of the power taking units 114 in the plurality of distribution zones may respectively be 11, 10, 10, 10, 10, and 10.

Metal pieces can be provided between the adjacent power taking units 114, and along the series connection direction, lengths of metal pieces between at least some of the adjacent power taking units 114 are longer than those between other adjacent power taking units 114, wherein a long direction is perpendicular to the parallel connection direction. For example, the metal pieces may be a copper sheet. Thus, the metal pieces provided as such can decrease the resistance of the current channel, decrease the voltage drop of the current channel, and thereby decrease the energy loss on the current channel.

Row spacings of the chips 111 in each distribution zone are the same, and centers of a plurality of the chips 111 in each row are on a straight line. Along the series connection direction, centers of the three chips 111 in the end of the first distribution zone and those of the three chips 111 in the end of a corresponding sub-area are on a straight line. Gaps between two adjacent sub-areas correspond to the chips 111 in the 6th row, the 11th row, and the 16th row of the first distribution zone in the first direction, respectively.

That is to say, 117 chips 111 in the chip array are arranged in 21 rows and 6 columns, with centers of the chips 111 in each row on a straight line, and centers of the chips 111 in each column on a straight line. Row spacings of the chips 111 in first 3 columns are the same, and the 6th, 11th, and the 16th rows of the chips 111 in second 3 columns are missing. The number of the chips 111 in the first 3 columns is 63, and the number of the chips 111 in the second 3 columns is 54. The row direction of the chip array can be a heat dissipation direction. In this way, a total number of the chips 111 in a first half part close to an air inlet is greater than a total number of the chips 111 in a second half part close to an air outlet, which can also decrease the maximum temperature difference between the chips 111 close to the air outlet and the chips 111 close to the air inlet, thereby improving the temperature equalization of the chips 111.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 3, the 117 chips 111 on the circuit board 110 are arranged in multiple rows, and the row direction is parallel to a direction from the air inlet to the air outlet of a heat dissipation duct. The number of the chips 111 in the 6th row, the 11th row, and the 16th row is 3 respectively, and the number of the chips 111 in other rows is 6, so the number of the chips 111 in the 6th row, the 11th row, and the 16th row is less than the number of the chips 111 in other rows. At least some of the bosses can be provided at corresponding locations between the 5th power taking unit 114 and the 6th power taking unit 114, corresponding locations between the 9th power taking unit 114 and the 10th power taking unit 114, and corresponding locations between the 13th power taking unit 114 and the 14th power taking unit 114 in the second distribution zone.

### Embodiment Four

FIG. 4 shows a schematic structural view of a circuit board 110 according to Embodiment Four of the present application. As shown in FIG. 4, the number of the chips 111 in a chip array on the circuit board 110 is 120. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 66 chips 111 arranged in 22 rows and 3 columns, and the 3 chips 111 in each row of the first distribution zone are connected in parallel to constitute 1 power taking unit 114, so the first distribution zone includes 22 power taking units 114. Spacings of the power taking units 114 in the first distribution zone can be equal. The second distribution zone includes 54 chips 111 arranged in 18 rows and 3 columns, and the 3 chips 111 in each row of the second distribution zone are connected in parallel to constitute 1 power taking unit 114, so the second distribution zone includes 18 power taking units 114. In a series connection direction, a spacing between the 4th power taking unit 114 and the 5th power taking unit 114, a spacing between the 7th power taking unit 114 and the 8th power taking unit 114, a spacing between the 11th power taking unit 114 and the 12th power taking unit 114, and a spacing between the 14th power taking unit 114 and the 15th power taking unit 114 in the second distribution zone can be greater than spacings of other adjacent power taking units 114.

In a direction perpendicular to a parallel connection direction, the above “other adjacent power taking units 114” are non-edge power taking units 114 in the chip array. The spacings of the other adjacent power taking units 114 can be spacings of the 1st to 4th power taking units 114, spacings of the 5th to 7th power taking units 114, spacings of the 8th to 11th power taking units 114, spacings of the 12th to 14th power taking units 114, and spacings of the 15th to 18th power taking units 114 provided in the same column. In FIG. 4, the parallel connection direction is a row direction.

Based on the spacing between the 4th power taking unit 114 and the 5th power taking unit 114, the spacing between the 7th power taking unit 114 and the 8th power taking unit 114, the spacing between the 11th power taking unit 114 and the 12th power taking unit 114, and the spacing between the 14th power taking unit 114 and the 15th power taking unit 114, the 1st to 4th power taking units 114 in the second distribution zone can be divided in a first sub-area, which includes 12 chips 111 arranged in 4 rows and 3 columns; the 5th to 7th power taking units 114 can be divided in a second sub-area, which includes 9 chips 111 arranged in 3 rows and 3 columns; the 8th to 11th power taking units 114 can be divided in a third sub-area, which includes 12 chips 111 arranged in 4 rows and 3 columns; the 12th to 14th power taking units 114 can be divided in a fourth sub-area, which includes 9 chips 111 arranged in 3 rows and 3 columns; and the 15th to 18th power taking units 114 can be divided in a fifth sub-area, which includes 12 chips 111 arranged in 4 rows and 3 columns.

Thus, in the series connection direction, the 18 power taking units 114 in the second distribution zone can be partitioned according to the spacings between the adjacent power taking units 114, so as to divide the 18 power taking units 114 into 5 sub-areas. Power taking units 114 in each sub-area can be arranged with equal spacings, and a spacing between two adjacent sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

Along the parallel connection direction, the number of the power taking units 114 in each distribution zone can decrease. As shown in FIG. 4, the number of the power taking units 114 in the first distribution zone can be 22, and the number of the power taking units 114 in the second distribution zone can be 18. Of course, the present application is not limited to this. In a case where the number of the power taking units 114 in a distribution zone is greater than 2, the numbers of the power taking units 114 within adjacent distribution zones may gradually decrease in sequence, may gradually decrease in part, or may decrease in part. The number of the distribution zones is 6 for illustration. Along the parallel connection direction, the numbers of the power taking units 114 in the plurality of distribution zones may respectively be 15, 14, 13, 12, 11, and 10; alternatively, the numbers of the power taking units 114 in the plurality of distribution zones may respectively be 12, 12, 11, 11, 10, and 10; still alternatively, the numbers of the power taking units 114 in the plurality of distribution zones may respectively be 11, 10, 10, 10, 10, and 10.

Metal pieces can be provided between the adjacent power taking units 114, and along the series connection direction, lengths of metal pieces between at least some of the adjacent power taking units 114 are longer than those between other adjacent power taking units 114, wherein a long direction is perpendicular to the parallel connection direction. For example, the metal pieces may be a copper sheet. Thus, the metal pieces provided as such can decrease the resistance of the current channel, decrease the voltage drop of the current channel, and thereby decrease the energy loss on the current channel.

Row spacings of the chips 111 in each distribution zone are the same, and centers of a plurality of the chips 111 in each row are on a straight line. Along the series connection direction, centers of the three chips 111 in the end of the first distribution zone and those of the three chips 111 in the end of a corresponding sub-area are on a straight line. Gaps between two adjacent sub-areas correspond to the chips 111 in the 5th row, the 9th row, the 14th row, and the 18th row of the first distribution zone in the first direction, respectively.

That is to say, 120 chips 111 in the chip array are arranged in 22 rows and 6 columns, with centers of the chips 111 in each row on a straight line, and centers of the chips 111 in each column on a straight line. Row spacings of the chips 111 in first 3 columns are the same, and the 5th, 9th, 14th, and the 18th rows of the chips 111 in second 3 columns are missing. The number of the chips 111 in the first 3 columns is 66, and the number of the chips 111 in the second 3 columns is 54. The row direction of the chip array can be a heat dissipation direction. In this way, a total number of the chips 111 in a first half part close to an air inlet is greater than a total number of the chips 111 in a second half part close to an air outlet, which can also decrease the maximum temperature difference between the chips 111 close to the air outlet and the chips 111 close to the air inlet, thereby improving the temperature equalization of the chips 111.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 4, the 120 chips 111 on the circuit board 110 are arranged in multiple rows, and the row direction is parallel to a heat dissipation direction from the air inlet to the air outlet of a heat dissipation duct. The number of the chips 111 in the 5th row, the 9th row, the 14th row, and the 18th row is 3 respectively, and the number of the chips 111 in other rows is 6, so the number of the chips 111 in the 5th row, the 9th row, the 14th row, and the 18th row is less than the number of the chips 111 in other rows. At least some of the bosses can be provided at corresponding locations between the 4th power taking unit 114 and the 5th power taking unit 114, corresponding locations between the 7th power taking unit 114 and the 8th power taking unit 114, corresponding locations between the 11th power taking unit 114 and the 12th power taking unit 114, and corresponding locations between the 14th power taking unit 114 and the 15th power taking unit 114 in the second distribution zone.

### Embodiment Five

FIG. 5 shows a structural schematic view of a circuit board 110 according to Embodiment Five of the present application. As shown in FIG. 5, the number of the chips 111 in a chip array on the circuit board 110 is 120. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 66 chips 111 arranged in 22 rows and 3 columns, and the 3 chips 111 in each row of the first distribution zone are connected in parallel to constitute 1 power taking unit 114, so the first distribution zone includes 22 power taking units 114. Spacings of the power taking units 114 in the first distribution zone can be equal. The second distribution zone includes 54 chips 111 arranged in 18 rows and 3 columns, and the 3 chips 111 in each row of the second distribution zone are connected in parallel to constitute 1 power taking unit 114, so the second distribution zone includes 18 power taking units 114. In a series connection direction, a spacing between the 4th power taking unit 114 and the 5th power taking unit 114, a spacing between the 7th power taking unit 114 and the 8th power taking unit 114, a spacing between the 10th power taking unit 114 and the 11th power taking unit 114, and a spacing between the 14th power taking unit 114 and the 15th power taking unit 114 in the second distribution zone can be greater than spacings of other adjacent power taking units 114.

In a direction perpendicular to a parallel connection direction, the above “other adjacent power taking units 114” are non-edge power taking units 114 in the chip array. The spacings of the other adjacent power taking units 114 can be spacings of the 1st to 4th power taking units 114, spacings of the 5th to 7th power taking units 114, spacings of the 8th to 10th power taking units 114, spacings of the 11th to 14th power taking units 114, and spacings of the 15th to 18th power taking units 114 provided in the same column. In FIG. 5, the parallel connection direction is a row direction.

Based on the spacing between the 4th power taking unit 114 and the 5th power taking unit 114, the spacing between the 7th power taking unit 114 and the 8th power taking unit 114, the spacing between the 10th power taking unit 114 and the 11th power taking unit 114, and the spacing between the 14th power taking unit 114 and the 15th power taking unit 114, the 1st to 4th power taking units 114 in the second distribution zone can be divided in a first sub-area, which includes 12 chips 111 arranged in 4 rows and 3 columns; the 5th to 7th power taking units 114 can be divided in a second sub-area, which includes 9 chips 111 arranged in 3 rows and 3 columns; the 8th to 10th power taking units 114 can be divided in a third sub-area, which includes 9 chips 111 arranged in 3 rows and 3 columns; the 11th to 14th power taking units 114 can be divided in a fourth sub-area, which includes 12 chips 111 arranged in 4 rows and 3 columns; and the 15th to 18th power taking units 114 can be divided in a fifth sub-area, which includes 12 chips 111 arranged in 4 rows and 3 columns.

Thus, in the series connection direction, the 18 power taking units 114 in the second distribution zone can be partitioned according to the spacings between the adjacent power taking units 114, so as to divide the 18 power taking units 114 into 5 sub-areas. Power taking units 114 in each sub-area can be arranged with equal spacings, and a spacing between two adjacent sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

Along the parallel connection direction, the number of the power taking units 114 in each distribution zone can decrease. As shown in FIG. 5, the number of the power taking units 114 in the first distribution zone can be 22, and the number of the power taking units 114 in the second distribution zone can be 18.

Row spacings of the chips 111 in each distribution zone are the same, and centers of a plurality of the chips 111 in each row are on a straight line. Along the series connection direction, centers of the three chips 111 in the end of the first distribution zone and those of the three chips 111 in the end of a corresponding sub-area are on a straight line. Gaps between two adjacent sub-areas correspond to the chips 111 in the 5th row, the 9th row, the 13th row, and the 18th row of the first distribution zone in the first direction, respectively.

That is to say, 120 chips 111 in the chip array are arranged in 22 rows and 6 columns, with centers of the chips 111 in each row on a straight line, and centers of the chips 111 in each column on a straight line. Row spacings of the chips 111 in first 3 columns are the same, and the 5th, 9th, 13th, and 18th rows of the chips 111 in second 3 columns are missing. The number of the chips 111 in the first 3 columns is 66, and the number of the chips 111 in the second 3 columns is 54. The row direction of the chip array can be a heat dissipation direction. In this way, a total number of the chips 111 in a first half part close to an air inlet is greater than a total number of the chips 111 in a second half part close to an air outlet, which can also decrease the maximum temperature difference between the chips 111 close to the air outlet and the chips 111 close to the air inlet, thereby improving the temperature equalization of the chips 111.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 5, the 120 chips 111 on the circuit board 110 are arranged in multiple rows, and the row direction is parallel to a heat dissipation direction from the air inlet to the air outlet of a heat dissipation duct. The number of the chips 111 in the 5th row, the 9th row, the 13th row, and the 18th row is 3 respectively, and the number of the chips 111 in other rows is 6, so the number of the chips 111 in the 5th row, the 9th row, the 13th row, and the 18th row is less than the number of the chips 111 in other rows. At least some of the bosses can be provided at corresponding locations between the 4th power taking unit 114 and the 5th power taking unit 114, corresponding locations between the 7th power taking unit 114 and the 8th power taking unit 114, corresponding locations between the 10th power taking unit 114 and the 11th power taking unit 114, and corresponding locations between the 14th power taking unit 114 and the 15th power taking unit 114 in the second distribution zone.

### Embodiment Six

FIGS. 6A and 6B show schematic structural views of a circuit board 110 according to Embodiment Six of the present application. As shown in FIGS. 6A and 6B, the number of the chips 111 in a chip array on the circuit board 110 is 120. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 60 chips 111 arranged in 20 rows and 3 columns, and the 3 chips 111 in each row of the first distribution zone are connected in parallel to constitute 1 power taking unit 114, so the first distribution zone includes 20 power taking units 114. Distances between the 20 power taking units 114 in the first distribution zone can be equal. The second distribution zone includes 57 chips 111 arranged in 19 rows and 3 columns, and the 3 chips 111 in each row of the second distribution zone are connected in parallel to constitute 1 power taking unit 114, so the second distribution zone includes 19 power taking units 114. In a column direction, a spacing between the 10th power taking unit and the 11th power taking unit in the first distribution zone can be greater than spacings of other power taking units; and a spacing between the 7th power taking unit 114 and the 8th power taking unit 114, and a spacing between the 12th power taking unit 114 and the 13th power taking unit 114 in the second distribution zone can be greater than spacings of other adjacent power taking units 114. In FIG. 6A, a parallel connection direction is a row direction

Based on the spacing between the 10th power taking unit 114 and the 11th power taking unit 114 in the first distribution zone, the first distribution zone can be divided into two sub-areas, each including 20 chips 111 arranged in 10 rows and 3 columns. Based on the spacing between the 7th power taking unit 114 and the 8th power taking unit 114, and the spacing between the 12th power taking unit 114 and the 13th power taking unit 114, the 1st to 7th power taking units 114 in the second distribution zone can be divided in a first sub-area, which includes 21 chips 111 arranged in 7 rows and 3 columns; the 8th to 12th power taking units 114 can be divided in a second sub-area, which includes 15 chips 111 arranged in 5 rows and 3 columns; and the 13th to 19th power taking units 114 can be divided in a third sub-area, which includes 21 chips 111 arranged in 7 rows and 3 columns.

Thus, in a series connection direction, the power taking units 114 in the first distribution zone and the second distribution zone can be partitioned according to the spacings between the adjacent power taking units 114, so as to divide the 20 power taking units in the first distribution zone into two sub-areas, and the 19 power taking units 114 into three sub-areas. Power taking units 114 in each sub-area can be arranged with equal spacings, and a spacing between two adjacent sub-areas can be greater than spacings of the adjacent power taking units 114 in each sub-area, thereby making distances between the chips 111 in two ends within each sub-area in the series connection direction and the chips 111 in a center location small, effectively reducing the temperature of the chips 111 in the center location within each sub-area, and, in turn, reducing the temperature difference between the plurality of chips 111 within the sub-area.

Along a parallel connection direction, the number of the power taking units 114 in each distribution zone can decrease. As shown in FIG. 6A, the number of the power taking units 114 in the first distribution zone can be 20, and the number of the power taking units 114 in the second distribution zone can be 19. Row spacings of the chips 111 in each distribution zone are the same, and centers of a plurality of the chips 111 in each row are on a straight line.

In conjunction with FIG. 6A, 117 chips 111 in the chip array are arranged in 21 rows and 6 columns, with centers of the chips 111 in each row on a straight line, and centers of the chips 111 in each column on a straight line. The 11th row of the chips 111 in first 3 columns are missing, and the 8th and 14th rows of the chips 111 in second 3 columns are missing. The number of the chips 111 in the first 3 columns is 60, and the number of the chips 111 in the second 3 columns is 57. The row direction of the chip array can be a heat dissipation direction. In this way, a total number of the chips 111 in a first half part close to an air inlet is greater than a total number of the chips 111 in a second half part close to an air outlet, which can also decrease the maximum temperature difference between the chips 111 close to the air outlet and the chips 111 close to the air inlet, thereby improving the temperature equalization of the chips 111.

Along a direction perpendicular to the heat dissipation direction, the second distribution zone is distributed in two end areas and one middle area. The number of the chips 111 in each end area is greater than or equal to the number of the chips 111 in the middle area. In FIG. 6A, the chips 111 in the end areas are the chips 111 in the first sub-area and the chips 111 in the third sub-area, and the chips 111 in the middle area are the chips 111 in the second sub-area. The number of the chips 111 in each end area is 21, and the number of the chips 111 in the middle area is 15. Thus, in a case where the circuit board 110 is applied to an electronic device 3100, since the chips in the two end areas are closer to the external environment and the heat dissipation is better, by disposing a large number of the chips 111 in the end areas and a small number of the chips 111 in the middle area, the chip 111 temperature in the middle area can be effectively reduced, thereby decreasing the temperature difference between the chips 111 in the middle area and the chips 111 in the end areas, improving the heat dissipation effect of the circuit board 110, and ensuring the overall performance of the circuit board 110.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 6A, the 117 chips 111 on the circuit board 110 are arranged in multiple rows, and the row direction is parallel to a direction from the air inlet to the air outlet of a heat dissipation duct. The number of the chips 111 in the 8th row, the 11th row, and the 14th row is 3 respectively, and the number of the chips 111 in other rows is 6, so the number of the chips 111 in the 8th row, the 11th row, and the 14th row is less than the number of the chips 111 in other rows. At least some of the bosses can be provided at corresponding locations between the 10th power taking unit 114 and the 11th power taking unit 114 in the first distribution zone, and at corresponding locations between the 7th power taking unit 114 and the 8th power taking unit 114, and corresponding locations between the 12th power taking unit 114 and the 13th power taking unit 114 in the second distribution zone.

### Embodiment Seven

FIG. 7 shows a schematic structural view of a circuit board 110 according to Embodiment Seven of the present application. As shown in FIG. 7, the number of the chips 111 in the chip array on the circuit board 110 is 117. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 60 chips 111 arranged in 20 rows and 3 columns, and the 3 chips 111 in each row of the first distribution zone are connected in parallel to constitute 1 power taking unit 114, so the first distribution zone includes 20 power taking units 114. Distances between the 20 power taking units 114 in the first distribution zone can be equal. The second distribution zone includes 57 chips 111 arranged in 19 rows and 3 columns, and the 3 chips 111 in each row of the second distribution zone are connected in parallel to constitute 1 power taking unit 114, so the second distribution zone includes 19 power taking units 114. In a column direction, a spacing between the 10th power taking unit and the 11th power taking unit in the first distribution zone can be greater than spacings of other power taking units; and a spacing between the 6th power taking unit 114 and the 7th power taking unit 114, and a spacing between the 13th power taking unit 114 and the 14th power taking unit 114 in the second distribution zone can be greater than spacings of other adjacent power taking units 114. In FIG. 7, a parallel connection direction is a row direction

Based on the spacing between the 10th power taking unit 114 and the 11th power taking unit 114 in the first distribution zone, the first distribution zone can be divided into two sub-areas, each including 20 chips 111 arranged in 10 rows and 3 columns. Based on the spacing between the 6th power taking unit 114 and the 7th power taking unit 114, and the spacing between the 13th power taking unit 114 and the 14th power taking unit 114, the 1st to 6th power taking units 114 in the second distribution zone can be divided in a first sub-area, which includes 18 chips 111 arranged in 6 rows and 3 columns; the 7th to 13th power taking units 114 can be divided in a second sub-area, which includes 21 chips 111 arranged in 7 rows and 3 columns; and the 14th to 19th power taking units 114 can be divided in a third sub-area, which includes 18 chips 111 arranged in 6 rows and 3 columns.

Along a parallel connection direction, the number of the power taking units 114 in each distribution zone can decrease. As shown in FIG. 7, the number of the power taking units 114 in the first distribution zone can be 20, and the number of the power taking units 114 in the second distribution zone can be 19. Row spacings of the chips 111 in each distribution zone are the same, and centers of a plurality of the chips 111 in each row are on a straight line.

In conjunction with FIG. 7, 117 chips 111 in the chip array are arranged in 21 rows and 6 columns, with centers of the chips 111 in each row on a straight line, and centers of the chips 111 in each column on a straight line. The 11th row of the chips 111 in first 3 columns are missing, and the 7th and 15th rows of the chips 111 in second 3 columns are missing. The number of the chips 111 in the first 3 columns is 60, and the number of the chips 111 in the second 3 columns is 57. The row direction of the chip array can be a heat dissipation direction.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 7, the 117 chips 111 on the circuit board 110 are arranged in multiple rows, and the row direction is parallel to a direction from the air inlet to the air outlet of a heat dissipation duct. The number of the chips 111 in the 7th row, the 11th row, and the 15th row is 3 respectively, and the number of the chips 111 in other rows is 6, so the number of the chips 111 in the 7th row, the 11th row, and the 15th row is less than the number of the chips 111 in other rows. At least some of the bosses can be provided at corresponding locations between the 10th power taking unit 114 and the 11th power taking unit 114 in the first distribution zone, and at corresponding locations between the 6th power taking unit 114 and the 7th power taking unit 114, and corresponding locations between the 13th power taking unit 114 and the 14th power taking unit 114 in the second distribution zone.

### Embodiment Eight

FIG. 8 shows a structural schematic view of a circuit board 110 according to Embodiment Eight of the present application. As shown in FIG. 8, the number of the chips 111 in the chip array on the circuit board 110 is 114. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 60 chips 111 arranged in 20 rows and 3 columns, and the 3 chips 111 in each row of the first distribution zone are connected in parallel to constitute 1 power taking unit 114, so the first distribution zone includes 20 power taking units 114. Distances between the 20 power taking units 114 in the first distribution zone can be equal. The second distribution zone includes 54 chips 111 arranged in 18 rows and 3 columns, and the 3 chips 111 in each row of the second distribution zone are connected in parallel to constitute 1 power taking unit 114, so the second distribution zone includes 18 power taking units 114. In a column direction, a spacing between the 10th power taking unit and the 11th power taking unit in the first distribution zone can be greater than spacings of other power taking units; and a spacing between the 5th power taking unit 114 and the 6th power taking unit 114, a spacing between the 9th power taking unit 114 and the 10th power taking unit 114, and a spacing between the 13th power taking unit 114 and the 14th power taking unit 114 in the second distribution zone can be greater than spacings of other adjacent power taking units 114. In FIG. 8, a parallel connection direction is a row direction

Based on the spacing between the 10th power taking unit 114 and the 11th power taking unit 114 in the first distribution zone, the first distribution zone can be divided into two sub-areas, each including 20 chips 111 arranged in 10 rows and 3 columns. Based on the spacing between the 5th power taking unit 114 and the 6th power taking unit 114, the spacing between the 9th power taking unit 114 and the 10th power taking unit 114, and the spacing between the 13th power taking unit 114 and the 14th power taking unit 114, the 1st to 5th power taking units 114 in the second distribution zone can be divided in a first sub-area, which includes 15 chips 111 arranged in 5 rows and 3 columns; the 6th to 9th power taking units 114 can be divided in a second sub-area, which includes 12 chips 111 arranged in 4 rows and 3 columns; the 10th to 13th power taking units 114 can be divided in a third sub-area, which includes 12 chips 111 arranged in 4 rows and 3 columns; and the 14th to 18th power taking units 114 can be divided in a fourth sub-area, which includes 15 chips 111 arranged in 5 rows and 3 columns.

Along a parallel connection direction, the number of the power taking units 114 in each distribution zone can decrease. As shown in FIG. 8, the number of the power taking units 114 in the first distribution zone can be 20, and the number of the power taking units 114 in the second distribution zone can be 18. Row spacings of the chips 111 in each distribution zone are the same, and centers of a plurality of the chips 111 in each row are on a straight line.

In conjunction with FIG. 8, 114 chips 111 in the chip array are arranged in 21 rows and 6 columns, with centers of the chips 111 in each row on a straight line, and centers of the chips 111 in each column on a straight line. The 11th row of the chips 111 in first 3 columns are missing, and the 6th, 11th and 16th rows of the chips 111 in second 3 columns are missing. The number of the chips 111 in the first 3 columns is 60, and the number of the chips 111 in the second 3 columns is 54. The row direction of the chip array can be a heat dissipation direction.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 8, the 114 chips 111 on the circuit board 110 are arranged in multiple rows, and the row direction is parallel to a direction from the air inlet to the air outlet of a heat dissipation duct. At least some of the bosses can be provided at corresponding locations between the 10th power taking unit 114 and the 11th power taking unit 114 in the first distribution zone, and at corresponding locations between the 5th power taking unit 114 and the 6th power taking unit 114, corresponding locations between the 9th power taking unit 114 and the 10th power taking unit 114, and corresponding locations between the 13th power taking unit 114 and the 14th power taking unit 114 in the second distribution zone.

### Embodiment Nine

FIG. 9 shows a structural schematic view of a circuit board 110 according to Embodiment Nine of the present application. As shown in FIG. 9, the number of chips 111 of the chip array on the circuit board 110 is 120. The chip array includes a plurality of power taking units 114 composed of the chips 111 connected in parallel, and the plurality of power taking units 114 are connected in series. Distances between at least some of the adjacent power taking units 114 are not equal.

Specifically, the chip array includes a first distribution zone provided close to an air inlet and a second distribution zone provided close to an air outlet. Specifically, the first distribution zone includes 63 chips 111 arranged in 21 rows and 3 columns, and the 3 chips 111 in each row of the first distribution zone are connected in parallel to constitute 1 power taking unit 114, so the first distribution zone includes 21 power taking units 114. Distances between the 21 power taking units 114 in the first distribution zone can be equal. The second distribution zone includes 57 chips 111 arranged in 19 rows and 3 columns, and the 3 chips 111 in each row of the second distribution zone are connected in parallel to constitute 1 power taking unit 114, so the second distribution zone includes 19 power taking units 114. In a column direction, a spacing between the 10th power taking unit and the 11th power taking unit in the first distribution zone can be greater than spacings of other power taking units; and a spacing between the 5th power taking unit 114 and the 6th power taking unit 114, a spacing between the 9th power taking unit 114 and the 10th power taking unit 114, and a spacing between the 14th power taking unit 114 and the 15th power taking unit 114 in the second distribution zone can be greater than spacings of other adjacent power taking units 114. In FIG. 9, a parallel connection direction is a row direction.

Based on the spacing between the 10th power taking unit 114 and the 11th power taking unit 114 in the first distribution zone, the first distribution zone can be divided into two sub-areas, each including 20 chips 111 arranged in 10 rows and 3 columns. Based on the spacing between the 5th power taking unit 114 and the 6th power taking unit 114, the spacing between the 9th power taking unit 114 and the 10th power taking unit 114, and the spacing between the 14th power taking unit 114 and the 15th power taking unit 114, the 1st to 5th power taking units 114 in the second distribution zone can be divided in a first sub-area, which includes 15 chips 111 arranged in 5 rows and 3 columns; the 6th to 9th power taking units 114 can be divided in a second sub-area, which includes 12 chips 111 arranged in 4 rows and 3 columns; the 10th to 14th power taking units 114 can be divided in a third sub-area, which includes 15 chips 111 arranged in 5 rows and 3 columns; and the 15th to 19th power taking units 114 can be divided in a fourth sub-area, which includes 15 chips 111 arranged in 5 rows and 3 columns.

Along a parallel connection direction, the number of the power taking units 114 in each distribution zone can decrease. As shown in FIG. 9, the number of the power taking units 114 in the first distribution zone can be 20, and the number of the power taking units 114 in the second distribution zone can be 19. Row spacings of the chips 111 in each distribution zone are the same, and centers of a plurality of the chips 111 in each row are on a straight line.

In conjunction with FIG. 9, 120 chips 111 in the chip array are arranged in 21 rows and 6 columns, with centers of the chips 111 in each row on a straight line, and centers of the chips 111 in each column on a straight line. The 11th row of the chips 111 in first 3 columns are missing, and the 6th, 11th and 17th rows of the chips 111 in second 3 columns are missing. The number of the chips 111 in the first 3 columns is 63, and the number of the chips 111 in the second 3 columns is 57. The row direction of the chip array can be a heat dissipation direction.

Along the parallel connection direction, a distance between the first distribution zone and the second distribution zone can be greater than a distance between two adjacent columns of the chips 111 in each distribution zone; alternatively, along the parallel connection direction, a distance between the first distribution zone and the second distribution zone can be equal to a distance between two adjacent columns of the chips 111 in each distribution zone; still alternatively, along the parallel connection direction, distances between multiple columns of the chips 111 can gradually increase or decrease.

The circuit board 110 can be applied to a working assembly 2100. The working assembly 2100 can include a heat sink 2110. The heat sink 2110 includes a heat dissipation body and heat dissipation fins, the heat dissipation body including a first surface and a second surface opposite to each other. The first surface is connected with the heat dissipation fins, and the second surface is provided with a plurality of bosses, each provided corresponding to each row of the power taking units 114 or each column of the power taking units 114.

In FIG. 9, the 120 chips 111 on the circuit board 110 are arranged in multiple rows, and the row direction is parallel to a direction from the air inlet to the air outlet of a heat dissipation duct. At least some of the bosses can be provided at corresponding locations between the 10th power taking unit 114 and the 11th power taking unit 114 in the first distribution zone, and at corresponding locations between the 5th power taking unit 114 and the 6th power taking unit 114, corresponding locations between the 9th power taking unit 114 and the 10th power taking unit 114, and corresponding locations between the 14th power taking unit 114 and the 15th power taking unit 114 in the second distribution zone.

The circuit board 110 includes two first chip arrays provided close to the air inlet and four second chip arrays provided close to the air outlet. A plurality of chips 111 within the first chip array and the second chip array are arranged in rows. The two first chip arrays are provided with a spacing in a second direction, and the four second chip arrays are provided with spacings in the second direction, and a distance between the two adjacent first chip arrays and distances between two adjacent second chip arrays are greater than the row spacing of the chips 111.

In the example of FIG. 9, one of the first chip arrays includes 30 chips 111 arranged in 10 rows and 3 columns, and the other first chip array includes 33 chips 111 arranged in 11 rows and 3 columns. Row spacings of the chips 111 within the first chip arrays are equal, and centers of the three chips 111 in each row are on a straight line. Along the second direction, the first second chip array, the third second chip array and the fourth second chip array respectively include 15 chips 111 arranged in 5 rows and 3 columns, and the second chip array includes 12 chips 111 arranged in 4 rows and 3 columns. Row spacings of the chips 111 with the second chip array are equal, and centers of the three chips 111 in each row are on a straight line. A gap between the second chip array and the third second chip array is a first gap. A gap between the two first chip arrays is on the same straight line as the first gap.

The circuit board 110 is provided with 120 chips 111 arranged in an array. Centers of the chips 111 in each row are on a straight line, and centers of the chips 111 in each column are on a straight line. The 11th row of the chips in first 3 columns are missing, and the 6th, 11th, and 17th rows of the chips 111 in second 3 columns are missing. The number of the chips 111 in the first 3 columns is 63, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Ten

FIG. 10 shows a schematic structural view of a circuit board 110 according to Embodiment Ten of the present application. As shown in FIG. 10, the circuit board 110 includes one first chip array provided close to an air inlet and three second chip arrays disposed close to an air outlet. A plurality of chips 111 within the first chip array and the second chip array are arranged in rows. The three second chip arrays are provided with spacings in a second direction, and a distance between two adjacent second chip arrays is greater than a row spacing of the chips 111.

In the example of FIG. 10, the first chip array includes 60 chips 111 arranged in 20 rows and 3 columns. Row spacings of the chips 111 within the first chip array are equal, and centers of the three chips 111 in each row are on a straight line. Along the second direction, the first second chip array and the third second chip array respectively include 21 chips 111 arranged in 7 rows and 3 columns, and the second chip array includes 15 chips 111 arranged in 5 rows and 3 columns. Row spacings of the chips 111 within each second chip array are equal, and centers of the three chips 111 in each row are on a straight line. Along the second direction, centers of the three chips 111 in an end of the first chip array and those of the three chips 111 in a corresponding end of the second chip array are not on a straight line, and centers of the three chips 111 in the other end of the first chip array and those of the three chips 111 in a corresponding end of the second chip array are on a straight line.

The circuit board 110 is provided with 117 chips 111 arranged in an array. Centers of the chips 111 in each row are on a straight line, and centers of the chips 111 in each column are on a straight line. The 1st row of the chips 111 in first 3 columns is missing, and the 8th and 14th rows of the chips 111 in second 3 columns are missing. The number of the chips 111 in the first 3 columns is 60, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Eleven

FIG. 11 shows a schematic structural view of a circuit board 110 according to Embodiment Eleven of the present application. As shown in FIG. 11, the circuit board 110 includes one first chip array provided close to an air inlet and three second chip arrays provided close to an air outlet. A plurality of chips 111 within the first chip array and the second chip array are arranged in rows. The three second chip arrays are provided with spacings in a second direction, and a distance between two adjacent second chip arrays is greater than a row spacing of the chips 111.

In the example of FIG. 11, the first chip array includes 57 chips 111 arranged in 19 rows and 3 columns. Row spacings of the chips 111 within the first chip array are equal, and centers of the three chips 111 in each row are on a straight line. Along the second direction, the first second chip array and the third second chip array respectively include 21 chips 111 arranged in 7 rows and 3 columns, and the second chip array includes 15 chips 111 arranged in 5 rows and 3 columns. Row spacings of the chips 111 within each second chip array are equal, and centers of the three chips 111 in each row are on a straight line. Centers of the three chips 111 in an end of the first chip array and those of the three chips 111 in a corresponding end of the second chip array are not on a straight line.

The circuit board 110 is provided with 114 chips 111 arranged in an array. Centers of the chips 111 in each row are on a straight line, and centers of the chips 111 in each column are on a straight line. The 1st and 22nd rows of the chips 111 in first 3 columns are missing, and the 8th and 14th rows of the chips 111 in second 3 columns are missing. The number of the chips 111 in the first 3 columns is 57, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Twelve

FIG. 12 shows a schematic structural view of a circuit board 110 according to Embodiment Twelve of the present application. As shown in FIG. 12, the circuit board 110 includes three first chip arrays provided close to an air inlet and three second chip arrays provided close to an air outlet. A plurality of chips 111 within the first chip array and the second chip array are arranged in rows. The three first chip arrays are provided with spacings in a second direction, the three second chip arrays are provided with spacings in the second direction, and a distance between two adjacent first chip arrays and a distance between two adjacent second chip arrays are greater than a row spacing of the chips 111.

In the example of FIG. 12, along the second direction, each first chip array located in an end includes 21 chips 111 arranged in 7 rows and 3 columns, and a first chip array located in a middle portion includes 15 chips 111 arranged in 5 rows and 3 columns. Row spacings of the chips 111 within the first chip array are equal, and centers of the three chips 111 in each row are on a straight line. Along the second direction, each second chip array located in an end includes 21 chips 111 arranged in 7 rows and 3 columns, and a second chip array located in a middle portion includes 15 chips 111 arranged in 5 rows and 3 columns. Row spacings of the chips 111 within each second chip array are equal, and centers of the three chips 111 in each row are on a straight line. A gap between two adjacent first chip arrays and a gap between two adjacent second chip arrays are located on a straight line.

The circuit board 110 is provided with 114 chips 111 arranged in an array. Centers of the chips 111 in each row are on a straight line, and centers of the chips 111 in each column are on a straight line. The 8th and 14th rows of the chips 111 in first 3 columns are missing, and the 8th and 14th rows of the chips 111 in second 3 columns are missing. The number of the chips 111 in the first 3 columns is 57, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Thirteen

FIG. 13 shows a schematic structural view of a circuit board 110 according to Embodiment Thirteen of the present application. As shown in FIG. 13, the circuit board 110 includes three first chip arrays provided close to an air inlet and three second chip arrays provided close to an air outlet. A plurality of chips 111 within the first chip array and the second chip array are arranged in rows. The three first chip arrays are provided with spacings in a second direction, the three second chip arrays are provided with spacings in the second direction, and a distance between two adjacent first chip arrays and a distance between two adjacent second chip arrays are greater than a row spacing of the chips 111.

In the example of FIG. 13, along the second direction, each first chip array located in an end includes 18 chips 111 arranged in 6 rows and 3 columns, and a first chip array located in a middle portion includes 21 chips 111 arranged in 7 rows and 3 columns. Row spacings of the chips 111 within the first chip array are equal, and centers of the three chips 111 in each row are on a straight line. Along the second direction, each second chip array located in an end includes 21 chips 111 arranged in 7 rows and 3 columns, and a second chip array located in a middle portion includes 15 chips 111 arranged in 5 rows and 3 columns. Row spacings of the chips 111 within each second chip array are equal, and centers of the three chips 111 in each row are on a straight line. A gap between two adjacent first chip arrays and a gap between two adjacent second chip arrays are disposed in a misaligned manner.

The circuit board 110 is provided with 114 chips 111 arranged in an array. Centers of the chips 111 in each row are on a straight line, and centers of the chips 111 in each column are on a straight line. The 7th and 15th rows of the chips 111 in first 3 columns are missing, and the 8th and 14th rows of the chips 111 in second 3 columns are missing. The number of the chips 111 in the first 3 columns is 57, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Fourteen

FIG. 14 shows a schematic structural view of a circuit board 110 according to Embodiment Fourteen of the present application. As shown in FIG. 14, the circuit board 110 includes three first chip arrays provided close to an air inlet and four second chip arrays provided close to an air outlet. A plurality of chips 111 within the first chip array and the second chip array are arranged in rows. The three first chip arrays are provided with spacings in a second direction, the four second chip arrays are provided with spacings in the second direction, and a distance between two adjacent first chip arrays and a distance between two adjacent second chip arrays are greater than a row spacing of the chips 111.

In the example of FIG. 14, along the second direction, each first chip array located in an end includes 21 chips 111 arranged in 7 rows and 3 columns, and a first chip array located in a middle portion includes 18 chips 111 arranged in 6 rows and 3 columns. Row spacings of the chips 111 within the first chip array are equal, and centers of the three chips 111 in each row are on a straight line. Along the second direction, the first second chip array, the third second chip array and the fourth second chip array respectively include 15 chips 111 arranged in 5 rows and 3 columns, and the second chip array includes 12 chips 111 arranged in 4 rows and 3 columns. Row spacings of the chips 111 within each second chip array are equal, and centers of the three chips 111 in each row are on a straight line. A gap between two adjacent first chip arrays and a gap between two adjacent second chip arrays are disposed in a misaligned manner.

The circuit board 110 is provided with 117 chips 111 arranged in an array. Centers of the chips 111 in each row are on a straight line, and centers of the chips 111 in each column are on a straight line. The 8th and 15th rows of the chips 111 in first 3 columns are missing, and the 6th, 11th and 17th rows of the chips 111 in second 3 columns are missing. The number of the chips 111 in the first 3 columns is 60, and the number of the chips 111 in the second 3 columns is 57.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Fifteen

FIG. 15 shows a schematic structural view of a circuit board 110 according to Embodiment Fifteen of the present application. As shown in FIG. 15, the circuit board 110 includes four first chip arrays provided close to an air inlet and five second chip arrays provided close to an air outlet. A plurality of chips 111 within the first chip array and the second chip array are arranged in rows. The four first chip arrays are provided with spacings in a second direction, the five second chip arrays are provided with spacings in the second direction, and a distance between two adjacent first chip arrays and a distance between two adjacent second chip arrays are greater than a row spacing of the chips 111.

In the example of FIG. 15, along the second direction, the first chip array and the fourth first chip array respectively include 15 chips 111 arranged in 5 rows and 3 columns, and the second first chip array and the third first chip array respectively include 12 chips 111 arranged in 4 rows and 3 columns. Row spacings of the chips 111 within the first chip array are equal, and centers of the three chips 111 in each row are on a straight line. Along the second direction, the first second chip array includes 6 chips 111 arranged in 2 rows and 3 columns; the second chip array, the third second chip array and the fifth second chip array respectively include 12 chips 111 arranged in 4 rows and 3 columns, and the fourth second chip array includes 9 chips 111 arranged in 3 rows and 3 columns. Row spacings of the chips 111 within each second chip array are equal, and centers of the three chips 111 in each row are on a straight line. A gap between two adjacent first chip arrays and a gap between two adjacent second chip arrays are disposed in a misaligned manner.

The circuit board 110 is provided with 105 chips 111 arranged in an array. Centers of the chips 111 in each row are on a straight line, and centers of the chips 111 in each column are on a straight line. The 6th, 11th and 16th rows of the chips 111 in first 3 columns are missing, and the 3rd, 8th, 13th and 17th rows of the chips 111 in second 3 columns are missing. The number of the chips 111 in the first 3 columns is 54, and the number of the chips 111 in the second 3 columns is 51.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Sixteen

FIG. 16 shows a schematic structural view of a circuit board 110 according to Embodiment Sixteen of the present application. As shown in FIG. 16, the circuit board 110 includes six first chip arrays provided close to an air inlet and six second chip arrays provided close to an air outlet. A plurality of chips 111 within the first chip array and the second chip array are arranged in rows. The six first chip arrays are provided with spacings in a second direction, the six second chip arrays are provided with spacings in the second direction, and a distance between two adjacent first chip arrays and a distance between two adjacent second chip arrays are greater than a row spacing of the chips 111.

In the example of FIG. 16, along the second direction, the second to fifth first chip arrays respectively include 9 chips 111 arranged in 3 rows and 3 columns, the first chip array includes 6 chips 111 arranged in 2 rows and 3 columns, and the sixth first chip array includes 3 chips 111 arranged in 1 row and 3 columns. Row spacings of the chips 111 within the first chip array are equal, and centers of the three chips 111 in each row are on a straight line. Along the second direction, the first second chip array includes 3 chips 111 arranged in 1 row and 3 columns, and the second to sixth second chip arrays respectively include 9 chips 111 arranged in 3 rows and 3 columns. Row spacings of the chips 111 within each second chip array are equal, and centers of the three chips 111 in each row are on a straight line. A gap between two adjacent first chip arrays and a gap between two adjacent second chip arrays are disposed in a misaligned manner.

The circuit board 110 is provided with 93 chips 111 arranged in an array. Centers of the chips 111 in each row are on a straight line, and centers of the chips 111 in each column are on a straight line. The first, 4th, 8th, 12th, 16th, and 20th rows of the chips 111 in first 3 columns are missing, and the 2nd, 6th, 10th, 14th, and 18th rows of the chips 111 in second 3 columns are missing. The number of the chips 111 in the first 3 columns is 45, and the number of the chips 111 in the second 3 columns is 48.

Along a first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Seventeen

FIG. 17 shows a schematic structural view of a circuit board 110 according to Embodiment Seventeen of the present application. As shown in FIG. 17, the circuit board 110 includes three first chip arrays provided close to an air inlet and one second chip array provided close to an air outlet. A plurality of chips 111 within the first chip array and the second chip array are arranged in rows. The three first chip arrays are provided with spacings in a second direction, and a distance between the first chip arrays is greater than a row spacing of the chips 111.

In the example of FIG. 17, along the second direction, each first chip array located in an end includes 21 chips 111 arranged in 7 rows and 3 columns, a first chip array located in a middle portion includes 15 chips 111 arranged in 5 rows and 3 columns, and row spacings of the chips 111 within each first chip array are equal. The second chip array includes 63 chips 111 arranged in 21 rows and 3 columns, row spacings of the chips 111 in the second chip array are equal, and centers of a plurality of the chips 111 in each row are on a straight line. Along the second direction, centers of the three chips 111 in an end of the first chip array and those of the three chips 111 in a corresponding end of the second chip array are on a straight line. Gaps between two adjacent first chip arrays correspond in a first direction to the chips in the 8th and 14th rows of the second chip array.

That is to say, a total of 120 chips 111 arranged in 21 rows and 6 columns are provided on the circuit board 110. Centers of the chips 111 in each row are on a straight line, and centers of the chips 111 in each column are on a straight line. Row spacings of the chips 111 in second 3 columns are the same, and the 8th and 14th rows of the chips 111 in first 3 columns are missing. The number of the chips 111 in the first 3 columns is 57, and the number of the chips 111 in the second 3 columns is 63.

Along the first direction, a distance between the first chip array and the second chip array can be greater than a distance between two adjacent columns of the chips 111 within each chip array; alternatively, along the first direction, a distance between the first chip array and the second chip array can be equal to a distance between two adjacent columns of the chips 111 within each chip array; still alternatively, along the first direction, distances between multiple columns of the chips 111 can gradually increase or decrease.

### Embodiment Eighteen

FIG. 18 shows a schematic structural view of a circuit board 110 according to Embodiment Eighteen of the present application. As shown in FIG. 18, a total of 21 rows and 6 columns of chips 111 are provided on the circuit board 110. The 10th, 11th, and 12th rows of the chips 111 in the sixth column are missing. The number of the chips 111 in first 3 columns is 63, and the number of the chips 111 in second 3 columns is 60. Along a first direction, distances between two adjacent columns of the chips 111 can gradually increase; alternatively, along the first direction, distances between two adjacent columns of the chips 111 can gradually decrease; still alternatively, along the first direction, a distance between the third and fourth columns of the chips 111 is greater than distances between the chips 111 between the remaining two adjacent columns; of course, the present application is not limited to this, for example, along the first direction, distances between every two adjacent columns of the chips 111 may also be equal, or column spacings of the plurality of chips 111 may not be of any regularity.

### Embodiment Nineteen

FIG. 19A shows a schematic structural view of a circuit board 110 according to Embodiment Nineteen of the present application. As shown in FIG. 19A, a total of 10 columns and 8 rows of the chips 111 are provided on the circuit board 110. A total number of the chips 111 is 76, and the third to sixth rows of the chips 111 in the third column are missing. Along a first direction, namely, a left-right direction, distances between two adjacent columns of the chips 111 can gradually increase; alternatively, along the first direction, distances between two adjacent columns of the chips 111 can gradually decrease; still alternatively, along the first direction, a distance between the third and fourth columns of the chips 111 is greater than distances between the chips 111 between the remaining two adjacent columns; of course, the present application is not limited to this, for example, along the first direction, distances between every two adjacent columns of the chips 111 may also be equal, or column spacings of the plurality of chips 111 may be of any regularity.

FIG. 19B shows a current diagram of the circuit board 110 shown in FIG. 19A. As shown in FIG. 19B, in a case that a heat dissipation direction is an up-down direction, the circuit board 110 includes three first chip arrays provided close to an air inlet and three second chip arrays provided close to an air outlet. A first chip array located on an edge in a first direction includes 10 chip 111 sets, and two second chip arrays located in a middle portion in the first direction include 2 and 7 chip 111 sets, respectively. A second chip array located on an edge in the first direction includes 10 chip 111 sets, and two second chip arrays located in a middle portion in the first direction include 2 and 7 chip 111 sets, respectively. Each chip 111 set is composed of 2 chips 111 connected in parallel to form a power taking unit 114. Along a series connection direction of each chip 111 set, lengths of electrical connection lines between the adjacent chip arrays are greater than lengths of electrical connection lines between adjacent chip 111 sets, and lengths of signal lines 116 between the adjacent chip arrays are greater than lengths of signal lines 116 between adjacent chip 111 sets.

In a case that the heat dissipation direction is a left-right direction, the first and second rows of the chips constitute one chip array, the third and fourth rows of the chips are divided into two chip arrays by vacant positions 113, the fifth and sixth rows of the chips are divided into two chip arrays by vacant positions 113, and the seventh and eighth rows of the chips constitute one chip array. At this time, a parallel connection direction of the chips is perpendicular to the heat dissipation direction, and the vacant positions 113 are located in the chip array close to the air outlet.

### Embodiment Twenty

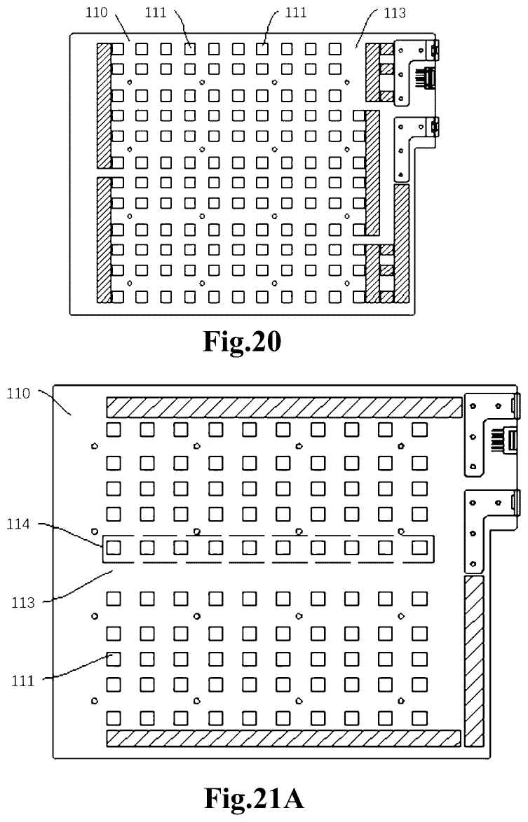

FIG. 20 shows a schematic structural view of a circuit board 110 according to Embodiment Twenty of the present application. As shown in FIG. 20, a total of 11 rows and 12 columns of chips 111 are provided on the circuit board 110. A total number of the chips 111 is 129, and the tenth to twelfth columns of the chips in the first row are missing. Along a first direction, namely, an up-down direction, distances between two adjacent columns of the chips 111 can gradually increase; alternatively, along the first direction, distances between two adjacent columns of the chips 111 can gradually decrease; still alternatively, along the first direction, a distance between the third and fourth columns of the chips 111 is greater than distances between the chips 111 between the remaining two adjacent columns; of course, the present application is not limited to this, for example, along the first direction, distances between every two adjacent columns of the chips 111 may also be equal, or column spacings of the plurality of chips 111 may not be of any regularity.

### Embodiment Twenty-One

FIG. 21A shows a schematic structural view of a circuit board 110 according to Embodiment Twenty-One of the present application. As shown in FIG. 21A, a total number of chips 111 on the circuit board 110 is 100, and the chips 111 in the sixth row are missing.

FIG. 21B shows a current diagram of the circuit board 110 shown in FIG. 21A. As shown in FIG. 21B, the circuit board 110 includes one first chip array provided close to an air inlet and one second chip array provided close to an air outlet. The first chip array and the second chip array include 5 chip 111 sets, respectively. Each chip 111 set is composed of 10 chips 111 connected in parallel to form a power taking unit 114. Along a series connection direction of each chip 111 set, lengths of electrical connection lines between the first chip array and the second chip array are greater than lengths of electrical connection lines between adjacent chip 111 sets in each chip array, and lengths of signal lines 116 between the adjacent chip arrays are greater than lengths of signal lines 116 between adjacent chip 111 sets in each chip array. 115

Other constructions of the circuit boards 110 and the working assembly 2100 of the above embodiments can be adopted in various technical solutions known to persons of ordinary skills in the art now and in the future, which will not be described in detail here.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the drawings, and are only for the convenience of describing the present application and simplifying the description, and do not indicate or imply that a device or element as mentioned must have a particular orientation, or be constructed and operated in a particular orientation, and therefore should not be understood as a limitation on the present application.

In addition, the terms “first” and “second” are used for descriptive purposes only and should not be understood as indicating or implying relative importance or implicitly stating the number of technical features as indicated. Accordingly, a feature defined by “first” or “second” may explicitly or implicitly include one or more of the features.

In the present application, unless otherwise clearly specified and defined, the terms “mount”, “connect with”, “connect”, “fix” and the like should be understood in a broad sense. For example, it is possible to be a fixed connection, a detachable connection, or an integration; it is possible to be a mechanical connection, an electrical connection, or a communication; it is possible to be a direct connection, or an indirect connection through an intermediate medium, or an internal communication between two elements or an interaction relationship between two elements. For those skilled in the art, the specific meanings of the above terms in the present application can be understood as a specific case may be.

In the present application, unless otherwise clearly specified and defined, a first feature being “on” or “under” a second feature may include a case that the first and second features are in direct contact, or a case that the first and second features are not in direct contact but are in contact through an additional feature between them. Moreover, a first feature being “on”, “above” and “over” a second feature includes a case that the first feature is directly above and obliquely above the second feature, or simply represents that the first feature is higher in level than the second feature. A first feature being “under”, “below” and “beneath” a second feature includes a case that the first feature is directly above and obliquely above the second feature, or simply represents that the first feature is lower in level than the second feature.

The disclosure above provides many different embodiments or instances to achieve the different structures of the present application. In order to simplify the disclosure of the present application, the parts and settings of particular instances are described above. Certainly, they are only examples, and their purpose is not to limit the present application. In addition, in the present application, reference numerals and/or reference letters can be repeated in different instances, and such repetition is for the purpose of simplification and clarity, which itself does not indicate the relationships between the various implementations and/or settings discussed.

Described above are only specific implementations of the present application, but the scope of protection of the present application is not limited thereto. Any technicians familiar with this technical field can readily envisage various changes or substitutions within the technical scope disclosed in the present application, all of which should be included in the scope of protection of the present application. Therefore, the scope of protection of the present application should be based on the scope of protection of the attached claims.

1. A circuit board, provided with a chip array thereon, the chip array comprising a plurality of power taking units, each of the plurality of power taking units comprising at least one chip, wherein distances between at least some adjacent power taking units of the plurality of power taking units are not equal.

2. The circuit board of claim 1, wherein chips in the chip array are of the same size, and a total number of chips in the chip array is greater than or equal to 20 or 50.

3. The circuit board of claim 1, wherein distances between at least some adjacent power taking units are greater than or equal to a spacing for accommodating one chip.

4. The circuit board of claim 1, wherein along a heat dissipation direction, distances between adjacent power taking units increase, and/or distances between adjacent chips increase.

5. The circuit board of claim 1, wherein at least one of the plurality of power taking units comprises a plurality of chips, and the chips of the power taking unit are connected in parallel.

6. The circuit board of claim 1, wherein the plurality of power taking units are connected in series.

7. The circuit board of claim 5, wherein along a direction perpendicular to a parallel connection direction, distances between at least some adjacent power taking units are greater than distances between other adjacent power taking units; or
along a direction perpendicular to a parallel connection direction, lengths of electrical connection lines between at least some adjacent power taking units are longer than lengths of electrical connection lines between other adjacent power taking units; or
metal pieces are provided between adjacent power taking units, and along a direction perpendicular to a parallel connection direction, lengths of metal pieces between at least some adjacent power taking units are longer than those between other adjacent power taking units.

8. (canceled)

9. (canceled)

10. The circuit board of claim 6, wherein along a series connection direction, distances between at least some adjacent power taking units are greater than distances between other adjacent power taking units; or
along a series connection direction, lengths of electrical connection lines between at least some adjacent power taking units are longer than lengths of electrical connection lines between other adjacent power taking units; or
metal pieces are provided between adjacent power taking units, and along a series connection direction, lengths of metal pieces between at least some adjacent power taking units are longer than those between other adjacent power taking units.

11. (canceled)

12. (canceled)

13. The circuit board of claim 7, wherein the other adjacent power taking units are adjacent power taking units in the same row or column.

14. The circuit board of claim 7, wherein the other adjacent power taking units are non-edge power taking units in the chip array.

15. The circuit board of claim 1, wherein in a heat dissipation direction, a rectangular area occupied by the chip array on the circuit board is divided into a plurality of distribution zones, and numbers of the power taking units within at least two of the distribution zones are not equal.

16. The circuit board of claim 15, wherein in a case that a chip row direction is the heat dissipation direction, numbers of chip columns in each of the distribution zones are the same; and in a case that a chip column direction is the heat dissipation direction, numbers of chip rows in each of the distribution zones are the same; or
along the heat dissipation direction, the numbers of the power taking units within the plurality of distribution zones decrease.

17. (canceled)

18. The circuit board of claim 1, wherein in a direction perpendicular to a heat dissipation direction, a rectangular area occupied by the chip array on the circuit board is divided into a plurality of sub-areas, and a spacing of at least two adjacent sub-areas of the plurality of sub-areas is not equal to spacings of adjacent power taking units within any one of the plurality of sub-areas.

19. The circuit board of claim 18, wherein the spacing of at least two adjacent sub-areas of the plurality of sub-areas is greater than or equal to a spacing for accommodating one chip; or
in a case that a chip row direction is the heat dissipation direction, numbers of chip columns in each of the sub-areas are the same; and in a case that a chip column direction is the heat dissipation direction, numbers of chip rows in each of the sub-areas are the same; or
the numbers of power supply units in at least two of the sub-areas are not equal.

20. (canceled)

21. (canceled)

22. The circuit board of claim 18, wherein the plurality of sub-areas comprise two end areas and one middle area, and number of the power taking units in the end areas is greater than or equal to number of the power taking units in the middle area.

23. The circuit board of claim 22, wherein the numbers of the power taking units increases from the middle area to the end areas; or the two end areas comprise a first end area and a second end area, and the number of the power taking units in the first end area is less than the number of the power taking units in the second end area, wherein in a perpendicularly placed state of the circuit board, the first end area is close to a top of the circuit board, and the second end area is close to a bottom of the circuit board.

24. (canceled)

25. The circuit board of claim 18, wherein the plurality of sub-areas comprise two end areas and one middle area, and number of chips in the end areas is greater than or equal to number of chips in the middle area; or
the plurality of sub-areas comprise two end areas and one middle area, and an average chip spacing in the end areas is less than an average chip spacing in the middle area.

26. (canceled)

27. The circuit board of claim 1, wherein a row direction of the chip array is a parallel connection direction of a plurality of chips of the power taking units.

28. The circuit board of claim 1, wherein a row direction of the chip array is a heat dissipation direction; or a parallel connection direction of a plurality of chips of the power taking units is a heat dissipation direction.

29. (canceled)

30. The circuit board of claim 1, wherein a working temperature difference between chips of the chip array ranges from 0 to 10 °C; or centers of the chips in each row or the chips in each column are on the same straight line.

31.-142. (canceled)
